(19) United States
(12) Patent Application Publication
(10) Pub. No.: US 2026/0125817 A1
(43) Pub. Date: May 7, 2026

(54) ARTICLES WITH DECORATIVE SURFACE COATINGS

(71) Applicant: MAXTERIAL, INC., Pleasanton, CA (US)

(72) Inventors: Atieh Haghdoost, Pleasanton, CA (US); Mehdi Kargar, Pleasanton, CA (US); Ersan Ilgar, Pleasanton, CA (US); Daniel Church, Pleasanton, CA (US)

(21) Appl. No.: 19/236,806

(22) Filed: Jun. 12, 2025

Related U.S. Application Data
(63) Continuation of application No. PCT/US23/84478, filed on Dec. 16, 2023.
(60) Provisional application No. 63/433,363, filed on Dec. 16, 2022.

(51) Int. Cl. C25D 7/00; C25D 5/10

(52) U.S. Cl. CPC C25D 7/00; C25D 5/10

(57) ABSTRACT

Decorative items with surface coatings are described. A surface of the decorative item can include a surface coating. The surface coating can include many different materials and may include a metal or metal alloy such as, for example, a molybdenum alloy or a nickel alloy or a nickel molybdenum alloy. A decorative coating layer comprising chromium or other materials can be present on an alloy layer, e.g., on a molybdenum alloy layer.

### PRIORITY APPLICATIONS

This application is a continuation application of PCT/US23/84478 filed on Dec. 16, 2023. PCT/US23/84478 claims priority to, and the benefit of, U.S. Provisional Application No. 63/433,363 filed on Dec. 16, 2022, the entire disclosure of which is hereby incorporated herein by reference for all purposes.

### TECHNOLOGICAL FIELD

Certain configurations described herein are directed to decorative coatings that can be used on jewelry, silverware, automotive parts, connector shells and other devices or portions thereof.

### SUMMARY

Certain aspects, embodiments and configurations are described below in connection with articles that include decorative surface coatings.

In an aspect, a decorative item comprises a decorative item substrate, wherein at least a portion of an outer surface of the decorative item substrate comprises a coated surface. For example, the coated surface comprises a surface coating, wherein the surface coating comprises an alloy layer comprising (i) molybdenum or tungsten and (ii) at least one element selected from the group consisting of nickel, cobalt, chromium, tin, phosphorous, iron, magnesium and boron or at least one compound comprising one or more of nickel, cobalt, chromium, tin, phosphorous, iron, magnesium or boron.

In certain embodiments, the alloy layer is present on all surfaces of the decorative item substrate. In other embodiments, the alloy layer is present on inner surfaces of the decorative item substrate.

In certain configurations, the molybdenum or tungsten is present in the surface coating at 40% or less by weight based on a weight of the surface coating, or at 20% or less by weight based on a weight of the surface coating, or at 10% or less by weight based on a weight of the surface coating, or at 40% or less by weight based on a weight of the alloy layer, or at 20% or less by weight based on a weight of the alloy layer, or at 10% or less by weight based on a weight of the alloy layer.

In other embodiments, the surface coating comprises a surface roughness Ra of less than 1 micron or less than 10 microns.

In some embodiments, the alloy layer consists essentially of nickel and molybdenum or consists essentially of nickel, molybdenum and phosphorous, or consists essentially of nickel and tungsten or consists essentially of nickel, tungsten and phosphorous.

In other embodiments, the surface coating comprises a surface roughness Ra of less than 1 micron, and the molybdenum or tungsten is present in the alloy layer at 20% or less by weight based on a weight of the surface coating, and the surface coating excludes precious metals.

In certain configurations, the alloy layer is an electrodeposited alloy layer. In other configurations, the surface coating is free of any precious metals.

In certain embodiments, the alloy layer is an exposed outer layer of the surface coating. In some embodiments, the exposed outer layer (i) consists essentially of molybdenum or tungsten and only one element or compound comprising nickel, cobalt, tin, phosphorous, iron, chromium or boron, or (ii) consists essentially of molybdenum or tungsten and only two elements or compounds comprising of nickel, cobalt, tin, phosphorous, iron, chromium or boron, or (iii) consists essentially of molybdenum, nickel and only element or compound comprising tungsten, cobalt, tin, phosphorous, iron, chromium or boron or (iv) consists essentially of tungsten, nickel and only element or compound comprising molybdenum, cobalt, tin, phosphorous, iron, chromium, magnesium or boron.

In certain configurations, an intermediate layer can be between the alloy layer and the surface of the substrate. In certain embodiments, the alloy layer is present as an exposed outer layer of the surface coating, wherein the exposed outer layer is an electrodeposited alloy layer, and wherein the electrodeposited alloy layer excludes precious metals.

In some examples, an additional layer can be formed on the alloy layer.

In other embodiments, the alloy layer is present as an electrodeposited alloy layer, and wherein the electrodeposited alloy layer excludes precious metals.

In certain embodiments, the decorative item substrate comprises a textured surface. In other embodiments, the coated surface comprises a textured surface. In certain embodiments, the textured surface comprises a surface roughness Ra of more than 1 micron and less than 30 microns or a surface roughness Ra of more than 0.5 microns and less than 15 microns.

In certain embodiments, the coated surface is free of precious metals.

In some configurations, the decorative item substrate comprises stainless steel, hardened steel, carbon steel, alloy steel, a precious metal or other metal, and wherein the surface coating comprises a chromium layer on the alloy layer.

In other embodiments, the decorative item substrate comprises stainless steel, hardened steel, carbon steel, alloy steel, a precious metal or other metal, and wherein the surface coating is free of lead.

In some embodiments, the decorative item substrate comprises stainless steel, hardened steel, carbon steel, alloy steel, a precious metal or other metal, and wherein the surface coating is free of mercury.

In an aspect, a decorative item comprises a decorative item substrate, wherein at least a portion of an outer surface of the decorative item substrate comprises a coated surface, wherein the coated surface comprises a surface coating, and wherein the surface coating comprises an alloy layer comprising (i) molybdenum or tungsten and (ii) at least one element selected from the group consisting of nickel, cobalt, tin, phosphorous, iron, magnesium and boron or at least one compound comprising one or more of nickel, cobalt, tin, phosphorous, iron, magnesium or boron, and wherein the alloy layer is free of chromium, lead, and mercury.

Additional aspects, embodiments, examples and configurations are discussed in more detail below.

### BRIEF DESCRIPTION OF THE SEVERAL VIEWS OF THE DRAWINGS

Certain aspects, embodiments and configurations are described with reference to the figures in which:

FIG. 1 is an illustration of a device including a surface coating on a substrate;

FIG. 2 is an illustration of a device including two layers in a coating on a substrate;

FIG. 3 is another illustration of a device including two layers in a coating on a substrate;

FIG. 4A and FIG. 4B are illustrations of a device including a textured surface;

FIG. 5A and FIG. 5B are illustrations of a device including two or more layers;

FIG. 6, FIG. 7, and FIG. 8 are illustration of coating layers;

FIG. 9, FIG. 10 and FIG. 11 are illustrations of non-flat surfaces;

FIG. 12 is an illustration of a device with multiple coating layers;

FIG. 13A, FIG. 13B, FIG. 13C, FIG. 13D, FIG. 13E, FIG. 13F and FIG. 13G show various decorative coatings on automotive parts;

FIG. 14A, FIG. 14B, FIG. 14C, FIG. 14D, FIG. 14E, FIG. 14F, FIG. 14G, FIG. 14H, FIG. 14I, FIG. 14J, FIG. 14K, FIG. 14L and FIG. 14M show various decorative coatings on silverware;

FIG. 15A, FIG. 15B, FIG. 15C and FIG. 15D show various decorative coatings on jewelry;

FIG. 15E and FIG. 15F shows a decorative coating on a connector shell;

FIG. 16 and FIG. 17 are photographs showing a coating on a surface;

FIG. 18A, FIG. 18B, FIG. 18C and FIG. 18D are photographs showing cracks in coatings before and after heat treatment;

FIG. 19A and FIG. 19B are photographs showing cracks in coatings;

FIG. 20 is a table showing a corrosion scale;

FIG. 21 is a photograph showing corrosion on a surface;

FIG. 22A, FIG. 22B, FIG. 22C, FIG. 22D and FIG. 22E are photographs showing corrosion on a surface;

FIG. 23 is a graph showing corrosion versus exposure hours;

FIG. 24 is a table showing corrosion ratings of different coatings;

FIG. 25A, FIG. 25B and FIG. 25C are photographs showing corrosion;

FIG. 26 is a photograph showing a coating applied to notch bars;

FIG. 27 is a photograph showing a coating applied to an article;

FIG. 28A and FIG. 28B are the results of a wear test;

FIG. 29 is an illustration of a device used to test friction coefficients;

FIG. 30 is a table showing coefficients of friction;

FIG. 31 and FIG. 32 are table showing wear factors;

FIG. 33 is a graph showing Taber wear index values;

FIG. 34 is a photograph showing a cut in a socket with a surface coating;

FIG. 35 is a graph showing corrosion rates after acid exposure;

FIG. 36 is a photograph showing a tested coating after elongation; and

FIG. 37 is a microscopic image of the coating of FIG. 36.

It will be recognized by the person of ordinary skill in the art, given the benefit of this specification, that the layers and features shown in the figures are not necessarily drawn to scale. The arrangement and dimensions of the various layers and features in the figures are not intended to imply that any one arrangement or thickness is required.

### DETAILED DESCRIPTION

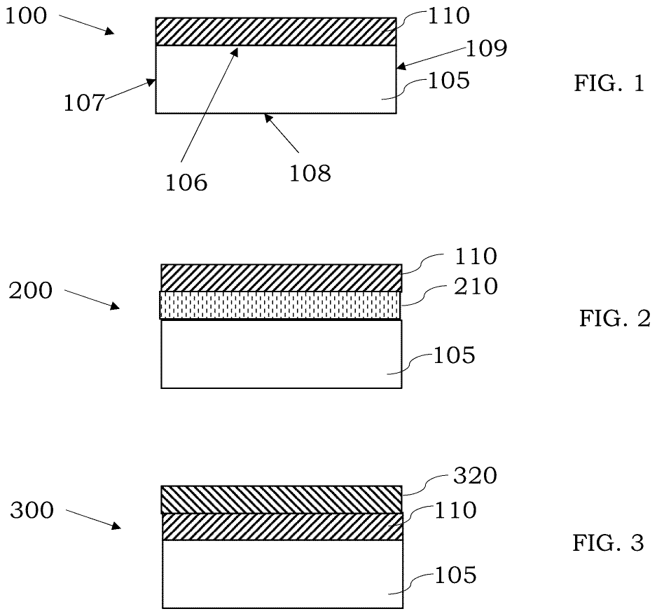

There is a need for decorative coating technologies. In certain embodiments, the surface coatings described herein can be present in in various different types of decorative items. The decorative items generally include a substrate formed of a metal, metal alloy or other materials with a coated surface on some portion of the substrate. The entire external surface of the decorative items need not include the surface coating but may include the surface coating if desired. The exact composition and arrangement of the surface coating can vary as noted below. As noted in detail below, the decorative item can include an outer decorative coating on top of one of or more of the surface coatings or layers described in reference to FIGS. 1-12.

The coatings described herein can have numerous attributes and properties depending on the particular composition. The coating can have different appearances. The coating can be matt or shiny. In certain embodiments, the coating can have mirror-like appearance. The coating can have different colors. For example, it can be metallic or black may have a texture or be non-textured.

In certain embodiments, the coating and coated articles described herein can be heat treated to increase the hardness of the coatings. Hardness can be assessed according to ASTM E384-17 to determine the hardness in the absence of heat treating and after heat treating. The exact hardness of the coating can vary depending on the composition and any post-deposition processing. For example, the hardness can vary between 520-780 Vickers hardness (HV) post-deposition. If desired, the hardness can increase after heat treatment. In some embodiments, hardness can increase at least by 2%, at least by 5%, at least by 8%, at least by up 10% or more after heat treatment. For example, hardness can increase to 650-940 HV after heat treatment or other processing.

In general, hard chrome coatings have a Vickers hardness under ASTM E384-17 of about 800-1000 HV prior to heat treatment with the hardness decreasing to 700-750 HV after 23 hours of heat treatment. It is worth mentioning that most specifications, such as MIL-STD-1501F, call for the baking requirement at 191±14° C. (375±25° F.) for twenty-three hours to prevent hydrogen embrittlement. So, at this baking condition, hard chrome coating loses its hardness. In addition, a lot of applications where high heat is experienced or the coating is exposed to heat during the operation and chrome softens at the operation condition in these applications. In contrast to hard chrome coatings, the coatings described herein can have an increased hardness after heat treatment.

In certain configurations, the coatings can be designed to include microcracks or be free of, or substantially free of, microcracks on the surface. For example, in applications where the coatings are used on articles that contain a hydraulic fluid, lubricant or other fluid, the presence of microcracks can enhance retention of the hydraulic fluid, lubricant or other fluid on a surface of the article. By increasing microcrack density, improved properties and longer article life can be achieved. In some embodiments where microcracks are desired, the coating can have a microcrack density of 150 to 300 individual cracks per linear inch in the horizontal dimension (based on full thickness of the coating layer). In certain instances, the coatings can be heat treated without altering the overall microcrack density to any substantial degree. When microcracks are present, the microcracks desirably do not penetrate so deep that the underlying substrate is exposed. In instances where microcracks may result in substrate exposure, one or more underlayers may first be coated onto the substrate prior to deposition of the coatings to protect the underlying substrate against corrosion. In contrast to hard chrome coatings, which generally have microcracks that form macrocracks after heat treatment, heat treatment of the coatings described herein generally result in no or few macrocracks. This result can increase the overall corrosion resistance of the coatings described herein.

In certain configurations, the coatings described herein can provide significant corrosion resistance. In some instances, the corrosion resistance can be measured by ASTM B117-19 salt spray test and the rating can be determined according to the ASTM B537 Rust Grade test. In brief, the salt spray test provides a controlled accelerated corrosive environment to evaluate the relative corrosion resistance of the coating, substrate, or part itself. The corrosion level can be assessed according to a 0 -10 scale based on the percentage of visible rust. 10 represents no surface rust with the scale decreasing as surface rust appears. A table representative of the rust scale is shown in the specific examples provided below. In a certain embodiments, hard chrome coating has an initial corrosion resistance of 10 which decreases to 4 or less after continued salt spray exposure. A corrosion rate of 4 indicates that 3 to 10% of the surface area is corroded after 1000 hours. In certain embodiments, the coatings described herein can have an initial corrosion resistance of 10 that decreases to 9, 8 or 7 after continued salt spray exposure. In some embodiments, the corrosion rating of the coatings described herein is 6 or more after 1000 hours of salt spray exposure. In additional embodiments, the corrosion rating of the coatings described herein is 7 or more after 1000 hours of salt spray exposure. In other embodiments, the corrosion rating of the coatings described herein is 8 or more after 1000 hours of salt spray exposure. In some embodiments, the corrosion rating of the coatings described herein is 9 or more after 1000 hours of salt spray exposure. In other embodiments, the corrosion rating of the coatings described herein is 10 or more after 1000 hours of salt spray exposure. In other embodiments, the corrosion rating of the coatings described herein is 6 or more after 48 hours of salt spray exposure. These corrosion rating values are based on the scale noted in ASTM B537. In a certain embodiment, the coatings described herein exhibit 5% corrosion on its surface (based on total surface area) after 1000 hours of the salt spray test. In another embodiment, the coatings described herein exhibit 5% corrosion on its surface (based on total surface area) after 5000 hours of the salt spray test. In other embodiments, corrosion resistance can be measured by exposing the coatings to strong acid, e.g., concentrated HCl, concentrated HNO₃ or concentrated H₂SO₄. When acid is used as a measure of corrosion resistance, the weight of the coating before and after acid exposure is used to determine wear resistance. The weight decreases if material is removed as a result of the exposure to the acidic environment. The acid resistance test can expose the coating to 32% HCl for 24 hours by immersing the coating and substrate in the acidic liquid. The results can be normalized to millinches per year to consistently compare different types of coatings. Hard chrome coatings can exceed 90,000 millinches per year as these coatings are not generally acid resistant and dissolve quickly in HCl. Nickel coatings can have an acid resistance of around 80 millinches per year. Hastelloy® B2 alloys have an acid resistance of 15 millinches per year, and Inconel® alloys have an acid resistance of 39 millinches per year. In certain embodiments, the coatings described herein can have an acid resistance of less than 30 millinches per year or less than 20 millinches per year or even less than 15 millinches per year. For example, the acid resistance of the coatings described herein can vary from 1 millinch per year to 20 millinches per year or 1 millinches per year to 14 millinches per year or 1 millinch per year to 13 millinches per year or 1 millinch per year to 12 millinches per year or 1 millinch per year to 11 millinches per year or 1 millinch per year to 10 millinches per year.

The coatings described herein can be more ductile than many existing coatings. Ductility is a measure of the ability of the coating to be bent without fracture or blistering. ASTM E8/8M-22 can be used to measure ductility with higher values representative of the coating being more ductile. A ductility of hard chrome coatings is typically less than 0.1%. Electroless nickel coatings have a ductility of 1-1.5%. In comparison, the coatings described herein can have a ductility of 2% or more or 3% or more. In some embodiments, the ductility may be 4% or more or even 5% or more. For example, the ductility of the coating can be 2% to 10% or 2% to 9% or 2% to 8% or 2% to 7% or 2% to 6% or 2% to 5% or 2% to 4% or 2% to 3%. In other embodiments, the ductility of the coating can be 3% to 10% or 3% to 9% or 3% to 8% or 3% to 7% or 3% to 6% or 3% to 5% or 3% to 4%. In other embodiments, the ductility of the coating can be 4% to 10% or 4% to 9% or 4% to 8% or 4% to 7% or 4% to 6% or 4% to 5%. In additional embodiments, the ductility of the coating can be 5% to 10% or 5% to 9% or 5% to 8% or 5% to 7% or 5% to 6%. Depending on the materials used, the ductility can exceed 10% for certain coatings including the materials described herein. Increased ductility allows the coatings herein to be used on parts which can be formed into shapes after the coatings have been deposited on the substrates while reducing the risk of compromising the coated surface from the shaping process.

In certain embodiments, the coatings described herein do not impose a hydrogen embrittlement issue. In some instances, hydrogen-induced cracking of the coatings is not observed after exposure to a hydrogen environment. For example, hydrogen embrittlement can be tested according to ASTM F519-18. In certain embodiment, the coatings described herein do not cause hydrogen embrittlement and do not require special bake-relief treatment to avoid such hydrogen embrittlement. In contrast, many hard chrome coatings are susceptible to hydrogen embrittlement and require a bake-relief process within 1-3 hours of plating to avoid hydrogen embrittlement. It is important to note that hydrogen embrittlement also depends on the pre-treatment process in addition to the plating process. Depending on the pre-treatment process, hydrogen embrittlement may occur in the coating regardless of the plating process. Therefore, bake relief is always recommended as a safety measure for all coatings.

The coatings described herein can provide for longer part lifetimes due to the increased wear resistance of the coatings. Wear resistance is typically measured by cycling the parts in an environment simulating continued use. For example and for illustration purposes only, the part can be cycled in its use environment or exposed to a use environment to simulate wear of the part. The particular movement of one part relative to another depends on the intended use of the article that includes the coating. In comparison to the coatings described herein, the wear resistance of hard chrome coatings generally reduces at higher temperatures. For example, hard chrome coatings can exhibit more wear after heat treatment, whereas the coatings described herein generally become more wear resistant after heat treatment. This result permits the coatings described herein to be used in high temperature environments where hard chrome coatings may not be suitable.

In certain embodiments, the friction coefficients of the coatings described herein are comparable or better than friction coefficients of hard chrome coatings. One method to measure frictional coefficients or wear is the ASTM G99-17 test. The test generally uses a hard ball that applies a force onto a surface during rotation of the surface. Lower frictional coefficients generally provide lower wear to the parts including the coatings. The coatings described herein can have a frictional coefficient of 0.10 or less as tested by ASTM G 99-17.

In some embodiments, the ASTM G99-17 test can also be used to measure wear in the presence and absence of a lubricant if desired. In a certain embodiment, the wear rate of hard chrome coatings (in the absence of any lubricant on the surface) may exceed 600×10⁻⁵ mm³/m under the ASTM G99 test, whereas the coatings described herein can have a wear resistance (in the absence of any lubricant on the surface) that is less than 100×10⁻⁵ mm³/m under the ASTM G99 test or less than 75×10⁻⁵ mm³/m under the ASTM G99 test or less than 50×10⁻⁵ mm³/m under the ASTM G99 test or less than 25×10⁻⁵ mm³/m under the ASTM G99 test. In some embodiments, the disk wear rate under ASTM G99 test may be less than 10×10⁻⁵ mm³/m under the ASTM G99 test or even less than 5×10⁻⁵ mm³/m under the ASTM G99 test. For example, the disk wear resistance rate may be between 0 and 5×10⁻⁵ mm³/m under the ASTM G99 test or between 1×10⁻⁵ mm³/m and 5×10⁻⁵ mm³/m under the ASTM G99 test.

In certain configurations, the coatings described herein can have a higher adherence to underlying substrates or underlying layers compared to a hard chrome coating. Higher adherence can often lead to improved wear resistance and better corrosion resistance. Adherence can be measured according to ASTM B571-18. In general, the coatings described herein can pass the adhesion test such that no material is transferred from the surface to the test tape used in the ASTM B571-18 test.

In certain embodiments, the coatings described herein can be more environmentally friendly. In some embodiments, the coatings can be free of lead. In other embodiments, the coatings can be free of cadmium. In additional embodiments, the coatings can be free of mercury. In some embodiments, the coatings can be free of chromium VI. In other embodiments, the coatings described herein can be free of fluoro compounds, e.g., PFAS or PFOS. In other embodiments, the coatings can be free of lead, cadmium, mercury, chromium VI and fluoro compounds.

The coatings described herein need not include all the performance properties described above but can include one or more of these attributes depending on the composition and the intended use of the part including the coating.

Certain layers or coatings are described with reference to weight percentages. The weight percentages can be based on weight of the layer or the entire coating. In some embodiments, one metal in a layer is present at 20% by weight or less in the layer, e.g., is present at 19%, 18%, 17%, 16%, 15%, 14%, 13%, 12%, 10%, 9%, 8%, 7%, 6%, 5%, 4%, 3%, 2%, 1% or less by weight in the layer or in the coating. For example, one or more of molybdenum, tungsten or cobalt can be present in the layer or in the coating at 20%, 19%, 18%, 17%, 16%, 15%, 14%, 13%, 12%, 10%, 9%, 8%, 7%, 6%, 5%, 4%, 3%, 2%, 1% or less in the layer or the coating. In other configurations, one or more of the layers can include a metal in a layer that is present at 80% by weight or more, e.g., is present at 81%, 82%, 83%, 84%, 85%, 85%, 87%, 88%, 89%, 90%, 91%, 92%, 93%, 94%, 95%, 96%, 97%, 98%, 99% or more by weight in the layer or in the coating. For example, nickel can be present in the layer or in the coating at 80%, 81%, 82%, 83%, 84%, 85%, 85%, 87%, 88%, 89%, 90%, 91%, 92%, 93%, 94%, 95%, 96%, 97%, 98%, 99% or more by weight in the layer or in the coating.

In certain embodiments, the substrate can include one or more layers as described below in connection with FIGS. 1-12. Specific articles or devices including the substrate and/or other layers are also described. The exact material or materials in the surface coating may vary. In some configurations, the surface coating comprises one or more metals. In some embodiments, the surface coating may include a metal alloy, e.g., an alloy comprising two or more metals. In some embodiments, the surface coating comprises a metal alloy including only two metals or a metal and another material. In certain embodiments, the surface coating comprises a metal alloy including only three metals or a metal and two other materials. In other embodiments, the surface coating may contain only a single layer formed on the substrate. For example, the single layer can be exposed to the environment to protect the underlying substrate from degradation. In some instances, the surface coating may contain only a first layer formed on the substrate and a second layer formed on the first layer.

In some embodiments, the alloy layer may “consist essentially of” two or more materials. The phrase “consists essentially of” or “consisting essentially of” is intended to refer to the specified materials and only minor impurities and those materials that do not materially affect the basic characteristic(s) of the configuration. The term “consists of” refers to only those materials and any impurities that cannot be removed through conventional purification techniques.

In certain embodiments, the alloy layers described herein can include one, two or more Group IV transition metals which include scandium, titanium, vanadium, chromium, manganese, iron, cobalt, nickel, copper and zinc.

In other configurations, the alloy layers described herein can include one, two or more Group V metals, which include yttrium, zirconium, niobium, ruthenium, rhodium, palladium, silver and cadmium.

In some configurations, the alloy layers described herein can include one, two or more Group VI metals, which include the non-radioactive lanthanides (La, Ce, Pr, Nd, Sm, Eu, Gd, Tb, Dy, Ho, Er, Tm, Yb and Lu), hafnium, tantalum, tungsten, rhenium, osmium, iridium, platinum, gold and mercury.

In other embodiments, the alloy layers described herein can include one, two or more Group VII metals, which include the non-radioactive actinides (Th, Pa, U).

In some instances, the alloy layers described herein can include one or more metals from the Group IV metals and one or more metals from the Group V metals or the Group VI metals or the Group VII metals.

In other instances, the alloy layers described herein can include one or more metals from the Group V metals and one or more metals from the Group VI metals or the Group VII metals.

In other examples, the alloy layers described herein can include one or more metals from the Group VI metals and one or more metals from the Group VII metals.

In some embodiments, the alloy layers described herein includes only two metals with one metal from the Group IV metals and the other metal from the Group V metals, the Group VI metals or Group VII metals.

In some embodiments, the alloy layers described herein includes only two metals with one metal from the Group V metals and the other metal from the Group VI metals or Group VII metals.

In other embodiments, the alloy layers described herein includes only two metals with one metal from the Group VI metals and the other metal from the Group VII metals.

In some examples, the alloy layers described herein includes only two metals with both metals being Group IV metals.

In some embodiments, the alloy layers described herein includes only two metals with both metals being Group V metals.

In some embodiments, the alloy layers described herein includes only two metals with both metals being Group VI metals.

In some embodiments, the alloy layers described herein includes only two metals with both metals being Group VII metals.

If desired, the alloy layers described herein can also include Group II materials (Li, Be, B and C) or Group III materials (Na, Mg, Al, Si, P, and S) in addition to, or in place, of the other metals. These materials may be present in combination with one, two, three or more metals.

In some embodiments, the alloy layer described herein comprises molybdenum and one or more additional metals, e.g., one or more additional metals selected from the group consisting of Group IV metals, Group V metals, Group VI metals and Group VII metals. In certain embodiments, the metal alloy comprises molybdenum and only one additional metal, e.g., only one additional metal selected from the group consisting of Group IV metals, Group V metals, Group VI metals and Group VII metals. In certain embodiments, the metal alloy comprises molybdenum and only two additional metals or materials, e.g., only two additional metals or materials selected from the group consisting of Group IV metals, Group V metals, Group VI metals, Group VII metals, Group II materials and Group III materials. In some embodiments, the surface coating has a single layer formed on the substrate, where the single layer comprises molybdenum and one or more additional metals, e.g., one or more additional metals selected from the group consisting of Group IV metals, Group V metals, Group VI metals and Group VII metals. In certain embodiments, the surface coating has a single layer formed on the substrate, where the single layer comprises molybdenum and only one additional metal, e.g., only one additional metal selected from the group consisting of Group IV metals, Group V metals, Group VI metals and Group VII metals. In some examples, the surface coating has a single layer formed on the substrate, where the single layer comprises molybdenum and only two additional metals or materials, e.g., only two additional metal or material selected from the group consisting of Group IV metals, Group V metals, Group VI metals, Group VII metals, Group II materials and Group III materials.

In some embodiments, the alloy layer described herein comprises tungsten and one or more additional metals, e.g., one or more additional metals selected from the group consisting of Group IV metals, Group V metals, Group VI metals and Group VII metals. In certain embodiments, the metal alloy comprises tungsten and only one additional metal, e.g., only one additional metal selected from the group consisting of Group IV metals, Group V metals, Group VI metals and Group VII metals. In certain embodiments, the metal alloy comprises tungsten and only two additional metals or materials, e.g., only two additional metals or materials selected from the group consisting of Group IV metals, Group V metals, Group VI metals, Group VII metals, Group II materials and Group III materials. In some embodiments, the surface coating has a single layer formed on the substrate, where the single layer comprises tungsten and one or more additional metals, e.g., one or more additional metals selected from the group consisting of Group IV metals, Group V metals, Group VI metals and Group VII metals. In certain embodiments, the surface coating has a single layer formed on the substrate, where the single layer comprises tungsten and only one additional metal, e.g., only one additional metal selected from the group consisting of Group IV metals, Group V metals, Group VI metals and Group VII metals. In some examples, the surface coating has a single layer formed on the substrate, where the single layer comprises tungsten and only two additional metals or materials, e.g., only two additional metal or material selected from the group consisting of Group IV metals, Group V metals, Group VI metals, Group VII metals, Group II materials and Group III materials.

In some embodiments, the alloy layer described herein comprises nickel and one or more additional metals, e.g., one or more additional metals selected from the group consisting of Group IV metals, Group V metals, Group VI metals and Group VII metals. In certain embodiments, the metal alloy comprises nickel and only one additional metal, e.g., only one additional metal selected from the group consisting of Group IV metals, Group V metals, Group VI metals and Group VII metals. In certain embodiments, the metal alloy comprises nickel and only two additional metals or materials, e.g., only two additional metals or materials selected from the group consisting of Group IV metals, Group V metals, Group VI metals, Group VII metals, Group II materials and Group III materials. In some embodiments, the surface coating has a single layer formed on the substrate, where the single layer comprises nickel and one or more additional metals, e.g., one or more additional metals selected from the group consisting of Group IV metals, Group V metals, Group VI metals and Group VII metals. In certain embodiments, the surface coating has a single layer formed on the substrate, where the single layer comprises nickel and only one additional metal, e.g., only one additional metal selected from the group consisting of Group IV metals, Group V metals, Group VI metals and Group VII metals. In some examples, the surface coating has a single layer formed on the substrate, where the single layer comprises nickel and only two additional metals or materials, e.g., only two additional metal or material selected from the group consisting of Group IV metals, Group V metals, Group VI metals, Group VII metals, Group II materials and Group III materials.

In certain configurations, the alloy layer comprises (i) molybdenum and (ii) at least one element selected from the group consisting of nickel, tungsten, cobalt, chromium, tin, phosphorous, iron, magnesium and boron or at least one compound comprising one or more of nickel, tungsten, cobalt, chromium, tin, phosphorous, iron, magnesium or boron. In certain embodiments, the alloy excludes precious metals.

In certain configurations, the alloy layer described herein comprises two or more of nickel, molybdenum, copper, phosphorous, boron, boron nitride, silicon carbide, aluminum oxide, molybdenum disulfide, carbon fibers, carbon nanotubes, particles, cobalt, tungsten, gold, platinum, silver, or alloys or combinations thereof.

In other embodiments, the alloy layer described herein includes two or more of nickel, molybdenum, copper, phosphorous, boron, boron nitride, silicon carbide, aluminum oxide, molybdenum disulfide, carbon fibers, carbon nanotubes, particles, cobalt, tungsten, gold, platinum, silver, or alloys or combinations thereof.

In certain embodiments, the alloy layer described herein comprises an alloy of (i) molybdenum, molybdenum oxide or other compounds of molybdenum, and (ii) a transition metal, transition metal oxide or other compounds of a transition metal.

In certain embodiments, the alloy layer described herein includes only two metals from (i) molybdenum, molybdenum oxide or other compounds of molybdenum, and (ii) a transition metal, transition metal oxide or other compounds of a transition metal.

In certain embodiments, the metal alloy of the layers described herein includes only two metals from (i) tungsten, tungsten oxide or other compounds of tungsten, and (ii) a transition metal, transition metal oxide or other compounds of a transition metal.

In certain embodiments, the alloy layer described herein includes only two metals from (i) nickel, nickel oxide or other compounds of nickel, and (ii) a transition metal, transition metal oxide or other compounds of a transition metal. In some embodiments, the transition metal, transition metal oxide or other compounds of the transition metal comprises scandium, manganese, iron, cobalt, nickel, copper, zinc, yttrium, technetium, silver, cadmium, lanthanum, platinum, gold, mercury, actinium, and combinations thereof. For example, the metal alloy coating can include a Ni—Mo alloy, a Ni—W alloy or only have a Ni—Mo alloy or a Ni—W alloy.

In certain embodiments, the alloy layer exhibits at least two times more corrosion resistance compared to a chrome coating according to an ASTM B117 salt spray corrosion test. In some embodiments, the metal alloy layer does not exhibit hydrogen embrittlement as tested by an ASTM F519 standard.

In embodiments where the alloy layer includes molybdenum, molybdenum oxide or other compounds of molybdenum, these materials can be present in the metal alloy coating at 35% by weight or less (or 25% by weight or less) based on a weight of the alloy layer or the weight of the surface coating. In some other cases where the metal alloy layer includes molybdenum, molybdenum oxide or other compounds of molybdenum, these materials can be present in the metal alloy coating at 48% by weight or less based on a weight of the alloy layer or the surface coating.

In some instances, the alloy layer may consist of a single layer. In other configurations, two or more layers may be present in a surface coating. As noted herein, the two layers may comprise the same or different materials. When the materials are the same, the materials may be present in different amounts in the two layers or may be deposited in different layers using different processes.

In some embodiments, the alloy layer can include an alloy of molybdenum, e.g., molybdenum in combination with one or more of nickel, chromium, carbon, cobalt, tin, tungsten, aluminum, vanadium, titanium, niobium, iron, boron, phosphorous, magnesium or copper. For example, molybdenum may be present at 35% by weight or less and the other component can be present at 65% by weight or more. More than two components or metals may be present if desired. In other embodiments, the surface coating can include an alloy of molybdenum and one other metal or material, e.g., molybdenum in combination with only one of nickel, chromium, carbon, cobalt, tin, tungsten, aluminum, vanadium, titanium, niobium, iron, boron, phosphorous, magnesium or copper. In some embodiments, the surface coating can include an alloy of molybdenum and two other metals, e.g., molybdenum in combination with only two of nickel, chromium, carbon, cobalt, tin, tungsten, aluminum, vanadium, titanium, niobium, iron, boron, phosphorous, magnesium or copper.

In some embodiments, the alloy layer can include an alloy of tungsten, e.g., tungsten in combination with one or more of nickel, molybdenum, chromium, carbon, cobalt, tin, aluminum, vanadium, titanium, niobium, iron, boron, phosphorous, magnesium or copper. In other embodiments, the surface coating can include an alloy of tungsten and one other metal or material, e.g., tungsten in combination with only one of nickel, molybdenum, chromium, carbon, cobalt, tin, aluminum, vanadium, titanium, niobium, iron, boron, phosphorous, magnesium or copper. In some embodiments, the surface coating can include an alloy of tungsten and two other metals, e.g., tungsten in combination with only two of nickel, molybdenum, chromium, carbon, cobalt, tin, aluminum, vanadium, titanium, niobium, iron, boron, phosphorous, magnesium or copper. In some embodiments, the surface coating can include an alloy of tungsten, e.g., tungsten in combination with one or more of chromium, molybdenum, carbon, cobalt, tin, aluminum, vanadium, titanium, niobium, iron, boron, phosphorous, magnesium or copper. For example, tungsten may be present at 35% by weight or less and the other component can be present at 65% by weight or more. More than two components or metals may be present if desired. In other embodiments, the surface coating can include an alloy of tungsten and one or two other metals or materials, e.g., tungsten in combination with only one of nickel, molybdenum, chromium, carbon, cobalt, tin, aluminum, vanadium, titanium, niobium, iron, boron, phosphorous, magnesium or copper. In some embodiments, the surface coating can include an alloy of tungsten and two other metals, e.g., tungsten in combination with only two of nickel, molybdenum, chromium, carbon, cobalt, tin, aluminum, vanadium, titanium, niobium, iron, boron, phosphorous, magnesium or In some embodiments, the surface coatings described herein may provide desirable performance criteria including, but not limited to, a certain surface roughness (Ra) as described in the ISO 4287 and ISO 4288 standards. Roughness can be measured, for example, using a profilometer. Coating thickness may also be measured using a non-destructive technique such as a magnetic measurement tool, XRF, or sampling and destructive technique such as cross-section analysis. The exact surface roughness (Ra) may vary, for example, and may be equal to or less than 1 micron or can be between 0.1 microns and 1 micron. The devices may also have a desired coefficient of friction (CoF). This property generally depends on both the surfaces worn against each other and the fluid located between them. The roughness of each surface, the viscosity of the fluid, and the temperature of the test can impact coefficient of friction measurements. CoF can be measured, for example, according to ASTM G99-17 or a block on ring test as specified in ASTM G77-17. The coating, or one or more layers of the coating, may provide a specific hardness as tested by ASTM E 384-17. For example, the coating may have a hardness higher than 600 Vickers as measured per ASTM E384-17. Where the coating includes more than a single layer, any one or more of the layers have a hardness higher than 600 Vickers as measured per ASTM E 384-17. In some embodiments, an outer layer of the coating may have a hardness higher than 600 Vickers as measured per ASTM E384-17. In other embodiments where the coating has a hardness of 600 Vickers or higher as measured per ASTM E 384-17, one of the layers, when present by itself, may have a hardness less than 600 Vickers as measured per ASTM E 384-17.

While various layers and substrates are described below in reference to FIGS. 1-12 as having flat surfaces, a flat surface is not required and may not be desired in some instances. For example, a substrate (or any of the layers or both) may have a rough surface or be roughened purposefully or be smoothed purposefully as desired. As an example, the substrate may have a textured surface including transferring texture which a partial or complete replica of the transferring texture shall be transferred to the other objects that come in contact with such a surface with transferring texture. In an embodiment, such a surface can be a part of an article or device that during use or movement contacts another material. For example, a steel work roll used in cold rolling processes where the surface of the work roll has certain transferring texture that can be transferred to the steel sheet during the rolling process. Another example is the steel work roll described in the previous embodiment where the transferring texture is made using electrical discharge texturing (EDT). Another embodiment is a work roll used in hot rolling processes. In another embodiment, a transferring texture can be a part of a mold which is designed to transfer the texture to another object. In an embodiment, the texture is transferred to a metal. In an embodiment, the texture is transferred to a polymer. In an embodiment, the texture is transferred to a molten metal which solidified afterward. In an embodiment, the texture is transferred to a liquid or fluid which solidified afterward.

In another embodiment the surface may have an adhesive roughness designed to increase the adhesion between such a surface and another surface or a coating applied on top. In an embodiment, the adhesive texture is used to increase the adhesion of the substrate to the thermal spray coatings. In another embodiment, the adhesive texture is used to increase the adhesion of a coating comprising tungsten the surface. In another embodiment, the adhesive layer is used to increase the adhesion of a coating comparing one or combination of nitride, a nitride, a metal carbide, a carbide, a boride, tungsten, tungsten carbide, a tungsten alloy, a tungsten compound, a stainless steel, a ceramic, chromium, chromium carbide, chromium oxide, a chromium compound, aluminum oxide, zirconia, titania, nickel, a nickel carbide, a nickel oxide, a nickel alloy, a cobalt compound, a cobalt alloy, a cobalt phosphorous alloy, molybdenum, a molybdenum compound, a nanocomposite, an oxide composite.

In another embodiment, the roughness is added to impact the light reflection. In an embodiment, the surface roughness is altered to have less roughness. In an embodiment, the surface roughness, Ra, may be altered to be less than 1 um. In another embodiment, the surface roughness is altered to be less than 0.5 um. In an embodiment, the surface with altered roughness is shiny. In another embodiment, the surface with altered roughness is exposed and is required to be touched by human. In another embodiment, the surface reflects less light and becomes less shiny. In an embodiment, the contact angle of water on the surface with altered roughness is less than the original surface.

In certain embodiments, the roughness may have irregular shapes or respective patterns. In certain embodiments, the roughness of the surfaces with coating, Ra, is less than 1 um. In another embodiment, the roughness of the surfaces with coating, Ra, is more than 1 um and less than 10 um. In another embodiments, the roughness of the surfaces with coating, Ra, is more than 10 um and less than 100 um, in another embodiment the Ra of the surfaces is less than 0.7. In some embodiments, the Ra is less than 0.5 um and more than 0.05 um. In another embodiments the Ra is less than 0.5 um. In another embodiment, the Ra is less than 0.4 um. In another embodiment, the Ra is less than 0.3 um. In another embodiment, the Ra is less than 0.2 um. In another embodiment, the Ra is less than 0.1 um. In another embodiment, the patterns are made using grinding, blasting, sand blasting, abrasive blasting, sandblasting, burnishing, grinding, honing, mass finishing, tumble finishing, vibratory finishing, polishing, buffing, lapping, electrochemical etching, chemical etching, laser etching, laser patterning, or other methods. In another method, the surface is textured using shot blasting (SB), laser beam texturing (LBT) and electrical discharge texturing (EDT) or electron beam texturing (EBT) is being evaluated. Electrical discharge texturing (EDT) can be used on steel substrate to create textures. Textures may be formed using an electrodeposition techniques. Textures may be formed using thermal spray techniques. Cross section of the patterns may have specific geometries such as rectangles, triangles, stars, circles or a combinations of thereof. The patterns may be in the shape of ridges, pillars, spirals, a combination of thereof or other shapes. The Ra may be larger than 100 um. The patterns may be created using cutting, milling, molding and or other tools.

Certain embodiments are described in more detail below with reference to coatings or layers. The coatings or layers may include a single material, a combination of materials, an alloy, composites, or other materials and compositions as noted herein. In embodiments where the layer refers to a metal alloy, the metal alloy can include two or more materials, e.g., two or more metals. In some configurations, one metal may be present at 79% by weight or more in the layer and the other material may be present at 21% by weight or less in the layer. For example, one of the layers described herein can include a molybdenum alloy, a tungsten alloy or a nickel alloy. One of the materials may be present at 79% by weight or more in the layer and the other material(s) may be present at 21% by weight or less in the layer. Where the metal alloy includes molybdenum, the molybdenum can be present at 21% by weight or less or 79% by weight or more in the layer and the other material(s) may be present so the sum of the weight percentages add to 100 weight percent. Alternatively, the other material(s) can be present at 79% by weight or more in the layer and the molybdenum may be present at 21% by weight or less in the layer. One or may layers can also include another metal or a metal alloy. There may also be minor impurities present that add negligible weight to the overall alloy layer or surface coating.

The exact amount of each material present may be selected to provide a layer or article with desired performance specifications. The weight percentages can be based on weight of the alloy layer or the entire surface coating. In some embodiments, one metal in a layer is present at 35% by weight or less in the layer, e.g., is present at 34%, 33%, 32%, 31%, 30%, 29%, 28%, 27%, 26%, 25%, 24%, 23%, 22%, 21%, 20%, 19%, 18%, 17%, 16%, 15%, 14%, 13%, 12%, 10%, 9%, 8%, 7%, 6%, 5%, 4%, 3%, 2%, 1% or less by weight in the layer or in the coating. For example, one or more of molybdenum, tungsten or cobalt can be present in the layer or in the coating at 35% by weight or less, e.g., 25%, 24%, 23%, 33%, 31%, 20%, 19%, 18%, 17%, 16%, 15%, 14%, 13%, 12%, 10%, 9%, 8%, 7%, 6%, 5%, 4%, 3%, 2%, 1% or less in the layer or the coating. In other configurations, one or more of the layers can include a metal in a layer that is present at 65% by weight or more, e.g., is present at 65%, 70%, 75%, 80%, 81%, 82%, 83%, 84%, 85%, 85%, 87%, 88%, 89%, 90%, 91%, 92%, 93%, 94%, 95%, 96%, 97%, 98%, 99% or more by weight in the layer or in the coating. For example, nickel can be present in the layer or in the coating at 65%, 70%, 75%, 80%, 81%, 82%, 83%, 84%, 85%, 85%, 87%, 88%, 89%, 90%, 91%, 92%, 93%, 94%, 95%, 96%, 97%, 98%, 99% or more by weight of the alloy layer or the surface coating. Alternatively, molybdenum can be present in the layer or in the coating at 65%, 70%, 75%, 80%, 81%, 82%, 83%, 84%, 85%, 85%, 87%, 88%, 89%, 90%, 91%, 92%, 93%, 94%, 95%, 96%, 97%, 98%, 99% or more by weight of the alloy layer or the surface coating.

In some embodiments, the alloy layers described herein may be present without any precious metals. The term “precious metals” refers to gold, silver, ruthenium, rhodium, palladium, osmium, iridium, and platinum. For example, the alloy layer (and/or the entire surface coating) can be free of (has none of) each of gold, silver, ruthenium, rhodium, palladium, osmium, iridium, and platinum. Omission of the precious metals can reduce overall cost.

In certain embodiments, where nickel is present in a metal alloy layer, the nickel can be present without any tungsten or cobalt in that same layer. For example, where a layer comprises a nickel alloy, the layer has neither of tungsten or cobalt, e.g., 0% by weight of the cobalt or tungsten is present. That layer may also have 0% by weight precious metals.

In certain examples, the alloy layers can include non-metal materials and additives as desired. For example, particles, nanoparticles, nanomaterials or other materials that include one or more of polytetrafluoroethylene (PTFE), SiC, SiO₂, diamond, graphite, graphene, boron, boride, functionalized silicon particles, fluorosilicone, siloxanes, TiO₂, nanotubes and nanostructures may be present in the metal alloy layer. Additional materials are described in more detail below.

In some examples, one of the metals of the layers described herein is nickel. For example, nickel, nickel alloys, nickel compounds, nickel composites, a nickel-phosphorous alloy, a nickel-molybdenum alloy, a nickel-molybdenum-phosphorous alloy, a nickel-cobalt alloy, a nickel-tungsten alloy, a nickel-cobalt-phosphorus alloy, a nickel-tungsten-phosphorous alloy, a nickel alloy containing only nickel and molybdenum, nickel alloys including at least nickel and a transition metal, nickel alloys including at least two metals other than any precious metals, a nickel alloy including at least nickel and a refractory metal other than any precious metals, a nickel alloy including at least nickel and a refractory metal excluding tungsten, a nickel alloy including at least nickel and a refractory metal excluding tungsten and any precious metals, a nickel alloy including at least nickel and a excluding cobalt and any precious metals, a composite alloy containing nickel and particles, a composite alloy containing nickel and nanoparticles, a composite alloy containing nickel and SiO₂, SiC or other silicon compounds, a composite alloy containing nickel and boride, brome nitride or other boron compounds, a composite alloy containing nickel and PTFE or other fluorine compounds, a composite alloy containing nickel, molybdenum and chrome, chromium carbide, chromium oxide or other chrome compounds may be present in one or more of the layers described herein.

In certain embodiments, one of the metals of the alloy layers described herein is molybdenum. For example, molybdenum, a molybdenum alloy, molybdenum composite, a molybdenum-tin alloy, an alloy containing at least molybdenum and nickel, an alloy containing at least molybdenum and tin, an alloy containing at least molybdenum and cobalt, an alloy containing at least molybdenum and phosphorous, an alloy containing only nickel and molybdenum, an alloy containing only tin and molybdenum, an alloy containing only cobalt and molybdenum, an alloy containing only nickel, molybdenum and phosphorous, a molybdenum alloy including at least two metals other than precious metals, a molybdenum alloy including at least molybdenum and a transition metal, a molybdenum alloy including at least molybdenum and a transition metal other than precious metals, a molybdenum alloy including at least two metals excluding substances of very high concern under European law, a composite alloy including molybdenum and particles, a composite alloy including molybdenum and soft particles, a composite alloy including molybdenum and nanoparticles, a composite alloy containing molybdenum and SiO₂, SiC or other silicon compounds, a composite alloy containing molybdenum and boride, brome nitride or other boron compounds, a composite alloy containing molybdenum and PTFE or other fluorine compounds, a composite alloy containing molybdenum and chrome, chromium carbide, chromium oxide or other chrome compounds may be present in one or more of the layers described herein.

In another embodiment, one of the metals of the alloy layers described herein is cobalt. For example, cobalt, cobalt alloys, cobalt compounds, cobalt composites, a cobalt-phosphorous alloy, a cobalt-molybdenum alloy, a cobalt-molybdenum-phosphorous alloy, a cobalt-tungsten alloy, a cobalt-tungsten-phosphorous alloy, cobalt alloy containing only cobalt and molybdenum, cobalt alloys including at least cobalt and a transition metal, cobalt alloys including at least two metals excluding precious metals, a cobalt alloy including at least cobalt and a refractory metal excluding precious metals, a cobalt alloy including at least cobalt and a refractory metal excluding tungsten, a cobalt alloy including at least cobalt and a refractory metal excluding tungsten and precious metals, a cobalt alloy including at least cobalt and excluding nickel and precious metals, a composite alloy containing cobalt and particles, a composite alloy containing cobalt and nanoparticles, a composite alloy containing cobalt and SiO₂, SiC or other silicon compounds, a composite alloy containing cobalt and boride, brome nitride or other boron compounds, a composite alloy containing cobalt and PTFE or other fluorine compounds, a composite alloy containing cobalt, molybdenum and chrome, chromium carbide, chromium oxide or other chrome compounds.

In some embodiments, one of the metals of the alloy layers described herein is tin. For example, tin, tin alloys, tin compounds, tin composites, a tin-phosphorous alloy, a tin-molybdenum alloy, a tin-molybdenum-phosphorous alloy, a tin-tungsten alloy, a tin-tungsten-phosphorous alloy, a tin alloy containing only tin and molybdenum, tin alloys including at least tin and a transition metal, tin alloys including at least two metals excluding precious metals, a tin alloy including at least tin and a refractory metal excluding precious metals, a tin alloy including at least tin and a refractory metal excluding tungsten, a tin alloy including at least tin and a refractory metal excluding tungsten and precious metals, a tin alloy including at least tin and excluding nickel and precious metals, a composite alloy containing tin and particles, a composite alloy containing tin and nanoparticles, a composite alloy containing tin and SiO₂, SiC or other silicon compounds, a composite alloy containing tin and boride, brome nitride or other boron compounds, a composite alloy containing tin and PTFE or other fluorine compounds, a composite alloy containing tin, molybdenum and chrome, chromium carbide, chromium oxide or other chrome compounds.

In another embodiment, one of the metals of the alloy layers described herein is tungsten. For example, tungsten, tungsten alloys, tungsten compounds, tungsten composites, a tungsten-phosphorous alloy, a tungsten-molybdenum alloy, a tungsten-molybdenum-phosphorous alloy, a tungsten alloy containing only tungsten and molybdenum, a tungsten alloy including at least tungsten and a transition metal, a tungsten alloy including at least two metals excluding precious metals, a tungsten alloy including at least tungsten and a refractory metal excluding precious metals, a tungsten alloy including at least tungsten and excluding nickel and precious metals, a composite alloy containing tungsten and particles, a composite alloy containing tungsten and nanoparticles, a composite alloy containing tungsten and SiO₂, SiC or other silicon compounds, a composite alloys containing tungsten and boride, brome nitride or other boron compounds, a composite alloy containing tungsten and PTFE or other fluorine compounds, a composite alloy containing tungsten, molybdenum and chrome, chromium carbide, chromium oxide or other chrome compounds.

In certain embodiments, one or more of the alloy layers described herein may be considered a “hard” layer. The hard layer typically has a Vickers hardness higher than the substrate and/or any underlying layers. While not required, the hard layer is typically present as an outer layer. In some embodiments, the hard layer may comprise one or more of a nitride, a metal nitride, a carbide, a metal carbide, a boride, a metal boride, tungsten, tungsten carbide, a tungsten alloy, a tungsten compound, a stainless steel, a ceramic, chromium, chromium carbide, chromium oxide, a chromium compound, aluminum oxide, zirconia, titania, nickel, a nickel carbide, a nickel oxide, a nickel alloy, a cobalt compound, a cobalt alloy, a cobalt phosphorous alloy, molybdenum, a molybdenum compound, a nanocomposite, an oxide composite, or combinations thereof.

In certain embodiments, a simplified illustration of a substrate and an alloy layer of a surface coating is shown in FIG. 1. An article or device 100 includes a substrate 105 (which is shown as a section in FIG. 1) and a first layer 110 on a first surface 106 of the substrate 105. While not shown, a layer or coating may also be present on surfaces 107, 108 and 109 of the substrate 105. The layer 110 is shown in FIG. 1 as a solid layer with uniform thickness present across the surface 106 of the substrate 105. This configuration is not required, and different areas of the layer 110 may include different thicknesses or even different materials. Further, certain areas of the surface 106 may not include any surface coating at all. In some embodiments, the substrate 105 may be, or may include, a metal material including, but not limited to, steel (carbon steel, tool steel, stainless steel, etc.), copper, copper alloys, aluminum, aluminum alloys, chromium, chromium alloys, nickel, nickel alloys, titanium, titanium alloys, nickel-chromium superalloys, nickel-molybdenum alloys, brass, Hastelloy, Inconel, Nichrome, Monel, other substrates that include at least one metal or substrates that are nitrided or carburized. In some embodiments, the substrate may be porous or may be non-porous. The layer 110 typically includes one or more metals or two or more metals or three or more metals or materials. For example, the layer 110 can be a metal alloy formed from two or more metals. In some embodiments, the layer 110 is an alloy layer formed from only two metals or two materials. In some examples, the layer 110 is the only layer present in the surface coating. In certain examples, the layer 110 is an outer or exposed layer such that the layer can contact surrounding fluid or other materials and protect the underlying substrate 105 and any layers between the layer 110 and the substrate 105.

In some embodiments, one of the metals in the layer 110 is nickel. In other embodiments, one of the metals in the layer 110 is molybdenum. In other embodiments, one of the metals in the layer 110 is tungsten. In other embodiments, one of the metals in the layer 110 is cobalt. In an additional embodiment, one of the metals in the layer 110 is molybdenum in the form of a molybdenum alloy. In other embodiments, the layer 110 can include a nickel alloy, a molybdenum alloy, a cobalt alloy, a tungsten alloy, or combinations thereof. In other examples, the layer 110 may be a nickel molybdenum alloy. In certain configurations, the layer 110 may consist of a nickel molybdenum alloy with no other materials being present in the layer 110. In some configurations, the layer 110 may comprise a nickel molybdenum phosphorous alloy. In some configurations, the layer 110 may consist of a nickel molybdenum phosphorous alloy with no other materials being present in the layer 110.

In some configurations, the exact thickness of the layer 110 may vary 1 micron to about 2 mm depending on the device where the layer 110 is present. For example, the layer 110 may have a thickness from about 5 microns to about 1 mm or about 7 microns to about 900 microns. Where multiple layers are present in a surface coating each layer may have a thickness from 1 micron to about 2 mm or the total thickness of all layers may be about 1 micron to about 2 mm.

In certain embodiments, the layer 110 can also include other materials, e.g., particles, fibers, non-metals (for example, phosphorous, boron, boron nitride, silicon compounds such as silicon dioxide, silicon carbide, etc.), aluminum oxide, molybdenum disulfide, carbon fibers, carbon nanotubes, cobalt, tungsten, tin, gold, platinum, silver and combinations thereof. The particles can be soft particles such as polymer particles, PTFE particles, fluoropolymers, and other soft particles. The particles can be hard particles such as diamond, boron, boron nitride, silicon compounds such as silicon dioxide, silicon carbide, etc. The particles can be hydrophobic or hydrophilic. Hydrophobic particles such PTFE particles, Teflon particles, Fluoropolymers, silicon base particles, hard particles functionalized in hydrophobic, hydrophilic or both groups. Such as silicon dioxide or silicon carbide functionalized in fluoro-compounds, molecules containing florin, silicon compounds, molecules containing silicon, and other polymers. Other particles such as titanium dioxide, and other catalyst may be used as well either functionalized or as is.

In other configurations, the layer 110 can include a nickel molybdenum alloy, a nickel molybdenum alloy where a weight percentage of the molybdenum is less than 35% by weight, a nickel molybdenum phosphorous alloy where a weight percentage of the molybdenum is less than 35% by weight, a ductile alloy of a refractory metal with nickel, a ductile alloy of nickel and molybdenum, a brittle alloy of a refractory metal with nickel, a ductile alloy of nickel and molybdenum, a brittle alloy of a transition metal with molybdenum, a ductile alloy of a transition metal with molybdenum, an alloy of nickel and molybdenum with a hardness less than 1100 and higher than 500 Vickers, a nickel molybdenum alloy that provides a surface roughness Ra less than 1 micrometer, a nickel molybdenum alloy with uniform and non-uniform grain sizes, a nickel molybdenum alloy with an average grain size less than 2 microns, a conformal nickel molybdenum alloy, an alloy of nickel, molybdenum and phosphorous, an alloy of cobalt and molybdenum, an alloy of cobalt and molybdenum and phosphorous, an alloy of nickel, molybdenum and tungsten, an alloy of nickel with a material having a less magnetic property than nickel, an alloy of molybdenum with a material having a less hardness than molybdenum, a conformal alloy of a refractory metal and nickel, a ductile alloy of nickel molybdenum, a ductile alloy of nickel tungsten, a brittle alloy of nickel tungsten, a ductile alloy of nickel cobalt, a brittle alloy of nickel cobalt, an alloy of nickel and a material with a higher temperature resistance than nickel, a nickel molybdenum alloy where it contains a third element including but not limited to a refractory metal, a precious metal, hard particles, soft particles, hydrophobic particles, hydrophilic particles, catalysis, a material more conductive than nickel, a material more conductive than molybdenum, a material softer than nickel, a material harder than nickel and less hard than molybdenum, or other compounds such as phosphorous, boron, boron nitride, silicon carbide, silicone oxide, aluminum oxide, molybdenum disulfide, hard particles with a hardness of HV greater than 750 Vickers, and/or hard particles with size less 1 micron, a nickel molybdenum alloy where it contains a third element including but not limited to a refractory metal, a precious metal, hard particles, a material more conductive than nickel, a material more conductive than molybdenum, a material softer than nickel, or other compounds such as phosphorous, boron, boron nitride, silicon carbide, silicone oxide, aluminum oxide, molybdenum disulfide, hard particles with a hardness of HV greater than 750 Vickers, and/or hard particles with size less 1 micron.

In some instances, the layer 110 on the substrate 105 can include a nickel tungsten alloy or a nickel tungsten alloy where it contains a third element including, but not limited to, an element that is a refractory metal, a precious metal, hard particles or other compounds such as phosphorous, boron, boron nitride, silicon carbide, aluminum oxide, molybdenum disulfide, hard particles with hardness of HV>750, hard particles with size less 500 nm, highly conductive particles, carbon nanotubes and/or carbon nano-particles. Combinations of these materials may also be present in the layer 110 on the substrate 105.

In some embodiments, a simplified illustration of another device is shown in FIG. 2. In this illustration, the article or the device 200 includes an intermediate layer 210 between the layer 110 and the underlying substrate 105. In some examples, the intermediate layer 210 can improve adhesion, can improve corrosion, can brighten the coating or any combination thereof. For example, nickel, nickel alloys, copper alloys, nickel compounds, nickel composites, nickel-phosphorous alloy, nickel-molybdenum alloy, nickel-molybdenum-phosphorous alloy, nickel-cobalt alloy, nickel-tungsten alloy, nickel-cobalt-phosphorus alloy, copper, nickel-tungsten-phosphorous alloy copper alloys, copper composites, tin, tin alloy, tin composite, cobalt, cobalt alloy, cobalt composite, cobalt-molybdenum alloy, cobalt-tungsten alloy, cobalt-molybdenum-phosphorous alloy, cobalt-tungsten-phosphorous alloy, molybdenum, molybdenum alloy, molybdenum composite, nickel alloys including at least two metals excluding precious metals, molybdenum alloy including at least two metals excluding precious metals, molybdenum alloy including at least molybdenum and a transition metal, molybdenum alloy including at least molybdenum and a transition metal excluding precious metals, metals tungsten alloys, nickel alloys including at least nickel and a refractory metal, nickel alloy including at least nickel and a refractory metal (excluding precious metals), molybdenum-tin alloy, tungsten alloys, tungsten composite, or other materials may be present as a layer 210, between the layer 110 and the substrate 105 to improve adhesion between the layer 110 and the layer 210. Such a layer can be less than 10 um, 9 um, 8 um, 7 um, 2 um, 1 um, 0.75 um, 0.5 um, or 0.25 um thick. As noted herein, in some instances, the layer 210 may be a strike layer, e.g., a nickel layer, added to the substrate 105 to improve adhesion between the substrate 105 and the layer 110.

In certain configurations, the layer 210 can function as a brightener to increase the overall shiny appearance of the article or device 200. A bright or semi-bright layer generally reflects a higher percentage of light than the layer 110. For example, nickel, nickel alloys, copper alloys, nickel compounds, nickel composites, nickel-phosphorous alloy, nickel-molybdenum alloy, nickel-molybdenum-phosphorous alloy, nickel-cobalt alloy, nickel-tungsten alloy, nickel-cobalt-phosphorus alloy, copper, nickel-tungsten-phosphorous alloy copper alloys, copper composites, tin, tin alloy, tin composite, cobalt, cobalt alloy, cobalt composite, cobalt-molybdenum alloy, cobalt-tungsten alloy, cobalt-molybdenum-phosphorous alloy, cobalt-tungsten-phosphorous alloy, molybdenum, molybdenum alloy, molybdenum composite, nickel alloys including at least two metals excluding precious metals, molybdenum alloy including at least two metals excluding precious metals, molybdenum alloy including at least molybdenum and a transition metal, molybdenum alloy including at least molybdenum and a transition metal excluding precious metals, metals tungsten alloys, nickel alloys including at least nickel and a transition metal, nickel alloy including at least nickel and a refractory metal excluding precious metals, tungsten alloys, tungsten composite, or other materials may be present as a layer 210, between the layer 110 and the substrate 105 to brighten the overall coating appearance.

In other configurations, the layer 210 can act to increase corrosion resistance of the article or device 200. For example, nickel, nickel alloys, copper alloys, nickel compounds, nickel composites, nickel-phosphorous alloy, nickel-molybdenum alloy, nickel-molybdenum-phosphorous alloy, nickel-cobalt alloy, nickel-tungsten alloy, nickel-cobalt-phosphorus alloy, copper, nickel-tungsten-phosphorous alloy copper alloys, copper composites, tin, tin alloy, tin composite, cobalt, cobalt alloy, cobalt composite, cobalt-molybdenum alloy, cobalt-tungsten alloy, cobalt-molybdenum-phosphorous alloy, cobalt-tungsten-phosphorous alloy, molybdenum, molybdenum alloy, molybdenum composite, molybdenum-tin alloys, alloy containing at least molybdenum and nickel, alloy containing at least molybdenum and tin, alloy containing at least molybdenum and cobalt, composites including molybdenum and particles, composites including molybdenum and soft particles, composites including molybdenum and nanoparticles, composites including molybdenum and hard particles, nickel alloys including at least two metals excluding precious metals, molybdenum alloy including at least two metals excluding precious metals, molybdenum alloy including at least molybdenum and a transition metal, molybdenum alloy including at least molybdenum and a transition metal excluding precious metals, tungsten alloys, nickel alloys including at least nickel and a transition metal, nickel alloy including at least nickel and a refractory metal excluding precious metals, nickel alloy including at least nickel and a refractory metal excluding tungsten, nickel alloy including at least nickel and a refractory metal excluding tungsten and precious metals, tungsten alloys, a tungsten composite, tungsten alloys excluding alloys containing both nickel and tungsten, chrome, chrome compounds, or other materials may be present as a layer 210, between the layer 110 and the substrate 105 to increase corrosion resistance.

In some embodiments, the substrate 105 used with the intermediate layer 210 may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate may be porous or may be non-porous. In certain embodiments, the layer 210 can include one or more materials selected from the group consisting of Group II materials, Group III materials, a Group IV metal, a Group V metal, a Group VI metal and a Group VII metal. In some examples, the layer 210 is free of any precious metals. In other instances, the layer 210 only includes a single metal but may include other non-metal materials.

In certain embodiments, the layer 110 used with the intermediate layer 210 typically includes one or more metals or two or more metals. For example, the layer 110 used with the intermediate layer 210 can include any of those materials and configurations described in reference to FIG. 1. For example, the layer 110 used with the layer 210 be a metal alloy formed from two or more metals. In some embodiments, one of the metals in the layer 110 used with the intermediate layer 210 is nickel. In other embodiments, one of the metals in the layer 110 used with the intermediate layer 210 is molybdenum. In an additional embodiment, one of the metals in the layer 110 used with the intermediate layer 210 is tungsten. In an additional embodiment, one of the metals in the layer 110 used with the intermediate layer 210 is cobalt. In an additional embodiment, one of the metals in the layer 110 used with the intermediate layer 210 is chrome. In some embodiments, the layer 110 used with the layer 210 can include only two metals or two materials or three metals or three materials. For example, the layer 110 used with the layer 210 can include only nickel and molybdenum or only nickel, molybdenum and phosphorous or only nickel and tungsten or only nickel and cobalt or only nickel, phosphorous and iron or only nickel and phosphorous.

In other embodiments, the layer 110 used with the intermediate layer 210 can include a nickel alloy, a molybdenum alloy, a tungsten alloy, a cobalt alloy, a chrome alloy, or combinations thereof. In other examples, the layer 110 used with the intermediate layer 210 may be a nickel, nickel-molybdenum alloy, nickel-cobalt alloy, nickel-tungsten alloy, nickel-phosphorous ally, cobalt, cobalt-molybdenum alloy, cobalt-tungsten alloy, cobalt-phosphorous alloy, nickel-molybdenum-phosphorous alloy, cobalt-molybdenum-phosphorous alloy, cobalt-tungsten-phosphorous alloy, chrome, chrome alloy, molybdenum-tin alloy, chrome compounds. In certain configurations, the layer 110 used with the intermediate layer 210 may consist of a nickel-molybdenum alloy with no other materials being present in the layer 110. In other configurations, the layer 110 used with the intermediate layer 210 may consist of a nickel-molybdenum-phosphorous alloy with no other materials being present in the layer 110. In other configurations, the layer 110 used with the intermediate layer 210 may consist of a cobalt-molybdenum alloy with no other materials being present in the layer 110. In other configurations, the layer 110 used with the intermediate layer 210 may consist of a cobalt-molybdenum-phosphorous alloy with no other materials being present in the layer 110. In other configurations, the layer 110 used with the intermediate layer 210 may consist of a nickel alloy including at least two metals excluding precious metals. In other configurations, the layer 110 used with the intermediate layer 210 may consist of a molybdenum alloy including at least two metals excluding precious metals. In other configurations, the layer 110 used with the intermediate layer 210 may consist of a molybdenum alloy including at least molybdenum and a transition metal. In other configurations, the layer 110 used with the intermediate layer 210 may consist of a molybdenum alloy including at least molybdenum and a transition metal excluding precious metals. The exact thickness of the layer 110 used with the intermediate layer 210 may vary from 1 micron to about 2 mm depending on the article where the layer 110 is present. For example, the layer 110 may be about 10 microns to about 200 microns thick. Similarly, a thickness of the intermediate layer 210 may vary from 0.1 micron to about 2 mm, e.g., about 1 micron to about 20 microns. The thickness of the layer 210 can be less than a thickness of the layer 110 or more than a thickness of the layer 110.

In another configuration, two or more layers may be present on an underlying substrate. Referring to FIG. 3, an article or device 300 is shown that includes a first layer 110 and a second layer 320 on a substrate 105. The ordering of the layers 110, 320 could be reversed, so the layer 320 is closer to the substrate 105 if desired. The layers 110, 320 can include the same or different materials or may include similar materials that have been deposited in a different manner or under different conditions. For example, the layers 110, 320 in FIG. 3 can independently be any of those materials described herein, e.g., any of those materials described in reference to the layers of FIG. 1 or FIG. 2. In some configurations, the layers 110, 320 can each be an alloy layer. For example, each of the layers 110, 320 can include one or more of nickel, copper, molybdenum, cobalt or tungsten. The layers may be formed in similar or different manners. For example, the layer 110 may be electrodeposited under basic conditions, and the layer 220 may be electrodeposited under acidic conditions. As another example, the layers 110, 320 can each independently include nickel, copper, molybdenum, cobalt or tungsten, but the layer 110 may be electrodeposited under basic conditions and the layer 220 may be deposited using a physical vapor deposition technique, a chemical vapor deposition, an atomic layer deposition, thermal spray technique or other methods. The layers 110, 320 can include metals other than copper, e.g., nickel, molybdenum, cobalt, tungsten, tin etc. or non-metals or both. The different conditions can provide a different overall structure in the layers 110, 320 even though similar materials may be present. In certain configurations, the layer 110 can improve adhesion of the layer 320. In other configurations, the layer 110 can “brighten” the surface of the device 300 so the device 300 has a shinier overall appearance.

In some embodiments, the substrate 105 used with the layers 110, 320 may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The layers 110, 320 typically each includes one or more metals or two or more metals. For example, the layers 110, 320 can be a metal alloy formed from two or more metals. In some embodiments, one of the metals in the layers 110, 320 is nickel. In other embodiments, one of the metals in the layers 110, 320 is molybdenum. In an additional embodiment, one of the metals in the layers 110, 320 is cobalt. In an additional embodiment, one of the metals in the layers 110, 320 is tungsten. The layers 110, 320 need not have the same metal and desirably the metal in the layers 110, 320 is different. In other embodiments, the layers 110, 320 independently can include a nickel alloy, a molybdenum alloy, or combinations thereof. In other examples, the layers 110, 320 independently may be a nickel-molybdenum alloy, a nickel-molybdenum-phosphorous alloy, a tungsten alloy, a nickel-tungsten alloy, etc. In certain configurations, one or both of the layers 110, 320 may consist of a nickel molybdenum alloy with no other materials being present in each layer. In other configurations, one of the layers 110, 320 may consist of a nickel-molybdenum-phosphorous alloy with no other materials being present in each layer. In some configurations, both of the layers 110, 320 may consist of a nickel-molybdenum-phosphorous alloy with no other materials being present in each layer. In other configurations, one or both of the layers 110, 320 may consist of a nickel alloy including at least nickel and a transition metal. In other configurations, one or both of the layers 110, 320 may consist of a nickel alloy including at least nickel and a transition metal excluding precious metals. In other configurations, one or both of the layers 110, 320 may consist of a molybdenum alloy including at least molybdenum and a transition metal. In other configurations, one or both of the layers 110, 320 may consist of a molybdenum alloy including at least molybdenum and a transition metal excluding precious metals. The exact thickness of the layers 110, 320 may vary from 0.1 micron to about 2 mm depending on the device where the coating is present, and the thickness of the layers 110, 320 need not be the same. The layer 110 may be thicker than the layer 320 or may be less thick than the layer 320.

In certain configurations, an intermediate layer may be present between the first layer 110 and the second layer 320. The intermediate layer can include, for example, any of those materials described in reference to layer 210 herein. Alternatively, an intermediate layer may be present between the substrate 105 and the layer 110 when the coating includes the first layer 110 and the second layer 120. In some embodiments, the layer 320 may have a higher hardness than the layer 110. For example, a hardness of the layer 320 may be greater than 750 Vickers. In certain embodiments, the layer 320 may comprise one or more of a nitride, a metal nitride, a carbide, a metal carbide, a boride, a metal boride, tungsten, tungsten carbide, a tungsten alloy, a tungsten compound, a stainless steel, a ceramic, chromium, chromium carbide, chromium oxide, a chromium compound, aluminum oxide, zirconia, titania, nickel, a nickel carbide, a nickel oxide, a nickel alloy, a cobalt compound, a cobalt alloy, a cobalt phosphorous alloy, molybdenum, a molybdenum compound, a nanocomposite, an oxide composite, or combinations thereof.

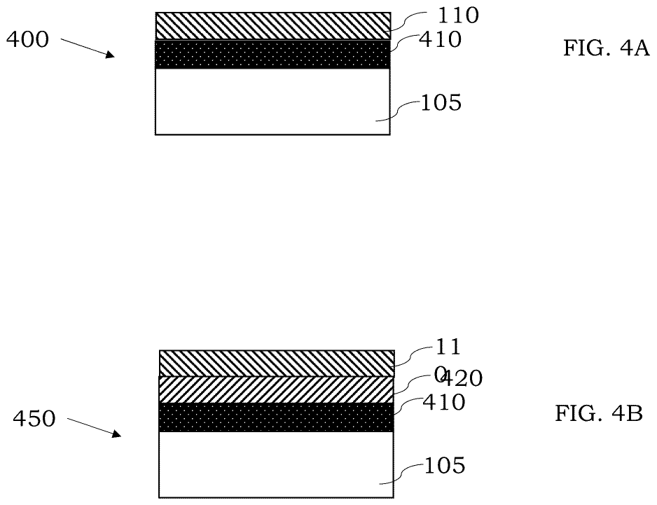

In other embodiments, a surface of the substrate may be treated or include a transferred surface, e.g., a carburized, nitrated, carbonitride, induction hardening, age hardening, precipitation hardening, gas nitriding, normalizing, subzero treatment, annealing, shot pinning, or chemically, thermally, or physically or a combination of thereof, modified surface, that is coated or treated with one or more other layers. Referring to FIG. 4A, an article or device 400 is shown that includes a transferred surface or a treated surface 410 on a substrate 105. The article or device 400 also includes a layer 110 on the treated surface 410. The layer 110 can be any of those materials described herein in reference to the layer 110 in FIGS. 1-3, 5A, 5B and 12. If desired and as shown in FIG. 4B, a layer 420 can be present between the treated surface 410 and the layer 110 of a device 450. The thickness of the layer/treated surface 410 may vary, for example, from about 0.1 microns to about 50 millimeters. The treated surface 410 can be harder than the underlying substrate 105 if desired. For example, the treated surface 410 may have a case hardness of 50-70 HRC. Where the treated surface/layer 410 is a transferred surface, the base material can be, but is not limited to, a steel (low carbon steel, stainless steel, nitride steel, a steel alloy, low alloy steel, etc.) or other metal based materials. The exact result of treatment may vary and typical treatment may be performed to enhance adhesion, alter surface roughness, improve wear resistance, improve the internal stress, reduce the internal stress, alter the hardness, alter lubricity, or for other reasons. The layer 110 may be used to protect device 450 against corrosion, wear, heat and other impacts. In some cases, the treated surface 410 can negatively reduce the resistance of device 450 against corrosion, wear, corrosion and wear combined, heat, heat and wear combined, corrosion and heat combined or other scenario and the layer 110 may be used to improve the performance as needed.

In some embodiments, the substrate 105 in FIGS. 4A and 4B may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The layer 110 in FIGS. 4A and 4B typically includes one or more metals or two or more metals as noted in connection with FIGS. 1-3, 5A, 5B and 12 herein. For example, the layer 110 in FIGS. 4A and 4B can be a metal alloy formed from two or more metals. In some embodiments, one of the metals in the layer 110 in FIGS. 4A and 4B is nickel. In other embodiments, one of the metals in the layer 110 in FIGS. 4A and 4B is molybdenum. In an additional embodiment, one of the metals in the layer 110 in FIGS. 4A and 4B is cobalt. In an additional embodiment, one of the metals in the layer 110 in FIGS. 4A and 4B is tungsten. In an additional embodiment, one of the metals in the layer 110 in FIGS. 4A and 4B is tin. In an additional embodiment, one of the metals in the layer 110 in FIGS. 4A and 4B is chromium. In other embodiments, the layer 110 in FIGS. 4A and 4B can include a nickel alloy, a molybdenum alloy, or combinations thereof. In other embodiments, the layer 110 in FIGS. 4A and 4B can include a molybdenum alloy including at least two metals (optionally excluding precious metals), a molybdenum alloy including at least molybdenum and a transition metal, a molybdenum alloy including at least molybdenum and a transition metal excluding precious metals. In other embodiments, the layer 110 in FIGS. 4A and 4B can include a nickel alloy including at least two metals excluding precious metals, nickel alloy including at least nickel and a refractory metal, nickel alloy including at least nickel and a refractory metal excluding precious metals. In other examples, the layer 110 in FIGS. 4A and 4B may be a nickel-molybdenum alloy or a nickel-molybdenum-phosphorous alloy. In certain configurations, the layer 110 in FIGS. 4A and 4B may consist of a nickel molybdenum alloy or a nickel molybdenum phosphorous alloy with no other materials being present in the layer 110. In other configurations, the layer 110 can include any of those materials, and material combinations, described in reference to FIG. 1, FIG. 2, or FIG. 3.

In certain embodiments, the exact thickness of the layer 110 in FIGS. 4A and 4B may vary from 1 micron to about 2 mm depending on the article or device where the layer 110 is present, e.g., the thickness may vary from about 5 microns to about 200 microns.

In certain embodiments, the intermediate layer 420, when present as shown in FIG. 4B, can improve adhesion between the layer 110 and the layer/surface 410. For example, copper, nickel, or other materials may be present as a thin layer, e.g., 1 micron thick or less, between the layer 110 and the layer/surface 410. While not shown, two or more layers may be present between the layer/surface 410 and the layer 110.

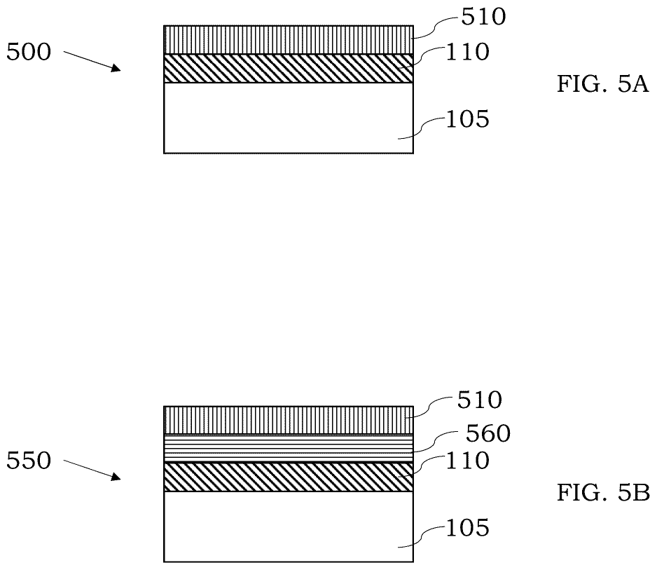

In certain embodiments, one or more layers may be present on top of the alloy layer 110. For example, a metal layer, a metal alloy layer, a layer with particles or composite materials or a layer with other materials may be present on top of the layer 110. Referring to FIG. 5A, an article or device 500 is shown where a layer 510 is present on top of the layer 110. If desired, an additional layer 560 can be present between the layer 510 and the layer 110 as shown in FIG. 5B. The exact materials present in the layers 510, 560 may vary depending on the end use application of the device 500.

In certain embodiments, the substrate 105 in FIGS. 5A and 5B may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The layer 110 in FIGS. 5A and 5B typically includes one or more metals or two or more metals as noted in connection with FIGS. 1-4B and 12. For example, the layer 110 in FIGS. 5A and 5B can be a metal alloy formed from two or more metals. In some embodiments, one of the metals in the layer 110 in FIGS. 5A and 5B is nickel. In other embodiments, one of the metals in the layer 110 in FIGS. 5A and 5B is molybdenum. In an additional embodiment, one of the metals in the layer 110 in FIGS. 5A and 5B is tungsten. In an additional embodiment, one of the metals in the layer 110 in FIGS. 5A and 5B is cobalt. In an additional embodiment, one of the metals in the layer 110 in FIGS. 5A and 5B is chrome. In other embodiments, the layer 110 in FIGS. 5A and 5B can include a nickel alloy, a molybdenum alloy, a cobalt alloy, a tungsten alloy, or combinations thereof. In other examples, the layer 110 in FIGS. 5A and 5B may be a nickel-molybdenum alloy or a nickel-molybdenum-phosphorous alloy. In certain configurations, the layer 110 in FIGS. 5A and 5B may consist of a nickel-molybdenum alloy a nickel-molybdenum-phosphorous alloy with no other materials being present in the layer 110. In other examples, the layer 110 in FIGS. 5A and 5B may include a nickel-molybdenum-phosphorous alloy. In other configurations, the layer 110 in FIGS. 5A and 5B may consist of a nickel-cobalt alloy, nickel-tungsten alloy, nickel-phosphorous ally, cobalt, cobalt-molybdenum alloy, cobalt-tungsten alloy, cobalt-phosphorous alloy, nickel-molybdenum-phosphorous alloy, cobalt-molybdenum-phosphorous alloy, cobalt-tungsten-phosphorous alloy, chrome, chrome alloy, molybdenum-tin alloy, chrome compounds in the layer 110. In other configurations, the layer 110 in FIGS. 5A and 5B may consist of a molybdenum alloy including at least two metals (optionally excluding precious metals), a molybdenum alloy including at least molybdenum and a transition metal, a molybdenum alloy including at least molybdenum and a transition metal excluding precious metals, molybdenum alloy including at least molybdenum and a transition metal and phosphorous, molybdenum alloy including at least molybdenum and a transition metal and tin, molybdenum alloy composite including some particles and nano-particles. In other configurations, the layer 110 in FIGS. 5A and 5B may consist of nickel alloy including at least two metals excluding precious metals, nickel alloy including at least nickel and a refractory metal, nickel alloy including at least nickel and a refractory metal excluding precious metals. The exact thickness of the layer 110 in FIGS. 5A and 5B may vary from 0.1 micron to about 2 mm depending on the device the layer 110 is present. In certain embodiments, the layers 510, 560 may each independently be a nickel layer, a nickel molybdenum layer, a metal alloy, tin, chrome, or combinations of these materials. In certain embodiments, the layers 510 may include a nitride, a metal carbide, a carbide, a boride, tungsten, tungsten carbide, a tungsten alloy, a tungsten compound, a stainless steel, a ceramic, chromium, chromium carbide, chromium oxide, a chromium compound, aluminum oxide, zirconia, titania, nickel, a nickel carbide, a nickel oxide, a nickel alloy, a cobalt compound, a cobalt alloy, a cobalt phosphorous alloy, molybdenum, a molybdenum compound, a nanocomposite, an oxide composite, or combinations thereof. In certain embodiments, the layers 510 may protect layer 110 against wear. In another embodiment, the layers 110 may protect the substrate 105 against corrosion. In another embodiments, the layer 110 may protect layer 510 against delamination, chipping off, or wearing away, In another embodiment, layer 110 may increase the adhesion of layer 510 to the substrate 105. In another embodiment, the layer 110 may improve the brightness for example by reflecting more light.

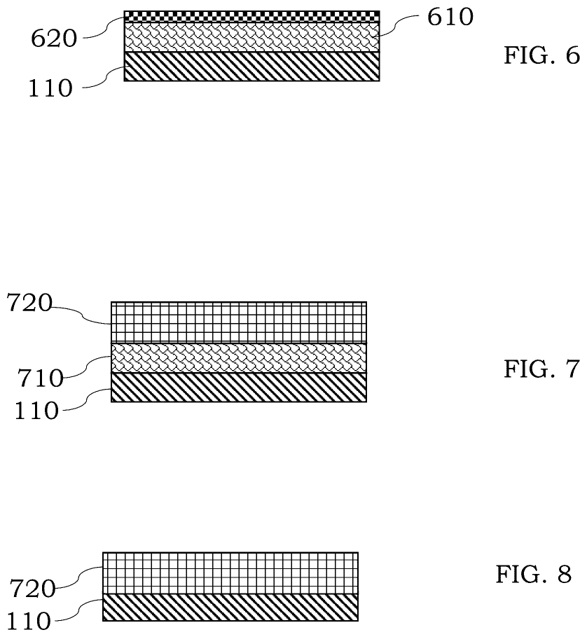

In other configurations, an article or device can include an outer metal layer and at least one underlying alloy layer. Referring to FIG. 6, several layers are shown including layer 110, 610 and 620. The substrate is intentionally omitted from FIGS. 6-8 to simplify the figures. A substrate is typically adjacent to the layer 110 though it may adjacent to another layer if desired. The layer 110 in FIG. 6 typically includes one or more metals or two or more metals as described in reference to FIGS. 1-5B and 12 or other materials as described herein. For example, the layer 110 in FIG. 6 can be a metal alloy formed from two or more metals. In some embodiments, one of the metals in the layer 110 in FIG. 6 is nickel. In other embodiments, one of the metals in the layer 110 in FIG. 6 is molybdenum. In other embodiments, the layer 110 in FIG. 6 can include a nickel alloy, a molybdenum alloy, or combinations thereof. In other examples, the layer 110 in FIG. 6 may be a nickel-molybdenum alloy or a nickel-molybdenum phosphorous alloy. In certain configurations, the layer 110 in FIG. 6 may consist of a nickel-molybdenum alloy or a nickel-molybdenum phosphorous alloy with no other materials being present in the layer 110. The exact thickness of the layer 110 in FIG. 6 may vary from 1 micron to about 2 mm, e.g., about 5 microns to about 200 microns, depending on the device where the layer 110 is present.

In certain embodiments, the layer 610 in FIG. 6 typically includes one or more metals or metal alloys, e.g., nickel, copper, molybdenum, nickel-molybdenum, nickel-molybdenum-phosphorous or combinations thereof. The thickness of the layer 610 is typically can be more or less than that of the layer 110. For example, the thickness of the layer 610 may vary from about 0.1 micron to about 1 micron. In some embodiments, the metal in the layer 610 may be present in the form of an alloy with another metal. The layer 620 typically also includes one or more metals, e.g., nickel, copper, molybdenum, nickel-molybdenum, nickel-molybdenum-phosphorous or combinations thereof. The metal of the layer 620 may be present in alloy or non-alloy form and can be present at a higher or lower thickness than a thickness of the layer 610. For example, the layer 620 may be present at a thickness of about 0.1 micron to about 0.5 microns. In some embodiments, the layer 620 can increase wear resistance, can increase conductivity, can provide a shinier surface, etc. In some configurations, the layers 610, 620 can include the same materials, but the materials may be present in different amounts. For example, each of the layers 610, 620 can be a nickel-molybdenum alloy, but an amount of molybdenum in the layer 610 is different than an amount of the molybdenum in the layer 620.

In certain embodiments, the layer 110 described herein in reference to FIGS. 1-6 can be present between two non-compatible materials to permit the non-compatible materials to be present in a coating or device. The term “non-compatible” generally refers to materials which do not readily bond or adhere to each other or have incompatible physical properties making them unsuitable to be used together. By including a metal alloy in the layer 110, it can be possible to include certain coatings in a device with a copper substrate. For example, an alloy layer of Ni—Mo or Ni—Mo-P may be present between a copper substrate and another metal layer. In certain embodiments, by including a layer 110 between a metal layer (or metal alloy layer) and a substrate, the overall wear resistance of the outer metal layer can increase as well.

In certain embodiments, one or more of the layers shown in FIGS. 1-6 may include tin (Sn). For example, tin can provide some corrosion resistance. Referring to FIG. 7, several layers are shown including layers 110, 710 and 720. A substrate (not shown) is typically adjacent to the layer 110 though it maybe adjacent to the layer 72 if desired. The layer 110 in FIG. 7 typically includes one or more metals or two or more metals as described in reference to FIGS. 1-6 and 12 or other materials as described herein. For example, the layer 110 in FIG. 7 can be a metal alloy formed from two or more metals. In some embodiments, one of the metals in the layer 110 in FIG. 7 is nickel. In other embodiments, one of the metals in the layer 110 in FIG. 7 is molybdenum. In other embodiments, the layer 110 in FIG. 7 can include a nickel alloy, a molybdenum alloy, or combinations thereof. In other examples, the layer 110 in FIG. 7 may be a nickel-molybdenum alloy or nickel-molybdenum-phosphorous alloy. In certain configurations, the layer 110 in FIG. 7 may consist of a nickel-molybdenum alloy or a nickel-molybdenum-phosphorous alloy with no other materials being present in the layer 110. The exact thickness of the layer 110 in FIG. 7 may vary from 1 micron to about 2 mm, e.g. about 5 microns to about 200 microns, depending on the article or device where the layer 110 is present.

In certain embodiments, the layer 710 in FIG. 7 typically includes one or more metals or metal alloys or combinations thereof. The thickness of the layer 710 can be more thick or less thick than a thickness of the layer 110. For example, the thickness of the layer 710 may vary from about 0.1 micron to about 1 micron. In some embodiments, the metal in the layer 710 may be present in the form of an alloy with another material, e.g., another metal. The layer 720 can include, for example, tin or a tin alloy, etc. The exact thickness of the layer 720 may vary and can be thicker or thinner than a thickness of the layer 710. For example, the layer 720 may be present at a thickness of more than 5 microns, e.g. 10-300 microns or 10-100 microns. In some embodiments, the layer 720 can be present to assist in keeping the surface clean, can increase wear resistance, can increase conductivity, can provide a shinier surface, can resist hydraulic fluids, etc. In some configurations, the layers 710, 720 can include the same materials, but the materials may be present in different amounts. For example, each of the layers 710, 720 can be a tin alloy, but an amount of tin in the layer 710 is different than an amount of tin in the layer 720.

In certain embodiments, a tin or tin alloy layer may be present directly on a metal or metal alloy layer as shown in FIG. 8. Several layers are shown including layer 110 and 720. No layer is present between the layer 110 and the layer 720. A substrate (not shown) is typically attached to the layer 110. The layer 110 in FIG. 8 typically includes one or more metals or two or more metals as described in reference to FIG. 1, FIG. 2 or FIG. 3 or other materials as described herein. For example, the layer 110 in FIG. 8 can be a metal alloy formed from two or more metals. In some embodiments, one of the metals in the layer 110 in FIG. 8 is nickel. In other embodiments, one of the metals in the layer 110 in FIG. 8 is molybdenum. In other embodiments, the layer 110 in FIG. 8 can include a nickel alloy, a molybdenum alloy, or combinations thereof. In other examples, the layer 110 in FIG. 8 may be a nickel-molybdenum alloy or a nickel-molybdenum-phosphorous alloy. In certain configurations, the layer 110 in FIG. 8 may consist of a nickel-molybdenum alloy or a nickel-molybdenum-phosphorous alloy with no other materials being present in the layer 110. The exact thickness of the layer 110 in FIG. 8 may vary from 1 micron to about 2 mm, e.g., from 5 microns to 200 microns, depending on the article or device where the layer 110 is present with typical thicknesses in the range of 10 microns or less or 5 microns or less. The layer 720 can include, for example, tin or a tin alloy, etc. The exact thickness of the layer 720 may vary and is typically thicker than the layer 710. For example, the layer 720 may be present at a thickness of more than 5 microns, e.g. 10-500 microns or 10-200 microns. In some embodiments, the layer 720 can be present to assist in keeping the surface clean, can increase wear resistance, can increase conductivity, can provide a shinier surface, etc.

In certain embodiments, the tin layers described in reference to FIGS. 7 and 8 could be replaced with a chromium layer. For example, chromium can be used to increase hardness and can also be used in decorative layers to enhance the outward appearance of the articles or devices. One or both of the layers 710, 720 could be a chromium layer or a layer comprising chromium.

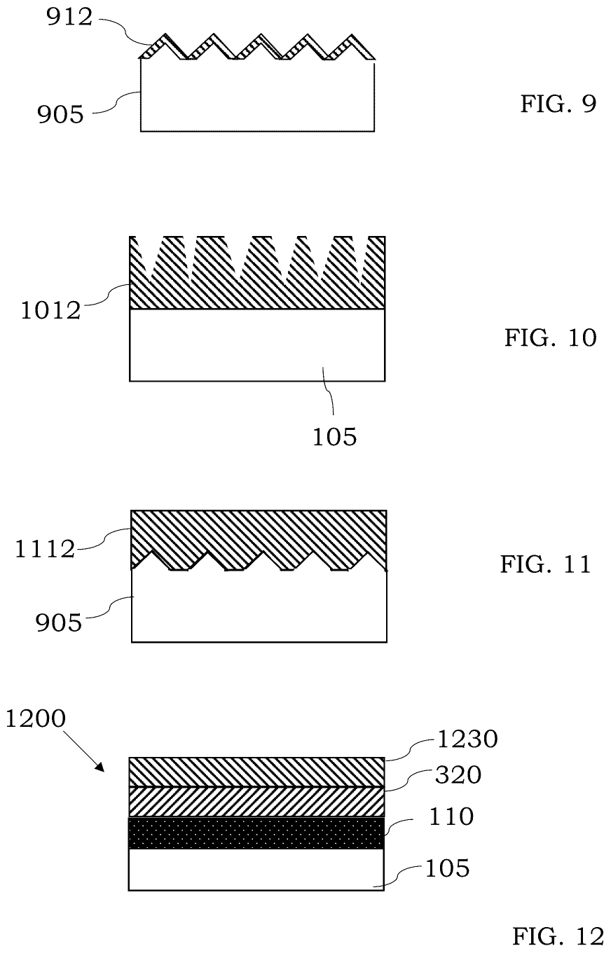

Referring to FIG. 9, an illustration is shown including a substrate 905 and a first layer 912. The surface of the substrate is shown as being rough for illustration purposes, and the layer 912 generally conforms to the various peaks and valleys on the surface. The thickness of the layer 912 may be the same or may be different at different areas. In some embodiments, the substrate 905 may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 905 may be porous or may be non-porous. For example, the coating 912 can be a metal alloy formed from two or more metals as described in reference to layer 110 in FIGS. 1-8 and 12 or other materials as described herein. In some embodiments, one of the metals in the coating 912 is nickel. In other embodiments, one of the metals in the coating 912 is molybdenum. In other examples, the coating 912 may be a nickel-molybdenum alloy or a nickel-molybdenum phosphorous alloy. In certain configurations, the coating 912 may consist of a nickel-molybdenum alloy or a nickel-molybdenum phosphorous alloy with no other materials being present in the coating 912. The exact thickness of the coating 912 may vary from 1 micron to about 2 mm, e.g. about 5 microns to about 200 microns, depending on the article or device where the coating 912 is present. While the exact function of the layer 912 may vary, as discussed further below, the layer 912 and roughened surface of the substrate 905 can provide a texture that renders the surface less prone to scattering light or showing fingerprints.

In certain embodiments, one or more layers may be present between the substrate 905 and the layer 912. For example, one or more intermediate layers may be present between the substrate 905 and the layer 912. In some instances, the intermediate layer(s) can improve adhesion between the layer 912 and the substrate 905. For example, copper, nickel, or other materials may be present as a thin layer, e.g., 1 micron thick or less, between the coating 912 and the substrate 905. In certain configurations, the intermediate layer(s) can function as a brightener to increase the overall shiny appearance of the article surface or device surface. In other configurations, the intermediate layer(s) can act to increase corrosion resistance of the coating. In some embodiments, the substrate 905 used with the intermediate layer may be, or may include, a metal material including, but not limited to, steel (carbon steel, tool steel, stainless steel, etc.), copper, copper alloys, aluminum, aluminum alloys, chromium, chromium alloys, nickel, nickel alloys, titanium, titanium alloys, nickel-chromium superalloys, nickel-molybdenum alloys, brass, a plastic, a polymer or combinations thereof. The coating 912 used with the intermediate layer(s) typically includes one or more metals or two or more metals. For example, the coating 912 used with the intermediate layer(s) can be a metal alloy formed from two or more metals as described in reference to the layer 110 in FIG. 1-8 and 12 or other materials as described herein. In some embodiments, one of the metals in the coating 912 used with the intermediate layer(s) is nickel. In other embodiments, one of the metals in the coating 912 used with the intermediate layer(s) is molybdenum. In other embodiments, the coating 912 used with the intermediate layer(s) can include a nickel alloy, a molybdenum alloy or combinations thereof. In other examples, the coating 912 used with the intermediate layer(s) may be a nickel-molybdenum alloy or a nickel-molybdenum phosphorous alloy. In certain configurations, the coating 912 used with the intermediate layer(s) may consist of a nickel-molybdenum alloy or a nickel-molybdenum phosphorous alloy with no other materials being present in the coating 912. The exact thickness of the coating 912 used with the intermediate layer(s) may vary from 1 micron to about 2 mm, e.g. about 5 microns to about 200 microns, depending on the article or device where the coating 912 is present.

In certain embodiments, it may be desirable to have a surface layer that is roughened. Referring to FIG. 10, an article or device is shown that includes a substrate 105 and a roughened surface layer 1012. The roughened surface layer 1012 can include any of those materials described in connection with the layer 110. In this illustration, the substrate 105 is generally smooth and the layer 1012 may be subjected to post deposition steps to roughen the surface layer 1012. The thickness of the layer 1012 is different at different areas. In some embodiments, the substrate 105 shown in FIG. 10 may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The coating 1012 typically includes one or more metals or two or more metals as described in reference to the layer 110 in FIGS. 1-8 and 12 or other materials as described herein. For example, the coating 1012 can be a metal alloy formed from two or more metals. In some embodiments, one of the metals in the coating 1012 is nickel. In other embodiments, one of the metals in the coating 1012 is molybdenum. In other embodiments, the coating 1012 can include a nickel alloy, a molybdenum alloy, or combinations thereof. In other examples, the coating 1012 may be a nickel-molybdenum alloy or a nickel-molybdenum phosphorous alloy. In certain configurations, the coating 1012 may consist of a nickel-molybdenum alloy or a nickel-molybdenum phosphorous alloy with no other materials being present in the coating 1012. The exact thickness of the coating 1012 may vary from 0.1 micron to about 2 mm, e.g. about 5 microns to about 200 microns, depending on the article or device where the coating 1012 is present. While the exact function of the layer 1012 may vary, as discussed further below, the layer 1012 can provide a texture that renders the surface less prone to scattering light or showing fingerprints.

In certain embodiments, one or more layers may be present between the substrate 105 and the layer 1012. For example, one or more intermediate layers may be present between the substrate 105 and the layer 1012. In some instances, the intermediate layer(s) can improve adhesion between the layer 1012 and the substrate 105. For example, copper, nickel or other materials may be present as a thin layer, e.g., 1 micron thick or less, between the coating 1012 and the substrate 105. In certain configurations, the intermediate layer(s) can function as a brightener to increase the overall shiny appearance of the article or device. In other configurations, the intermediate layer(s) can act to increase corrosion resistance of the article or device. In some embodiments, the substrate 105 used with the intermediate layer may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The coating 1012 used with the intermediate layer(s) typically includes one or more metals or two or more metals as described in reference to the layer 110 in FIGS. 1-8 and 12 or other materials as described herein. For example, the coating 1012 used with the intermediate layer(s) can be a metal alloy formed from two or more metals. In some embodiments, one of the metals in the coating 1012 used with the intermediate layer(s) is nickel. In other embodiments, one of the metals in the coating 1012 used with the intermediate layer(s) is molybdenum. In other embodiments, the coating 1012 used with the intermediate layer(s) can include a nickel alloy, a molybdenum alloy or combinations thereof. In other examples, the coating 1012 used with the intermediate layer(s) may be a nickel-molybdenum alloy or a nickel-molybdenum phosphorous alloy. In certain configurations, the coating 1012 used with the intermediate layer(s) may consist of a nickel-molybdenum alloy or a nickel-molybdenum-phosphorous alloy with no other materials being present in the coating 1012. The exact thickness of the coating 1012 used with the intermediate layer(s) may vary from 1 micron to about 2 mm, e.g. about 10 microns to about 200 microns, depending on the article or device where the coating 1012 is present.

In certain embodiments, a surface coating can be applied to a roughened surface to provide an overall smooth surface. An illustration is shown in FIG. 11 where a roughened substrate 905 includes a layer 1110 that fills in the peaks and valleys and provides a generally smoother outer surface. The surface layer 1110 can include any of those materials described in connection with the layer 110 in FIGS. 1-8 and 12 or other materials as described herein. In this illustration, the substrate 905 may have been subjected to a roughening process and the layer 1110 may be subjected to post deposition steps, e.g., shot peening or other steps, to smooth the surface layer 1110 in the event that it is not smooth after deposition. The thickness of the layer 1110 is different at different areas to fill in the peaks and valleys. In some embodiments, the substrate 905 may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 905 may be porous or may be non-porous. The coating 1110 typically includes one or more metals or two or more metals as described herein in connection with the layer 110. For example, the coating 1110 can be a metal alloy formed from two or more metals. In some embodiments, one of the metals in the coating 1110 is nickel. In other embodiments, one of the metals in the coating 1110 is molybdenum. In other embodiments, the coating 1110 can include a nickel alloy, a molybdenum alloy, or combinations thereof. In other examples, the coating 1110 may be a nickel-molybdenum alloy or a nickel-molybdenum phosphorous alloy. In certain configurations, the coating 1110 may consist of a nickel-molybdenum alloy or a nickel-molybdenum-phosphorous alloy with no other materials being present in the coating 1110. The exact thickness of the coating 1110 may vary from 1 micron to about 2 mm, e.g., about 5 microns to about 200 microns, depending on the article or device where the coating 1110 is present. While the exact function of the layer 1110 may vary, as discussed further below, the layer 1110 can provide a smoother or shinier surface that is more aesthetically pleasing.

In certain embodiments, one or more layers may be present between the substrate 905 and the layer 1110. For example, one or more intermediate layers may be present between the substrate 905 and the layer 1110. In some instances, the intermediate layer(s) can improve adhesion between the layer 1110 and the substrate 905. For example, copper, nickel or other materials may be present as a thin layer, e.g., 1 micron thick or less, between the coating 1110 and the substrate 905. In certain configurations, the intermediate layer(s) can function as a brightener to increase the overall shiny appearance of the article or device. In other configurations, the intermediate layer(s) can act to increase corrosion resistance of the coating. In some embodiments, the substrate 105 used with the intermediate layer may be, or may include, a metal material including, but not limited to, steel (carbon steel, tool steel, stainless steel, alloy steel, low alloy steel, etc.), copper, copper alloys, aluminum, aluminum alloys, chromium, chromium alloys, nickel, nickel alloys, molybdenum, molybdenum alloys, titanium, titanium alloys, nickel-chromium superalloys, nickel-molybdenum alloys, brass, bronze, a superalloy, Hastelloy, Inconel, Nichrome, Monel, or combinations thereof. In some embodiments, the substrate 105 may be porous or may be non-porous. The coating 1110 used with the intermediate layer(s) typically includes one or more metals or two or more metals. For example, the coating 1110 used with the intermediate layer(s) can be a metal alloy formed from two or more metals as described in reference to the layer 110 in FIGS. 1-8 and 12 or other materials as described herein. In some embodiments, one of the metals in the coating 1110 used with the intermediate layer(s) is nickel. In other embodiments, one of the metals in the coating 1110 used with the intermediate layer(s) is molybdenum. In other embodiments, the coating 1110 used with the intermediate layer(s) can include a nickel alloy, a molybdenum alloy, or combinations thereof. In other examples, the coating 1110 used with the intermediate layer(s) may be a nickel-molybdenum alloy or a nickel-molybdenum-phosphorous alloy. In certain configurations, the coating 1110 used with the intermediate layer(s) may consist of a nickel-molybdenum alloy or a nickel-molybdenum-phosphorous alloy with no other materials being present in the coating 1012. The exact thickness of the coating 1110 used with the intermediate layer(s) may vary from 0.1 micron to about 2 mm, e.g. about 5 microns to about 200 microns, depending on the article or device where the coating 1110 is present.

In certain embodiments, a device or article described herein may include coating with a first layer, a second layer and a third layer on a surface of a substrate. Referring to FIG. 12, an article or device 1200 includes a substrate 105, a first layer 110, a second layer 320 and a third layer 1230. Each of the layers 110, 320 and 1230 may include any of those materials described in connection with the layers 110, 320 described above. In some embodiments, the layer 1230 may be a polymeric coating or a metal or non-metal based coating. The layer 110 is typically a metal alloy layer including two or more metals as noted in connection with the layer 110 of FIGS. 1-8 or other materials as described herein.

In certain configurations, the articles and devices described herein can include a substrate with a coated surface where the coated surface comprises a surface coating. The surface coating may comprise two or more layers. For example, an alloy layer as noted in connection with layer 110 can be on a surface of a substrate 105 and a second layer can be on the alloy layer 110. In some examples, the alloy layer can include molybdenum as noted herein, e.g., molybdenum in combination with one or more of nickel, tungsten, cobalt, chromium, tin, phosphorous, iron, magnesium or boron. The second layer is on the alloy layer can may comprise a ceramic or an alloy or some material which may be harder than the underlying layer with molybdenum. In other instances, the alloy layer with molybdenum may be harder than the second layer depending on the intended use of the article or device. In some embodiments, the second layer may comprise one or more of tungsten, chromium, aluminum, zirconium, titanium, nickel, cobalt, molybdenum, silicon, boron or combinations thereof. (The ceramic comprises metal nitride, a nitride, a metal carbide, a carbide, a boride, tungsten, tungsten carbide, a tungsten alloy, a tungsten compound, a stainless steel, a ceramic, chromium, chromium carbide, chromium oxide, a chromium compound, aluminum oxide, zirconia, zirconium oxide titania, nickel, a nickel carbide, a nickel oxide, a nickel alloy, a cobalt compound, a cobalt alloy, a cobalt phosphorous alloy, molybdenum, a molybdenum compound, a nanocomposite, an oxide composite, or combinations thereof. In some instances, the second layer may have a Vickers hardness of 600 Vickers or more.

In other configurations, the articles or devices described herein may comprise materials which provide a lubricious alloy layer. For example, a substrate can include a coated surface with a smooth alloy layer. In some embodiments, the alloy layer can be formed on the substrate and may comprise molybdenum or other materials as noted in connection with the layer 110 in the figures. A weight percentage of the molybdenum or other metal may be 35% by weight or less. A surface roughness Ra of the lubricious alloy layer may be less than 1 micron. In some instances, the alloy layer can also include one or more of nickel, tungsten, cobalt, chromium, tin, phosphorous, iron, magnesium or boron. In some embodiments, the surface coating can include two or more layers. For example, a base layer may be present with an alloy layer formed or added to the base layer. The base layer can be an intermediate layer between a substrate and the alloy layer or may be a standalone layer that is self-supporting and not present on any substrate. In some examples, the base layer may comprise one or more of a nickel layer, a copper layer, a nickel-phosphorous layer, a nickel-molybdenum layer or other materials. The coating on the base layer may comprise one or more of molybdenum, nickel, tungsten, cobalt, chromium, tin, phosphorous, iron, magnesium or boron. In some instances, the alloy layer may be an exposed outer later or may be free of precious metals. If desired, particles may also be present in one or more of the layers. Illustrative particles are described herein.

In certain embodiments, a surface coating that includes two or more layers including the same materials may be present on the articles described herein. Alternatively, one of the layers may be a standalone layer that is self-supporting and not present on any substrate. For example, a first alloy layer comprising nickel and molybdenum may be present in combination with a second alloy layer comprising nickel and molybdenum. The amounts of the materials in different layers may be different or different layers may have different additives, e.g., different particles or other materials. In some instances, one of the layers may be rougher than the other layer by altering the amounts of the materials in one of the layers. For example, a weight percent of molybdenum in the second alloy layer can be less than 30% by weight and the roughness of the overall surface coating can be less than 1 um Ra. Each of the two layers may independently include one or more of molybdenum, nickel, tungsten, cobalt, chromium, tin, phosphorous, iron, magnesium or boron. In some instances, one of the alloy layers may be free of precious metals. In other instances, each of the alloy layer is free of precious metals. If desired, particles may also be present in one or more of the alloy layers. Illustrative particles are described herein.

In certain embodiments, an article can include a surface coating that has an alloy layer described herein along with a chromium layer on top of the alloy layer. The alloy layer can include molybdenum and one or more of nickel, tungsten, cobalt, chromium, tin, phosphorous, iron, magnesium or boron. The chromium layer may be an alloy including another metal or material. In some examples, the chromium layer is free of precious metals. In other instances, each of the alloy layer and the chromium layer is free of precious metals.

In other configurations, a surface coating can include a nickel molybdenum phosphorous (Ni—Mo—P) alloy layer. In some instances, one or more other materials may be present in the nickel molybdenum phosphorous alloy layer. For example, one or more of tungsten, cobalt, chromium, tin, iron, magnesium or boron may be present. If desired, particles may also be present. The Ni—Mo—P alloy layer may include molybdenum at 35% by weight or less in the alloy layer or in the surface coating.

In certain examples, the coating layers described herein can be applied to the substrate using suitable methodologies including, but not limited to, vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods.

In certain examples, one or more of the coating layers may be deposited using vacuum deposition. In certain embodiments, vacuum deposition generally deposits a layer of material atom-by-atom or molecule-by-molecule on a surface of a substrate. Vacuum deposition processes can be used to deposit one or more materials with a thickness from one or more atoms up to a few millimeters.

In certain embodiments, physical vapor deposition (PVD), a type of vacuum deposition, can be used to deposit one or more of the coating layers described herein. PVD generally uses a vapor of the materials to produce a thin coating on the substrate. The coatings described herein may be, for example, sputtered onto a surface of the substrate or applied onto a surface of the substrate using evaporation PVD. In other embodiments, one or more coating layers can be produced on a substrate using chemical vapor deposition (CVD). CVD generally involves exposing the substrate to one or more materials that react and/or decompose on the surface of the substrate to provide a desired coating layer on the substrate. In other configurations, plasma deposition (PD), e.g., plasma enhanced chemical vapor deposition or plasma assisted chemical vapor deposition, can be used to provide a coating layer on a substrate. PD generally involves creating a plasma discharge from reacting gases including the material to be deposited and/or subjecting an already deposited material to ions in a plasma gas to modify the coating layer. In other examples, atomic layer deposition (ALD) can be used to provide a coating layer on a surface. In ALD, a substrate surface is exposed to repeated amounts of precursors that can react with a surface of a material to build up the coating layer.

In other examples, one or more of the coating layers described herein can be deposited into a surface of a substrate using brushing, spin-coating, spray coating, dip coating, electrodeposition (e.g., electroplating, cathodic electrodeposition, anodic electrodeposition, etc.), electroless plating, electrocoating, electrophoretic deposition, or other techniques. Where an electric current is used to deposit a coating layer on a substrate, the current may be continuous, pulsed or combinations of continuous current and pulsed current can be used. Certain electrodeposition techniques are described in more detail below.

In some configurations, one or more layers of the coating may be applied using electrodeposition. In general, electrodeposition uses a voltage applied to the substrate placed in a bath to form the coating on the charged substrate. For example, ionic species present in the bath can be reduced using the applied voltage to deposit the ionic species in a solid form onto a surface (or all surfaces) of the substrate. As noted in more detail below, the ionic species can be deposited to provide a metal coating, a metal alloy coating or combinations thereof. Depending on the exact ionic species used and the electrodeposition conditions and techniques, the resulting properties of the formed, electrodeposited coating may be selected or tuned to provide a desired result.

In certain embodiments where electrodeposition is used, the ionic species may be dissolved or solvated in an aqueous solution or water. The aqueous solution may include suitable dissolved salts, inorganic species or organic species to facilitate electrodeposition of the coating layer(s) on the substrate. In other embodiments where electrodeposition is used, the liquid used in the electrodeposition bath may generally be non-aqueous, e.g., include more than 50% by volume of non-aqueous species, and may include hydrocarbons, alcohols, liquified gases, amines, aromatics and other non-aqueous materials.

In general, the electrodeposition bath includes the species to be deposited as a coating on the substrate. For example, where nickel is deposited onto a substrate, the bath can include ionic nickel or solvated nickel. Where molybdenum is deposited into a substrate, the bath can include ionic molybdenum or solvated molybdenum. Where an alloy is to be deposited on a substrate, the bath can include more than a single species, e.g., the bath may include ionic nickel and ionic molybdenum that are co-electrodeposited to form a nickel-molybdenum alloy as a coating layer on a substrate. The exact form of the materials added to the bath to provide ionic or solvated species can vary. For example, the species may be added to the bath as metal halides, metal fluorides, metal chlorides, metal carbonates, metal hydroxides, metal acetates, metal sulfates, metal nitrates, metal nitrites, metal chromates, metal dichromates, metal permanganates, metal platinates, metal cobalt-nitrites, metal hexachloroplatinates, metal citrates, ammonium salt of the metal, metal cyanides, metal oxides, metal phosphates, metal monobasic sodium phosphates, metal dibasic sodium phosphates, metal tribasic sodium phosphates, sodium salt of the metal, potassium salt of the metal, metal sulfamate, metal nitrite, and combinations thereof. In some examples, a single material that includes both of the metal species to be deposited can be dissolved in the electrodeposition bath, e.g., a metal alloy salt can be dissolved in a suitable solution prior to electrodeposition. The specific materials used in the electrodeposition bath depends on the particular alloy layer to be deposited. Illustrative materials include, but are not limited to, nickel sulfate, nickel sulfamate, nickel chloride, sodium tungstate, tungsten chloride, sodium molybdate, ammonium molybdate, cobalt sulfate, cobalt chloride, chromium sulfate, chromium chloride, chromic acid, stannous sulfate, sodium stannate, hypophosphite, sulfuric acid, nickel carbonate, nickel hydroxide, potassium carbonate, ammonium hydroxide, hydrochloric acid or other materials.

In certain embodiments, the exact amount or concentration of the species to be electrodeposited onto a substrate may vary. For example, the concentration of the species may vary from about 1 gram/Liter to about 400 grams/Liter. If desired, as the ionic species are depleted as a result of formation of the coating on the substrate, additional material can be added to the bath to increase an amount of the species available for electrodeposition. In some instances, the concentration of the species to be deposited may be maintained at a substantially constant level during electrodeposition by continuously adding material to the bath.

In certain embodiments, the pH of the electrodeposition bath may vary depending on the particular ionic species present in the bath. For example, the pH may vary from 1 to about 13, but in certain instances, the pH may be less than 1, or even less than 0, or greater than 13 or even greater than 14. Where metal species are deposited as metal alloys onto a substrate, the pH may range, in certain instances, from 4 to about 12. It will be recognized, however, that the pH may be varied depending on the particular voltage and electrodeposition conditions that are selected for use. Some pH regulators and buffers may be added to the bath. Examples of pH regulators include but not limited to boric acid, hydrochloric acid, sodium hydroxide, potassium hydroxide, ammonium hydroxide, glycine, Sodium acetate, buffered saline, Cacodylate buffer, Citrate buffer, Phosphate buffer, Phosphate-citrate buffer, Barbital buffer, TRIS buffers, Glycine-NaOH buffer, and any combination thereof.

In certain embodiments, alloy plating can use a complexing agent. For example, the main role of complexing agents in an alloy deposition process is making complexations of different metallic ions. Therefore, without a proper complexing agent, simultaneous deposition of nickel and molybdenum and alloy formation will not occur. Examples of complexing agents include but are not limited to phosphates, phosphonates, polycarboxylates, zeolites, citrates, ammonium hydroxide, ammonium salts, citric acid, ethylenediaminetetraacetic acid, diethylene-triaminepentaacetic acid, aminopolycarboxylates, nitrilotriacetic acid, IDS (N-(1,2-dicarboxyethyl)-D,L-aspartic acid (iminodisuccinic acid), DS (polyaspartic acid), EDDS (N,N′-ethylenediaminedisuccinic acid), GLDA (N,N-bis(carboxylmethyl)-L-glutamic acid) and MGDA (methylglycinediacetic acid), hexamine cobalt (III) chloride, ethylene glycol-bis(β-aminoethyl ether)-N,N,N′,N′-tetraacetic acid (EGTA), ferrocene, cyclodextrins, choleic acid, polymers, and any combination thereof.

In some examples, a suitable voltage can be applied to cathodes and anodes of the electrodeposition bath to promote formation of the layer(s) described herein on a substrate. In some embodiments, a direct current (DC) voltage can be used. In other examples, an alternating current (AC) optionally in combination with current pulses can be used to electrodeposit the layers. For example, AC electrodeposition can be carried out with an AC voltage waveform, in general sinusoidal, squared, triangular, and so on. High voltages and current densities can be used to favor the tunneling of electrons through an oxide base layer that can form on the substrate. Furthermore, the base layer can conduct in the direction of the cathode, which favors the deposition of the material and avoids its reoxidation during the oxidant half-cycle.

In certain embodiments, illustrative current density ranges that can be used in electrodeposition include, but are not limited to 1 mA/cm² DC to about 600 mA/cm² DC, more particularly about 1 mA/cm² DC to about 300 mA/cm² DC. In some examples, the current density can vary from 5 mA/cm² DC to about 300 mA/cm² DC, from 20 mA/cm² DC to about 100 mA/cm² DC, from 100 mA/cm² DC to about 400 mA/cm² DC or any value falling within these illustrative ranges. The exact time that the current is applied may vary from about 10 seconds to a few days, more particularly about 40 seconds to about 2 hours. A pulse current can also be applied instead of a DC current if desired.

In some examples, the electrodeposition may use pulse current or pulse reverse current is during the electrodeposition of the alloy layer. In pulse electrodeposition (PED), the potential or current is alternated swiftly between two different values. This results in a series of pulses of equal amplitude, duration and polarity, separated by zero current. Each pulse consists of an ON-time (TON) during which potential and/current is applied, and an OFF-time (TOFF) during which zero current is applied. It is possible to control the deposited film composition and thickness in an atomic order by regulating the pulse amplitude and width. They favor the initiation of grain nuclei and greatly increase the number of grains per unit area resulting in finer grained deposit with better properties than conventionally plated coatings.

In examples where the coating includes two or more layers, the first layer and the second layer of the coating may be applied using the same or different electrodeposition baths. For example, a first layer can be applied using a first aqueous solution in an electrodeposition bath. After application of a voltage for a sufficient period to deposit the first layer, the voltage may be reduced to zero, the first solution can be removed from the bath and a second aqueous solution comprising a different material can be added to the bath. A voltage can then be reapplied to electrodeposit a second layer. In other instances, two separate baths can be used, e.g., a reel-to-reel process can be used, where the first bath is used to electrodeposit the first layer and a second, different bath is used to deposit the second layer.

In some cases, individual articles may be connected such that they can be sequentially exposed to separate electrodeposition baths, for example in a reel-to-reel process. For instance, articles may be connected to a common conductive substrate (e.g., a strip). In some embodiments, each of the electrodeposition baths may be associated with separate anodes and the interconnected individual articles may be commonly connected to a cathode.

While the exact material used in electroplating methods may vary, illustrative materials include cations of one or more of the following metals: nickel, molybdenum, copper, aluminum, cobalt, tungsten, gold, platinum, palladium, silver, or combinations thereof. The exact anion form of these metals may vary from chlorides, acetates, sulfates, nitrates, nitrites, chromates, dichromates, permanganates, platinates, cobalt nitrites, hexachloroplatinates, citrates, cyanides, oxides, phosphates, monobasic sodium phosphates, dibasic sodium phosphates, tribasic sodium phosphates and combinations thereof.

In other instances, the electrodeposition process can be designed to apply an alloy layer including molybdenum and one or more of nickel, tungsten, cobalt, chromium, tin, phosphorous, iron, magnesium and boron or at least one compound comprising one or more of nickel, tungsten, cobalt, chromium, tin, phosphorous, iron, magnesium or boron. In some embodiments, the resulting alloy layer may be free of precious metals.

In some embodiments, there may be no intervening or intermediate layers between the coating layer 110 and the substrate 105. For example, the coating layer 110 can be deposited directly onto the substrate surface 105 without any intervening layer between them. In other instances, an intermediate layer may be present between the coating layer 110 and the surface 106 of the substrate 105. The intermediate layer can be formed using the same methods used to form the coating layer 110 or different methods used to form the coating layer 110. In some embodiments, an intermediate layer can include one or more of copper, a copper alloy, nickel, a nickel alloy, a nickel-phosphorous alloy, a nickel-phosphorous alloy including hard particles or other compounds such as phosphorous, boron, boron nitride, silicon carbide, aluminum oxide, molybdenum disulfide, hard particles with a hardness of HV>1000, hard particles with size less 500 nm, highly conductive particles, carbon nanotubes and or carbon nano-particles. In other instances, the intermediate layer can include an alloy of nickel that is less magnetic than nickel alone. In some instances, the intermediate layer may be substantially less than the coating layer 110 and can be used to enhance adhesion of the coating layer 110 to the substrate 105. For example, the intermediate layer can be 90%, 80%, 70%, 60%, 50%, 40%, 30%, 20% or 10% less thick than a thickness of the coating layer 110. In certain embodiments, the layer between the substrate and the alloy layer may be a “nickel strike” layer as is commonly known in the electroplating arts.

In some embodiments, one or more of the materials of a coating layer can be provided using a soluble anode. The soluble anode can dissolve in the electrodeposition bath to provide the species to be deposited. In some embodiments, the soluble anode may take the form of a disk, a rod, a sphere, strips of materials or other forms. The soluble anode can be present in a carrier or basket coupled to a power source.

In some embodiments, one or more of the coating layers described herein may be deposited using an anodization process. Anodization generally uses the substrate as the anode of an electrolytic cell. Anodizing can change the microscopic texture of the surface and the resulting metal coating near the surface. For example, thick coatings are often porous and can be sealed to enhance corrosion resistance. Anodization can result in harder and more corrosion resistant surfaces. In some examples, one of the coating layers of the articles described herein can be produced using an anodization process and another coating layer may be produced using a non-anodization process. In other instances, each coating layer in the article can be produced using an anodization process. The exact materials and process conditions using anodization may vary. Generally, the anodized layer is grown on a surface of the substrate by applying a direct current through an electrolyte solution including the material to be deposited. The material to be deposited can include magnesium, niobium, tantalum, zinc, nickel, molybdenum, copper, aluminum, cobalt, tungsten, gold, platinum, palladium, silver, or alloys or combinations thereof. Anodization is typically performed under acidic conditions and may include chromic acid, sulfuric acid, phosphoric acid, organic acids or other acids.

In certain embodiments, the coatings described herein may be applied in the presence of other additive or agents. For example, wetting agents, leveling agents, brighteners, defoaming agents and/or emulsifiers can be present in aqueous solutions that include the materials to be deposited onto the substrate surface. Illustrative additive and agents include, but are not limited to, thiourea, domiphen bromide, acetone, ethanol, cadmium ion, chloride ion, stearic acid, ethylenediamine dihydrochloride (EDA), saccharin, cetyltrimethylammonium bromide (CTAB), sodium dodecyl sulfate, sodium lauryl sulfate (SLS), saccharine, naphthalene sulfonic acid, benzene sulfonic acid, coumarin, ethyl vanillin, ammonia, ethylene diamine, polyethylene glycol (PEG), bis(3-sulfopropyl)disulfide (SPS), Janus green B (JGB), azobenzene-based surfactant (AZTAB), the polyoxyethylene family of surface active agents, sodium citrate, perfluorinated alkylsulfate, additive K, calcium chloride, ammonium chloride, potassium chloride, boric acid, myristic acid, choline chloride, citric acid, any redox active surfactant, any conductive ionic liquids, polyglycol ethers, polyglycol alcohols, sulfonated oleic acid derivatives, sulfate form of primary alcohols, alkylsulfonates, alkylsulfates, aralkylsulfonates, sulfates, Perfluoro-alkylsulfonates, acid alkyl and aralkyl-phosphoric acid esters, alkylpolyglycol ether, alkylpolyglycol phosphoric acid esters or their salts, N-containing and optionally substituted and/or quaternized polymers, such as polyethylene imine and its derivatives, polyglycine, poly(allylamine), polyaniline (sulfonated), polyvinylpyrrolidone, gelatin, polyvinylpyridine, polyvinylimidazole, polyurea, polyacrylamide, poly(melamine-co-formaldehyde), polyalkanolamines, polyaminoamide and derivatives thereof, polyalkanolamine and derivatives thereof, polyethylene imine and derivatives thereof, quaternized polyethylene imine, poly(allylamine), polyaniline, polyurea, polyacrylamide, poly(melamine-co-formaldehyde), hydroxy-ethyl-ethylene-diamine triacetic acid, 2 Butyne 1 4 diol, 2 2 azobis(2-methyl propionitrite), perfluoroammonoic acid, dextrose, cetyl methyl ammonium bromide, 1 hexadecyl pyridinium-chloride, d-mannitol, glycine, Rochelle salt, N N′-diphenylbenzidine, glycolic acid, tetra-methyl-ammonium hydroxide, reaction products of amines with epichlorohydrin, reaction products of an amine, epichlorohydrin, and polyalkylene oxide, reaction products of an amine with a polyepoxide, polyvinylpyridine, polyvinylimidazole, polyvinylpyrrolidone, or copolymers thereof, nigrosines, pentamethyl-para-rosaniline, one or more of fats, oils, long chained alcohols, or glycols, polyethylene glycols, polyethylene oxides such as Tritons, alkylphosphates, metal soaps, special silicone defoamers, commercial perfluoroalkyl-modified hydrocarbon defoamers and perfluoroalkyl-substituted silicones, fully fluorinated alkylphosphonates, perfluoroalkyl-substituted phosphoric acid esters, cationic-based agents, amphoteric-based agents, and nonionic-based agent; chelating agents such as citrates, acetates, gluconates, and ethylenediamine tetra-acetic acid (EDTA), or any combination thereof.

In embodiments where electroless plating is used, metal coatings can be produced on a substrate by autocatalytic chemical reduction of metal cations in a bath. In contrast to electrodeposition/electroplating, no external electric current is applied to the substrate in electroless plating. While not wishing to be bound by any particular configuration or example, electroless plating can provide more even layers of the material on the substrate compared to electroplating. Further, electroless plating may be used to add coatings onto non-conductive substrates.

In certain embodiments where electroless plating is used, the substrate itself may act as a catalyst to reduce an ionic metal and form a coating of the metal on the surface of the substrate. Where it is desirable to produce a metal alloy coating, the substrate may act to reduce two or more different ionic metals with the use of a complexing agent to form a metal alloy including the two different metals. In some examples, the substrate itself may not function as a catalyst but a catalytic material can be added to the substrate to promote formation of the metal coating on the substrate. Illustrative catalytic materials that can be added to a substrate include, but are not limited to, palladium, gold, silver, titanium, copper, tin, niobium, and any combination thereof.

While the exact material used in electroless plating methods may vary, illustrative materials include one or more of the following cations: magnesium, niobium, tantalum, zinc, nickel, molybdenum, copper, aluminum, cobalt, tungsten, gold, platinum, palladium, silver, or alloys or combinations thereof. For example, any one or more of these cations can be added as a suitable salt to an aqueous solution. Illustrative suitable salts include, but are not limited to, metal halides, metal fluorides, metal chlorides, metal carbonates, metal hydroxides, metal acetates, metal sulfates, metal nitrates, metal nitrites, metal chromates, metal dichromates, metal permanganates, metal platinates, metal cobalt nitrites, metal hexachloroplatinates, metal citrates, metal cyanides, metal oxides, metal phosphates, metal monobasic sodium phosphates, metal dibasic sodium phosphates, metal tribasic sodium phosphates and combinations thereof.

In certain embodiments, the substrates described herein may be subjected to pre-coating processing steps to prepare the substrate to receive a coating. These processing steps can include, for example, cleaning, electro-cleaning (anodic or cathodic), polishing, electro-polishing, pre-plating, thermal treatments, abrasive treatments and chemical treatments. For example, the substrates can be cleaned with an acid, a base, water, a salt solution, an organic solution, an organic solvent or other liquids or gases. The substrates can be polished using water, an acid or a base, e.g., sulfuric acid, phosphoric acid, etc. or other materials optionally in the presence of an electric current. The substrates may be exposed to one or more gases prior to application of the coating layers to facilitate removal of oxygen or other gases from a surface of the substrate. The substrate may be washed or exposed to an oil or hydrocarbon fluid prior to application of the coating to remove any aqueous solutions or materials from the surface. The substrate may be heated or dried in an oven to remove any liquids from the surface prior to application of the coating. Other steps for treating the substrate prior to application of a coating may also be used.

In some embodiments, the coatings layers described herein can be subjected to sealing. While the exact conditions and materials uses to seal the coatings can vary, sealing can reduce the porosity of the coatings and increase their hardness. In some embodiments, sealing may be performed by subjecting the coating to steam, organic additives, metals, metal salts, metal alloys, metal alloy salts, or other materials. The sealing may be performed at temperatures above room temperature, e.g., 30 degrees Celsius, 50 degrees Celsius, 90 degrees Celsius or higher, at room temperature or below room temperature, e.g., 20 degrees Celsius or less. In some examples, the substrate and coating layer may be heated to remove any hydrogen or other gases in the coating layer. For example, the substrate and coating can be baked to remove hydrogen from the article within 1-2 hours post-coating.

It will be recognized by the person of ordinary skill in the art that combinations of post-deposition processing methods can be used. For example, the coating layer may be sealed and then polished to reduce surface roughness.

In certain configurations, a substrate to receive a coating can be cleaned. The substrate can then be rinsed. The substrate can then be subjected to acid treatment. The acid treated substrate is then rinsed. The rinsed substrate is then added to a plating tank. The plated substrate can optionally be rinsed. The substrate with the coated surface can then be subjected to post-plating processes. Each of these steps are discussed in more detail below. An optional strike step to provide a nickel layer (or a layer of another material) on the surface of the substrate can be performed between steps the acid treatment step and the plating step if desired.

In certain embodiments, the cleaning step can be performed in the presence or absence of an electric current. Cleaning is typically performed in the presence of one or more salts and/or a detergent or surfactant and may be performed at an acidic pH or a basic pH. Cleaning is generally performed to remove any oils, hydrocarbons or other materials from the surface of the substrate.

After the substrate is cleaned, the substrate is rinsed to remove any cleaning agents. The rinsing is typically performed in distilled water but may be performed using one or more buffers or at an acidic pH or a basic pH. Rinsing may be performed once or numerous times. The substrate is typically kept wet between the various steps to minimize oxide formation on the surface. A water break test can be performed to verify the surface is clean and/or free of any oils.

After rinsing, the substrate can be immersed in an acid bath to activate the surface for electrodeposition, e.g., to pickle the surface. The exact acid used is not critical. The pH of the acidic treatment may be 0-7 or even less than 0 if desired. The time the substrate remains in the acid bath may vary, for example, from 10 seconds to about 10 minutes. The acidic solution can be agitated or pumped over the substrate surface if desired, or the substrate may be moved within the acidic tank during the pickling process.

After the pickling process, the surface can be rinsed to remove any acid. The rinsing may be performed by immersing the pickled substrate into a rinse bath, by flowing rinse agent over the surface or both. Rinsing can be performed multiple times or a single time as desired.

After pickling, the substrate can optionally be subjected to a strike. Without wishing to be bound by any one configuration, a strike applies a thin layer of material to a substrate that is typically inert or less reactive with the material to be deposited. Examples of inert substrates include, but are not limited to, stainless steels, titanium, certain metal alloys and other materials. In the strike process, a thin layer of material, e.g., up to a few microns thick, is applied using electrodeposition.

The rinsed, pickled substrate, or a rinsed substrate with the strike layer, can then be subjected to an electrodeposition process as noted above to apply a layer of material to the substrate surface. As noted herein, electrodeposition can be performed using AC voltages or DC voltages and various waveforms. The exact current density used can vary to favor or disfavor a particular amount of the elements that end up in the resulting coating. For example, where an alloy layer includes two metals, the current density can be selected so one metal is present in a higher amount than the other metal in the resulting alloy layer. The pH of the electrodeposition bath may also vary depending on the particular species that are intended to be present in the surface coating. For example, an acidic bath (pH=3-5.5), a neutral pH bath, or a basic pH bath (pH 9-12) may be used depending on the materials present in the electrodeposition bath and in the anode. The exact temperature used during the electrodeposition process may vary from room temperature (about 25 deg. Celsius) up to about 85 degrees Celsius. The temperature is desirably less than 100 deg. Celsius so water in the electrodeposition bath does not evaporate to a substantial degree. The electrodeposition bath can include the materials to be deposited along with optional agents including brighteners, levelers, particles, etc. as noted herein.

In some embodiments, the electrodeposition bath can include a brightener. A variety of organic compounds are used as brighteners in to provide a bright, level, and ductile nickel deposit. Brighteners can generally be divided into two classes. Class I, or primary, brighteners include compounds such as aromatic or unsaturated aliphatic sulfonic acids, sulfonamides, sulfonimides, and sulfimides. Class I brighteners can be used in relatively high concentrations and produce a hazy or cloudy deposit on the metal substrate. Decomposition of Class I brighteners during the electroplating process can cause sulfur to be incorporated into the deposit, which reduces the tensile stress of the deposit. Class II, or secondary, brighteners are used in combination with Class I brighteners to produce a fully bright and leveled deposit. Class II brighteners are generally unsaturated organic compounds. A variety of organic compounds containing unsaturated functional groups such as alcohol, diol, triol, aldehydic, olefinic, acetylinic, nitrile, and pyridine groups can be used as Class II brighteners. Typically, Class II brighteners are derived from acetylinic or ethylenic alcohols, ethoxylated acetylenic alcohols, coumarins and pyridine based compounds. Mixtures of such unsaturated compounds with mixtures of Class I brighteners can be combined to obtain maximum brightness or ductility for a given rate of leveling. A variety of amine compounds can also be used as brightening or leveling agents. Acyclic amines can be used as Class II brighteners. Acetylenic amines can be used in combination with acetylenic compounds to improve leveling and low current density coverage.

In certain embodiments, the resulting amount of metals present in the alloy layer can vary. For example, in one electrodeposition process where two metals are present in the surface coating, one of the metals, e.g., molybdenum, may be present up to about 35 weight percent based on a weight of the surface coating. In other embodiments, one of the metals, e.g., molybdenum, may be present up to about 20 weight percent based on a weight of the surface coating. In some examples, one of the metals, e.g., molybdenum, may be present up to about 16 weight percent based on a weight of the surface coating. In some examples, one of the metals, e.g., molybdenum, may be present up to about 10 weight percent based on a weight of the surface coating. In some examples, one of the metals, e.g., molybdenum, may be present up to about 6 weight percent based on a weight of the surface coating.

In certain configurations, the substrate with the surface coating can then be rinsed or can be subjected to another deposition process to apply a second layer onto the formed first layer. The second deposition process can be, for example, vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods. In some instances, a second electrodeposition step can be used to apply a second layer on top of the formed first layer. For example, the second layer can be an electrodeposited layer including one, two, three or more metal or other materials. If desired, additional layer can be formed on the second layer using electrodeposition or any of the other processes mentioned herein.

In other configurations, a layer of material can be deposited on a cleaned or pickled substrate prior to forming a layer using an electrodeposition process. For example, one or more layers can first be formed on a substrate using vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods. A second layer can be formed on the first layer using an electrodeposition process as noted herein. If desired, the first formed layer can be activated by a pickling process prior to electrodeposition of the second layer on the first layer.

In instances where a single layer is formed on a substrate by electrodeposition, the substrate with the coated surface can then be subjected to one or more post-processing steps including, for example, rinsing, polishing, sanding, heating, annealing, consolidating, etching or other steps to either clean the coated surface or alter the physical or chemical properties of the coated surface. If desired, some portion of the coating can be removed using an acidic solution or a basic solution depending on the materials present in the coating.

In certain embodiments, a method of producing an alloy layer on a substrate comprises forming a coated surface on the substrate by electrodepositing an alloy layer on the surface of the substrate. The electrodeposited alloy layer comprises (i) molybdenum and (ii) at least one element selected from the group consisting of nickel, tungsten, cobalt, chromium, tin, phosphorous, iron, magnesium and boron or at least one compound comprising one or more of nickel, tungsten, cobalt, chromium, tin, phosphorous, iron, magnesium or boron. In some examples, the method comprises, prior to electrodepositing the alloy layer, cleaning the substrate, rinsing the cleaned substrate, activating a surface of the cleaned substrate to provide an activated substrate, rinsing the activated substrate, and electrodepositing the alloy layer on the activated substrate. In some embodiments, the method comprises subjecting the electrodeposited alloy layer to a post deposition treatment process. In additional embodiments, the post deposition treatment process is selected from the group consisting of rinsing, polishing, sanding, heating, annealing, and consolidating. In some examples, the method comprises providing an additional layer on the electrodeposited alloy layer. In other examples, the additional layer is provided using one of vacuum deposition, physical vapor deposition, chemical vapor deposition, plasma deposition, brushing, spin-coating, spray coating, electrodeposition/electroplating, electroless deposition/plating, high velocity oxygen fuel coating, or thermal spraying.

In some configurations, prior to electrodepositing the alloy layer, an intermediate layer of material can be provided between the substrate and the electrodeposited alloy layer. In some examples, the intermediate layer is provided using one of vacuum deposition, physical vapor deposition, chemical vapor deposition, plasma deposition, brushing, spin-coating, spray coating, electrodeposition/electroplating, electroless deposition/plating, high velocity oxygen fuel coating, or thermal spraying. In certain embodiments, the electrodepositing uses a soluble anode or uses an insoluble anode. In some instances, the soluble anode comprises nickel or another metal.

In certain examples, the coating layers described herein can be applied to the substrate using suitable methodologies including, but not limited to, vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods.

In certain examples, one or more of the coating layers may be deposited using vacuum deposition. In certain embodiments, vacuum deposition generally deposits a layer of material atom-by-atom or molecule-by-molecule on a surface of a substrate. Vacuum deposition processes can be used to deposit one or more materials with a thickness from one or more atoms up to a few millimeters.

In certain embodiments, physical vapor deposition (PVD), a type of vacuum deposition, can be used to deposit one or more of the coating layers described herein. PVD generally uses a vapor of the materials to produce a thin coating on the substrate. The coatings described herein may be, for example, sputtered onto a surface of the substrate or applied onto a surface of the substrate using evaporation PVD. In other embodiments, one or more coating layers can be produced on a substrate using chemical vapor deposition (CVD). CVD generally involves exposing the substrate to one or more materials that react and/or decompose on the surface of the substrate to provide a desired coating layer on the substrate. In other configurations, plasma deposition (PD), e.g., plasma enhanced chemical vapor deposition or plasma assisted chemical vapor deposition, can be used to provide a coating layer on a substrate. PD generally involves creating a plasma discharge from reacting gases including the material to be deposited and/or subjecting an already deposited material to ions in a plasma gas to modify the coating layer. In other examples, atomic layer deposition (ALD) can be used to provide a coating layer on a surface. In ALD, a substrate surface is exposed to repeated amounts of precursors that can react with a surface of a material to build up the coating layer.

In other examples, one or more of the coating layers described herein can be deposited into a surface of a substrate using brushing, spin-coating, spray coating, dip coating, electrodeposition (e.g., electroplating, cathodic electrodeposition, anodic electrodeposition, etc.), electroless plating, electrocoating, electrophoretic deposition, or other techniques. Where an electric current is used to deposit a coating layer on a substrate, the current may be continuous, pulsed or combinations of continuous current and pulsed current can be used. Certain electrodeposition techniques are described in more detail below.

In some configurations, one or more layers of the coating may be applied using electrodeposition. In general, electrodeposition uses a voltage applied to the substrate placed in a bath to form the coating on the charged substrate. For example, ionic species present in the bath can be reduced using the applied voltage to deposit the ionic species in a solid form onto a surface (or all surfaces) of the substrate. As noted in more detail below, the ionic species can be deposited to provide a metal coating, a metal alloy coating or combinations thereof. Depending on the exact ionic species used and the electrodeposition conditions and techniques, the resulting properties of the formed, electrodeposited coating may be selected or tuned to provide a desired result.

In certain embodiments where electrodeposition is used, the ionic species may be dissolved or solvated in an aqueous solution or water. The aqueous solution may include suitable dissolved salts, inorganic species or organic species to facilitate electrodeposition of the coating layer(s) on the substrate. In other embodiments where electrodeposition is used, the liquid used in the electrodeposition bath may generally be non-aqueous, e.g., include more than 50% by volume of non-aqueous species, and may include hydrocarbons, alcohols, liquified gases, amines, aromatics and other non-aqueous materials.

In general, the electrodeposition bath includes the species to be deposited as a coating on the substrate. For example, where nickel is deposited onto a substrate, the bath can include ionic nickel or solvated nickel. Where molybdenum is deposited into a substrate, the bath can include ionic molybdenum or solvated molybdenum. Where an alloy is to be deposited on a substrate, the bath can include more than a single species, e.g., the bath may include ionic nickel and ionic molybdenum that are co-electrodeposited to form a nickel-molybdenum alloy as a coating layer on a substrate. The exact form of the materials added to the bath to provide ionic or solvated species can vary. For example, the species may be added to the bath as metal halides, metal fluorides, metal chlorides, metal carbonates, metal hydroxides, metal acetates, metal sulfates, metal nitrates, metal nitrites, metal chromates, metal dichromates, metal permanganates, metal platinates, metal cobalt-nitrites, metal hexachloroplatinates, metal citrates, ammonium salt of the metal, metal cyanides, metal oxides, metal phosphates, metal monobasic sodium phosphates, metal dibasic sodium phosphates, metal tribasic sodium phosphates, sodium salt of the metal, potassium salt of the metal, metal sulfamate, metal nitrite, and combinations thereof. In some examples, a single material that includes both of the metal species to be deposited can be dissolved in the electrodeposition bath, e.g., a metal alloy salt can be dissolved in a suitable solution prior to electrodeposition. The specific materials used in the electrodeposition bath depends on the particular alloy layer to be deposited. Illustrative materials include, but are not limited to, nickel sulfate, nickel sulfamate, nickel chloride, sodium tungstate, tungsten chloride, sodium molybdate, ammonium molybdate, cobalt sulfate, cobalt chloride, chromium sulfate, chromium chloride, chromic acid, stannous sulfate, sodium stannate, hypophosphite, sulfuric acid, nickel carbonate, nickel hydroxide, potassium carbonate, ammonium hydroxide, hydrochloric acid or other materials.

In certain embodiments, the exact amount or concentration of the species to be electrodeposited onto a substrate may vary. For example, the concentration of the species may vary from about 1 gram/Liter to about 400 grams/Liter. If desired, as the ionic species are depleted as a result of formation of the coating on the substrate, additional material can be added to the bath to increase an amount of the species available for electrodeposition. In some instances, the concentration of the species to be deposited may be maintained at a substantially constant level during electrodeposition by continuously adding material to the bath.

In certain embodiments, the pH of the electrodeposition bath may vary depending on the particular ionic species present in the bath. For example, the pH may vary from 1 to about 13, but in certain instances, the pH may be less than 1, or even less than 0, or greater than 13 or even greater than 14. Where metal species are deposited as metal alloys onto a substrate, the pH may range, in certain instances, from 4 to about 12. It will be recognized, however, that the pH may be varied depending on the particular voltage and electrodeposition conditions that are selected for use. Some pH regulators and buffers may be added to the bath. Examples of pH regulators include but not limited to boric acid, hydrochloric acid, sodium hydroxide, potassium hydroxide, ammonium hydroxide, glycine, Sodium acetate, buffered saline, Cacodylate buffer, Citrate buffer, Phosphate buffer, Phosphate-citrate buffer, Barbital buffer, TRIS buffers, Glycine-NaOH buffer, and any combination thereof.

In certain embodiments, alloy plating can use a complexing agent. For example, the main role of complexing agents in an alloy deposition process is making complexations of different metallic ions. Therefore, without a proper complexing agent, simultaneous deposition of nickel and molybdenum and alloy formation will not occur. Examples of complexing agents include but are not limited to phosphates, phosphonates, polycarboxylates, zeolites, citrates, ammonium hydroxide, ammonium salts, citric acid, ethylenediaminetetraacetic acid, diethylene-triaminepentaacetic acid, aminopolycarboxylates, nitrilotriacetic acid, IDS (N-(1,2-dicarboxyethyl)-D,L-aspartic acid (iminodisuccinic acid), DS (polyaspartic acid), EDDS (N,N′-ethylenediaminedisuccinic acid), GLDA (N,N-bis(carboxylmethyl)-L-glutamic acid) and MGDA (methylglycinediacetic acid), hexamine cobalt (III) chloride, ethylene glycol-bis(β-aminoethyl ether)-N,N,N′,N′-tetraacetic acid (EGTA), ferrocene, cyclodextrins, choleic acid, polymers, and any combination thereof.

In some examples, a suitable voltage can be applied to cathodes and anodes of the electrodeposition bath to promote formation of the layer(s) described herein on a substrate. In some embodiments, a direct current (DC) voltage can be used. In other examples, an alternating current (AC) optionally in combination with current pulses can be used to electrodeposit the layers. For example, AC electrodeposition can be carried out with an AC voltage waveform, in general sinusoidal, squared, triangular, and so on. High voltages and current densities can be used to favor the tunneling of electrons through an oxide base layer that can form on the substrate. Furthermore, the base layer can conduct in the direction of the cathode, which favors the deposition of the material and avoids its reoxidation during the oxidant half-cycle.

In certain embodiments, illustrative current density ranges that can be used in electrodeposition include, but are not limited to 1 mA/cm² DC to about 600 mA/cm² DC, more particularly about 1 mA/cm² DC to about 300 mA/cm² DC. In some examples, the current density can vary from 5 mA/cm² DC to about 300 mA/cm² DC, from 20 mA/cm² DC to about 100 mA/cm² DC, from 100 mA/cm² DC to about 400 mA/cm² DC or any value falling within these illustrative ranges. The exact time that the current is applied may vary from about 10 seconds to a few days, more particularly about 40 seconds to about 2 hours. A pulse current can also be applied instead of a DC current if desired.

In some examples, the electrodeposition may use pulse current or pulse reverse current is during the electrodeposition of the alloy layer. In pulse electrodeposition (PED), the potential or current is alternated swiftly between two different values. This results in a series of pulses of equal amplitude, duration and polarity, separated by zero current. Each pulse consists of an ON-time (TON) during which potential and/current is applied, and an OFF-time (TOFF) during which zero current is applied. It is possible to control the deposited film composition and thickness in an atomic order by regulating the pulse amplitude and width. They favor the initiation of grain nuclei and greatly increase the number of grains per unit area resulting in finer grained deposit with better properties than conventionally plated coatings.

In examples where the coating includes two or more layers, the first layer and the second layer of the coating may be applied using the same or different electrodeposition baths. For example, a first layer can be applied using a first aqueous solution in an electrodeposition bath. After application of a voltage for a sufficient period to deposit the first layer, the voltage may be reduced to zero, the first solution can be removed from the bath and a second aqueous solution comprising a different material can be added to the bath. A voltage can then be reapplied to electrodeposit a second layer. In other instances, two separate baths can be used, e.g., a reel-to-reel process can be used, where the first bath is used to electrodeposit the first layer and a second, different bath is used to deposit the second layer.

In some cases, individual articles may be connected such that they can be sequentially exposed to separate electrodeposition baths, for example in a reel-to-reel process. For instance, articles may be connected to a common conductive substrate (e.g., a strip). In some embodiments, each of the electrodeposition baths may be associated with separate anodes and the interconnected individual articles may be commonly connected to a cathode.

While the exact material used in electroplating methods may vary, illustrative materials include cations of one or more of the following metals: nickel, molybdenum, copper, aluminum, cobalt, tungsten, gold, platinum, palladium, silver, or combinations thereof. The exact anion form of these metals may vary from chlorides, acetates, sulfates, nitrates, nitrites, chromates, dichromates, permanganates, platinates, cobalt nitrites, hexachloroplatinates, citrates, cyanides, oxides, phosphates, monobasic sodium phosphates, dibasic sodium phosphates, tribasic sodium phosphates and combinations thereof.

In other instances, the electrodeposition process can be designed to apply an alloy layer including molybdenum and one or more of nickel, tungsten, cobalt, chromium, tin, phosphorous, iron, magnesium and boron or at least one compound comprising one or more of nickel, tungsten, cobalt, chromium, tin, phosphorous, iron, magnesium or boron. In some embodiments, the resulting alloy layer may be free of precious metals.

In some embodiments, there may be no intervening or intermediate layers between the coating layer 110 and the substrate 105. For example, the coating layer 110 can be deposited directly onto the substrate surface 105 without any intervening layer between them. In other instances, an intermediate layer may be present between the coating layer 110 and the surface 106 of the substrate 105. The intermediate layer can be formed using the same methods used to form the coating layer 110 or different methods used to form the coating layer 110. In some embodiments, an intermediate layer can include one or more of copper, a copper alloy, nickel, a nickel alloy, a nickel-phosphorous alloy, a nickel-phosphorous alloy including hard particles or other compounds such as phosphorous, boron, boron nitride, silicon carbide, aluminum oxide, molybdenum disulfide, hard particles with a hardness of HV>1000, hard particles with size less 500 nm, highly conductive particles, carbon nanotubes and or carbon nano-particles. In other instances, the intermediate layer can include an alloy of nickel that is less magnetic than nickel alone. In some instances, the intermediate layer may be substantially less than the coating layer 110 and can be used to enhance adhesion of the coating layer 110 to the substrate 105. For example, the intermediate layer can be 90%, 80%, 70%, 60%, 50%, 40%, 30%, 20% or 10% less thick than a thickness of the coating layer 110. In certain embodiments, the layer between the substrate and the alloy layer may be a “nickel strike” layer as is commonly known in the electroplating arts.

In some embodiments, one or more of the materials of a coating layer can be provided using a soluble anode. The soluble anode can dissolve in the electrodeposition bath to provide the species to be deposited. In some embodiments, the soluble anode may take the form of a disk, a rod, a sphere, strips of materials or other forms. The soluble anode can be present in a carrier or basket coupled to a power source.

In some embodiments, one or more of the coating layers described herein may be deposited using an anodization process. Anodization generally uses the substrate as the anode of an electrolytic cell. Anodizing can change the microscopic texture of the surface and the resulting metal coating near the surface. For example, thick coatings are often porous and can be sealed to enhance corrosion resistance. Anodization can result in harder and more corrosion resistant surfaces. In some examples, one of the coating layers of the articles described herein can be produced using an anodization process and another coating layer may be produced using a non-anodization process. In other instances, each coating layer in the article can be produced using an anodization process. The exact materials and process conditions using anodization may vary. Generally, the anodized layer is grown on a surface of the substrate by applying a direct current through an electrolyte solution including the material to be deposited. The material to be deposited can include magnesium, niobium, tantalum, zinc, nickel, molybdenum, copper, aluminum, cobalt, tungsten, gold, platinum, palladium, silver, or alloys or combinations thereof. Anodization is typically performed under acidic conditions and may include chromic acid, sulfuric acid, phosphoric acid, organic acids or other acids.

In certain embodiments, the coatings described herein may be applied in the presence of other additive or agents. For example, wetting agents, leveling agents, brighteners, defoaming agents and/or emulsifiers can be present in aqueous solutions that include the materials to be deposited onto the substrate surface. Illustrative additive and agents include, but are not limited to, thiourea, domiphen bromide, acetone, ethanol, cadmium ion, chloride ion, stearic acid, ethylenediamine dihydrochloride (EDA), saccharin, cetyltrimethylammonium bromide (CTAB), sodium dodecyl sulfate, sodium lauryl sulfate (SLS), saccharine, naphthalene sulfonic acid, benzene sulfonic acid, coumarin, ethyl vanillin, ammonia, ethylene diamine, polyethylene glycol (PEG), bis(3-sulfopropyl)disulfide (SPS), Janus green B (JGB), azobenzene-based surfactant (AZTAB), the polyoxyethylene family of surface active agents, sodium citrate, perfluorinated alkylsulfate, additive K, calcium chloride, ammonium chloride, potassium chloride, boric acid, myristic acid, choline chloride, citric acid, any redox active surfactant, any conductive ionic liquids, polyglycol ethers, polyglycol alcohols, sulfonated oleic acid derivatives, sulfate form of primary alcohols, alkylsulfonates, alkylsulfates, aralkylsulfonates, sulfates, Perfluoro-alkylsulfonates, acid alkyl and aralkyl-phosphoric acid esters, alkylpolyglycol ether, alkylpolyglycol phosphoric acid esters or their salts, N-containing and optionally substituted and/or quaternized polymers, such as polyethylene imine and its derivatives, polyglycine, poly(allylamine), polyaniline (sulfonated), polyvinylpyrrolidone, gelatin, polyvinylpyridine, polyvinylimidazole, polyurea, polyacrylamide, poly(melamine-co-formaldehyde), polyalkanolamines, polyaminoamide and derivatives thereof, polyalkanolamine and derivatives thereof, polyethylene imine and derivatives thereof, quaternized polyethylene imine, poly(allylamine), polyaniline, polyurea, polyacrylamide, poly(melamine-co-formaldehyde), hydroxy-ethyl-ethylene-diamine triacetic acid, 2 Butyne 1 4 diol, 2 2 azobis(2-methyl propionitrite), perfluoroammonoic acid, dextrose, cetyl methyl ammonium bromide, 1 hexadecyl pyridinium-chloride, d-mannitol, glycine, Rochelle salt, N N′-diphenylbenzidine, glycolic acid, tetra-methyl-ammonium hydroxide, reaction products of amines with epichlorohydrin, reaction products of an amine, epichlorohydrin, and polyalkylene oxide, reaction products of an amine with a polyepoxide, polyvinylpyridine, polyvinylimidazole, polyvinylpyrrolidone, or copolymers thereof, nigrosines, pentamethyl-para-rosaniline, one or more of fats, oils, long chained alcohols, or glycols, polyethylene glycols, polyethylene oxides such as Tritons, alkylphosphates, metal soaps, special silicone defoamers, commercial perfluoroalkyl-modified hydrocarbon defoamers and perfluoroalkyl-substituted silicones, fully fluorinated alkylphosphonates, perfluoroalkyl-substituted phosphoric acid esters, cationic-based agents, amphoteric-based agents, and nonionic-based agent; chelating agents such as citrates, acetates, gluconates, and ethylenediamine tetra-acetic acid (EDTA), or any combination thereof.

In embodiments where electroless plating is used, metal coatings can be produced on a substrate by autocatalytic chemical reduction of metal cations in a bath. In contrast to electrodeposition/electroplating, no external electric current is applied to the substrate in electroless plating. While not wishing to be bound by any particular configuration or example, electroless plating can provide more even layers of the material on the substrate compared to electroplating. Further, electroless plating may be used to add coatings onto non-conductive substrates.

In certain embodiments where electroless plating is used, the substrate itself may act as a catalyst to reduce an ionic metal and form a coating of the metal on the surface of the substrate. Where it is desirable to produce a metal alloy coating, the substrate may act to reduce two or more different ionic metals with the use of a complexing agent to form a metal alloy including the two different metals. In some examples, the substrate itself may not function as a catalyst but a catalytic material can be added to the substrate to promote formation of the metal coating on the substrate. Illustrative catalytic materials that can be added to a substrate include, but are not limited to, palladium, gold, silver, titanium, copper, tin, niobium, and any combination thereof.

While the exact material used in electroless plating methods may vary, illustrative materials include one or more of the following cations: magnesium, niobium, tantalum, zinc, nickel, molybdenum, copper, aluminum, cobalt, tungsten, gold, platinum, palladium, silver, or alloys or combinations thereof. For example, any one or more of these cations can be added as a suitable salt to an aqueous solution. Illustrative suitable salts include, but are not limited to, metal halides, metal fluorides, metal chlorides, metal carbonates, metal hydroxides, metal acetates, metal sulfates, metal nitrates, metal nitrites, metal chromates, metal dichromates, metal permanganates, metal platinates, metal cobalt nitrites, metal hexachloroplatinates, metal citrates, metal cyanides, metal oxides, metal phosphates, metal monobasic sodium phosphates, metal dibasic sodium phosphates, metal tribasic sodium phosphates and combinations thereof.

In certain embodiments, the substrates described herein may be subjected to pre-coating processing steps to prepare the substrate to receive a coating. These processing steps can include, for example, cleaning, electro-cleaning (anodic or cathodic), polishing, electro-polishing, pre-plating, thermal treatments, abrasive treatments and chemical treatments. For example, the substrates can be cleaned with an acid, a base, water, a salt solution, an organic solution, an organic solvent or other liquids or gases. The substrates can be polished using water, an acid or a base, e.g., sulfuric acid, phosphoric acid, etc. or other materials optionally in the presence of an electric current. The substrates may be exposed to one or more gases prior to application of the coating layers to facilitate removal of oxygen or other gases from a surface of the substrate. The substrate may be washed or exposed to an oil or hydrocarbon fluid prior to application of the coating to remove any aqueous solutions or materials from the surface. The substrate may be heated or dried in an oven to remove any liquids from the surface prior to application of the coating. Other steps for treating the substrate prior to application of a coating may also be used. For example, the substrate can be heated to a high temperature, for example, more than 100 deg. C, more than 200 deg C., more than 500 deg C., more than 700 deg C. or more than 1000 deg C. Similarly, the final article including the coating may operate in such high temperatures.

In some embodiments, the coatings layers described herein can be subjected to sealing. While the exact conditions and materials uses to seal the coatings can vary, sealing can reduce the porosity of the coatings and increase their hardness. In some embodiments, sealing may be performed by subjecting the coating to steam, organic additives, metals, metal salts, metal alloys, metal alloy salts, or other materials. The sealing may be performed at temperatures above room temperature, e.g., 30 degrees Celsius, 50 degrees Celsius, 90 degrees Celsius or higher, at room temperature or below room temperature, e.g., 20 degrees Celsius or less. In some examples, the substrate and coating layer may be heated to remove any hydrogen or other gases in the coating layer. For example, the substrate and coating can be baked to remove hydrogen from the article within 1-2 hours post-coating.

It will be recognized by the person of ordinary skill in the art that combinations of post-deposition processing methods can be used. For example, the coating layer may be sealed and then polished to reduce surface roughness.

In certain configurations, an electrodeposition process can include cleaning a substrate to receive a coating. The substrate can then be rinsed. The substrate can then be subjected to acid treatment. The acid treated substrate is then rinsed. The rinsed substrate is then added to a plating tank. The plated substrate can optionally be rinsed. The substrate with the coated surface can then be subjected to post-plating processes. Each of these steps are discussed in more detail below. An optional strike step to provide a nickel layer (or a layer of another material) on the surface of the substrate can be performed if desired.

In certain embodiments, the cleaning step can be performed in the presence or absence of an electric current. Cleaning is typically performed in the presence of one or more salts and/or a detergent or surfactant and may be performed at an acidic pH or a basic pH. Cleaning is generally performed to remove any oils, hydrocarbons or other materials from the surface of the substrate.

After the substrate is cleaned, the substrate is rinsed to remove any cleaning agents. The rinsing is typically performed in distilled water but may be performed using one or more buffers or at an acidic pH or a basic pH. Rinsing may be performed once or numerous times. The substrate is typically kept wet between the various steps to minimize oxide formation on the surface. A water break test can be performed to verify the surface is clean and/or free of any oils.

After rinsing, the substrate can be immersed in an acid bath to activate the surface for electrodeposition, e.g., to pickle the surface. The exact acid used is not critical. The pH of the acidic treatment may be 0-7 or even less than 0 if desired. The time the substrate remains in the acid bath may vary, for example, from 10 seconds to about 10 minutes. The acidic solution can be agitated or pumped over the substrate surface if desired, or the substrate may be moved within the acidic tank during the pickling process.

After the pickling process, the surface can be rinsed to remove any acid. The rinsing may be performed by immersing the pickled substrate into a rinse bath, by flowing rinse agent over the surface or both. Rinsing can be performed multiple times or a single time as desired.

After pickling, the substrate can optionally be subjected to a strike. Without wishing to be bound by any one configuration, a strike applies a thin layer of material to a substrate that is typically inert or less reactive with the material to be deposited. Examples of inert substrates include, but are not limited to, stainless steels, titanium, certain metal alloys and other materials. In the strike process, a thin layer of material, e.g., up to a few microns thick, is applied using electrodeposition.

The rinsed, pickled substrate, or a rinsed substrate with the strike layer, can then be subjected to an electrodeposition process as noted above to apply a layer of material to the substrate surface. As noted herein, electrodeposition can be performed using AC voltages or DC voltages and various waveforms. The exact current density used can vary to favor or disfavor a particular amount of the elements that end up in the resulting coating. For example, where an alloy layer includes two metals, the current density can be selected so one metal is present in a higher amount than the other metal in the resulting alloy layer. The pH of the electrodeposition bath may also vary depending on the particular species that are intended to be present in the surface coating. For example, an acidic bath (pH=3-5.5), a neutral pH bath, or a basic pH bath (pH 9-12) may be used depending on the materials present in the electrodeposition bath and in the anode. The exact temperature used during the electrodeposition process may vary from room temperature (about 25 deg. Celsius) up to about 85 degrees Celsius. The temperature is desirably less than 100 deg. Celsius so water in the electrodeposition bath does not evaporate to a substantial degree. The electrodeposition bath can include the materials to be deposited along with optional agents including brighteners, levelers, particles, etc. as noted herein.

In some embodiments, the electrodeposition bath can include a brightener. A variety of organic compounds are used as brighteners in to provide a bright, level, and ductile nickel deposit. Brighteners can generally be divided into two classes. Class I, or primary, brighteners include compounds such as aromatic or unsaturated aliphatic sulfonic acids, sulfonamides, sulfonimides, and sulfimides. Class I brighteners can be used in relatively high concentrations and produce a hazy or cloudy deposit on the metal substrate. Decomposition of Class I brighteners during the electroplating process can cause sulfur to be incorporated into the deposit, which reduces the tensile stress of the deposit. Class II, or secondary, brighteners are used in combination with Class I brighteners to produce a fully bright and leveled deposit. Class II brighteners are generally unsaturated organic compounds. A variety of organic compounds containing unsaturated functional groups such as alcohol, diol, triol, aldehydic, olefinic, acetylinic, nitrile, and pyridine groups can be used as Class II brighteners. Typically, Class II brighteners are derived from acetylinic or ethylenic alcohols, ethoxylated acetylenic alcohols, coumarins and pyridine based compounds. Mixtures of such unsaturated compounds with mixtures of Class I brighteners can be combined to obtain maximum brightness or ductility for a given rate of leveling. A variety of amine compounds can also be used as brightening or leveling agents. Acyclic amines can be used as Class II brighteners. Acetylenic amines can be used in combination with acetylenic compounds to improve leveling and low current density coverage.

In certain embodiments, the resulting amount of metals present in the alloy layer can vary. For example, in one electrodeposition process where two metals are present in the surface coating, one of the metals, e.g., molybdenum, may be present up to about 35 weight percent based on a weight of the surface coating. In other embodiments, one of the metals, e.g., molybdenum, may be present up to about 20 weight percent based on a weight of the surface coating. In some examples, one of the metals, e.g., molybdenum, may be present up to about 16 weight percent based on a weight of the surface coating. In some examples, one of the metals, e.g., molybdenum, may be present up to about 10 weight percent based on a weight of the surface coating. In some examples, one of the metals, e.g., molybdenum, may be present up to about 6 weight percent based on a weight of the surface coating.

In certain configurations, the substrate with the surface coating can then be rinsed or can be subjected to another deposition process to apply a second layer onto the formed first layer. The second deposition process can be, for example, vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods. In some instances, a second electrodeposition step can be used to apply a second layer on top of the formed first layer. For example, the second layer can be an electrodeposited layer including one, two, three or more metal or other materials. If desired, additional layer can be formed on the second layer using electrodeposition or any of the other processes mentioned herein.

In other configurations, a layer of material can be deposited on a cleaned or pickled substrate prior to forming a layer using an electrodeposition process. For example, one or more layers can first be formed on a substrate using vacuum deposition, physical vapor deposition (PVD), chemical vapor deposition (CVD), plasma deposition, brushing, spin-coating, spray coating, electrodeposition/electroplating, electroless deposition/plating, high velocity oxygen fuel (HVOF) coating, thermal spraying or other suitable methods. A second layer can be formed on the first layer using an electrodeposition process as noted herein. If desired, the first formed layer can be activated by a pickling process prior to electrodeposition of the second layer on the first layer.

In instances where a single layer is formed on a substrate by electrodeposition, the substrate with the coated surface can then be subjected to one or more post-processing steps including, for example, rinsing, polishing, sanding, heating, annealing, consolidating, etching or other steps to either clean the coated surface or alter the physical or chemical properties of the coated surface. If desired, some portion of the coating can be removed using an acidic solution or a basic solution depending on the materials present in the coating.

In certain embodiments, a method of producing an alloy layer on a substrate comprises forming a coated surface on the substrate by electrodepositing an alloy layer on the surface of the substrate. The electrodeposited alloy layer comprises (i) molybdenum and (ii) at least one element selected from the group consisting of nickel, tungsten, cobalt, chromium, tin, phosphorous, iron, magnesium and boron or at least one compound comprising one or more of nickel, tungsten, cobalt, chromium, tin, phosphorous, iron, magnesium or boron. In some examples, the method comprises, prior to electrodepositing the alloy layer, cleaning the substrate, rinsing the cleaned substrate, activating a surface of the cleaned substrate to provide an activated substrate, rinsing the activated substrate, and electrodepositing the alloy layer on the activated substrate. In some embodiments, the method comprises subjecting the electrodeposited alloy layer to a post deposition treatment process. In additional embodiments, the post deposition treatment process is selected from the group consisting of rinsing, polishing, sanding, heating, annealing, and consolidating. In some examples, the method comprises providing an additional layer on the electrodeposited alloy layer. In other examples, the additional layer is provided using one of vacuum deposition, physical vapor deposition, chemical vapor deposition, plasma deposition, brushing, spin-coating, spray coating, electrodeposition/electroplating, electroless deposition/plating, high velocity oxygen fuel coating, or thermal spraying.

In some configurations, prior to electrodepositing the alloy layer, an intermediate layer of material can be provided between the substrate and the electrodeposited alloy layer. In some examples, the intermediate layer is provided using one of vacuum deposition, physical vapor deposition, chemical vapor deposition, plasma deposition, brushing, spin-coating, spray coating, electrodeposition/electroplating, electroless deposition/plating, high velocity oxygen fuel coating, or thermal spraying. In certain embodiments, the electrodepositing uses a soluble anode or uses an insoluble anode. In some instances, the soluble anode comprises nickel or another metal.

In certain embodiments, the articles described herein can be configured as decorative items or include a decorative coating. For example, a decorative item can comprise a substrate and a surface coating on the substrate. The coating can include a single layer or multiple layers as noted above in connection with FIGS. 1-12. In some embodiments, the decorative item or decorative item substrate can include a first layer and a second layer, wherein the first layer comprises a molybdenum alloy (as noted in connection with FIGS. 1-12), and wherein the second layer comprises chromium. For example, the first layer can be formed on the substrate and the second layer can be on the first layer. In certain embodiments, the decorative item can be configured as a hand decorative item, a machine decorative item, a garden decorative item, or a power decorative item.

In some instances, the decorative item can include a substrate and a coating on the substrate. The coating of the decorative item can include a first layer and a second layer, wherein the first layer comprises a molybdenum alloy, a nickel alloy or both. The second layer can comprise chromium. The exact form of the decorative item may vary. In certain embodiments, the first layer can be formed on the substrate and the second layer can be on the first layer.

In certain examples, the decorative item can include any of those materials described in connection with the articles described herein and shown in FIGS. 1-12. For example, the decorative item can include a substrate, at least a first layer and an optional second layer and one or more other layers if desired. The first layer comprises a molybdenum alloy, a nickel alloy or both and optionally other materials. The second layer can include chromium, chromium compounds and optionally other materials. In some examples, the first layer of the decorative item coating comprises a nickel molybdenum alloy. For example, the molybdenum can be present in the first layer at 35% by weight or less. Alternatively, nickel can be present in the first layer at 65% by weight or more.

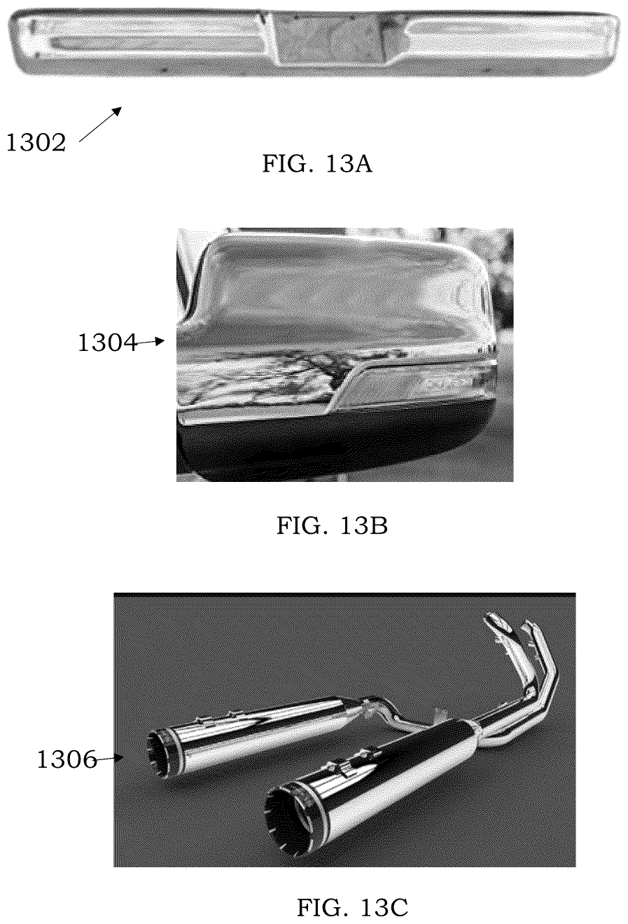

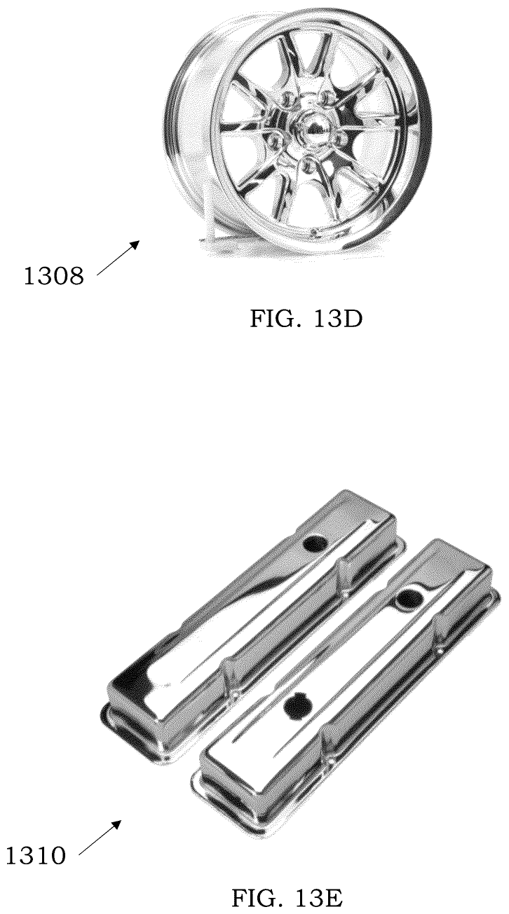

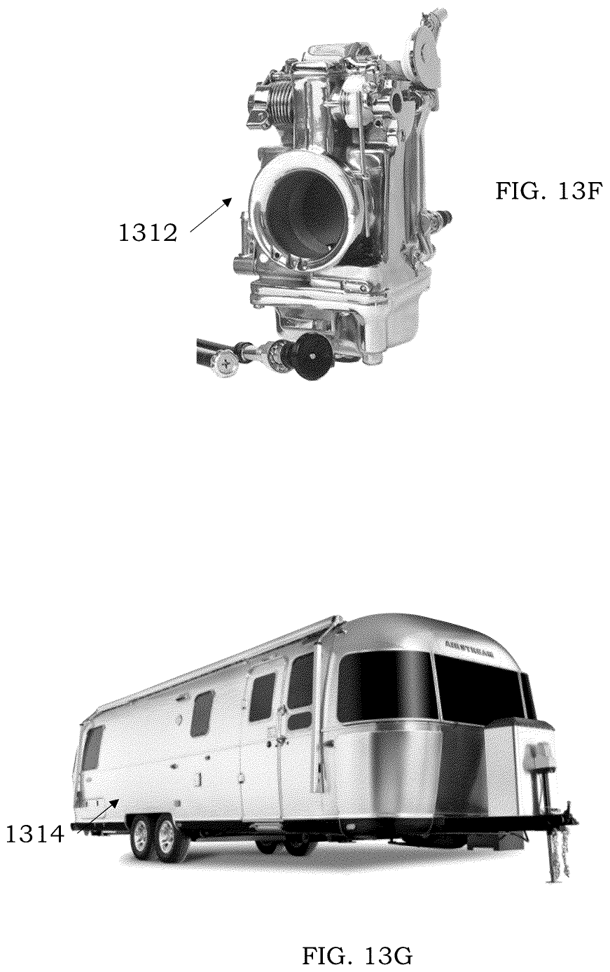

In certain embodiments, the articles described herein may be configured as a vehicle part. For example, a vehicle part can comprise a substrate configured to couple to a vehicle, and a coating on the substrate, wherein the coating comprises a first layer and a second layer, wherein the first layer comprises a molybdenum alloy or a nickel alloy (or both), and wherein the second layer comprises chromium. In some embodiments, the vehicle part may be configured as an exterior vehicle component, an interior vehicle component, a bumper 1302 (see FIG. 13A), a mirror 1304 (FIG. 13B), a vehicle exhaust 1306 (FIG. 13C), a vehicle rim 1308 (FIG. 13D), a vehicle engine component 1310 (FIG. 13E), a motorcycle component 1312 (FIG. 13F), a recreational vehicle component or recreational vehicle 1314 (FIG. 13G) or other vehicle components. In certain embodiments, the first layer can be formed on the substrate and the second layer can be on the first layer.

In certain examples, the vehicle part can include any of those materials described in connection with the articles described herein, e.g., can include the layers described in reference to FIGS. 1-12. For example, the vehicle part can include a substrate, at least a first layer and a second layer. The first layer comprises a molybdenum alloy, a nickel alloy or both and optionally other materials. The second layer can include chromium, chromium compounds and optionally other materials. In some examples, the first layer of the vehicle part coating comprises a nickel molybdenum alloy. For example, the molybdenum can be present in the first layer at 20% by weight or less. Alternatively, nickel can be present in the first layer at 80% by weight or more.

In other configurations, the vehicle part can include one or more layers between the first layer and the second layer, whereas in some configurations the coating can only include the first layer and the second layer. For example, an intermediate layer can be present between the first layer and the second layer so the vehicle part includes three layers on a substrate as noted above. The exact material(s) present in the intermediate layers may vary. For example, the intermediate layer can include one or more transition metals, particles, nanoparticles, refractory metals, metal alloys, etc. In some embodiments, the intermediate layer may be a “bright” or “semi-bright” layer as noted herein.

In certain embodiments, the first layer and the second layer of the vehicle part can be formed or otherwise deposited in numerous different manners as noted herein. In some instances, the first layer of the vehicle part can include an electrodeposited molybdenum alloy coating, an electroplated molybdenum alloy coating, an electroless deposited molybdenum alloy coating, an electrodeposited nickel alloy coating, an electroplated nickel alloy coating or an electroless deposited nickel alloy coating.

In certain embodiments, the first layer and the second layer of the vehicle part may together provide some corrosion resistance or other desired properties. For example, a coating including a first layer and a second layer (and optionally an intermediate layer) may exhibit less than 7% corrosion on its surface after 500 hours of the standard salt spray test per ASTM B 117-19.

In some configurations, the coating or individual layers of the coating may be free or certain metals or metal alloys to enhance overall performance. For example, the first layer, the second layer or both of a vehicle part may be free of iron or free of precious metals. In other instances, the first layer, the second layer or both of a vehicle part may be free of tungsten. If desired, the first layer and/or the second layer of the vehicle part may be free of both iron and tungsten.

In certain embodiments where a vehicle part includes a first layer and a second layer comprising chromium, one or more layers may be present between the first layer (e.g., a layer comprising a Mo alloy or a Ni alloy) and the substrate of the vehicle part. For example, one or more of an adhesion promotion layer, a corrosion promotion layer, a grain refinements layer, etc. may be present between the substrate of the vehicle part and the first layer.

In certain configurations where a substrate of a vehicle part includes a first layer (e.g., a layer comprising a Mo alloy or a Ni alloy) and a second layer, the substrate of the vehicle part may be any of those materials listed herein for substrates. For example, the substrate can include one or more of copper, a copper alloy, nickel, a nickel alloy, cobalt, a cobalt alloy, a plastic, steel, carbon steel, stainless steel, tool steel, galvanized steel, alloy steel, a superalloy, a nickel-chromium superalloy, nickel-chromium-iron-molybdenum alloy, zinc, a zinc alloy, titanium, a titanium alloy, aluminum, an aluminum alloy or other materials and combinations noted herein.

In some embodiments, one or more surfaces of the substrate of the vehicle part can be treated (e.g., physically or chemically) prior to placing the first layer on the substrate. For example, one or more substrate surfaces of the vehicle part can be hardened, carburized, nitrated, anodized or may be treated to provide combinations thereof.

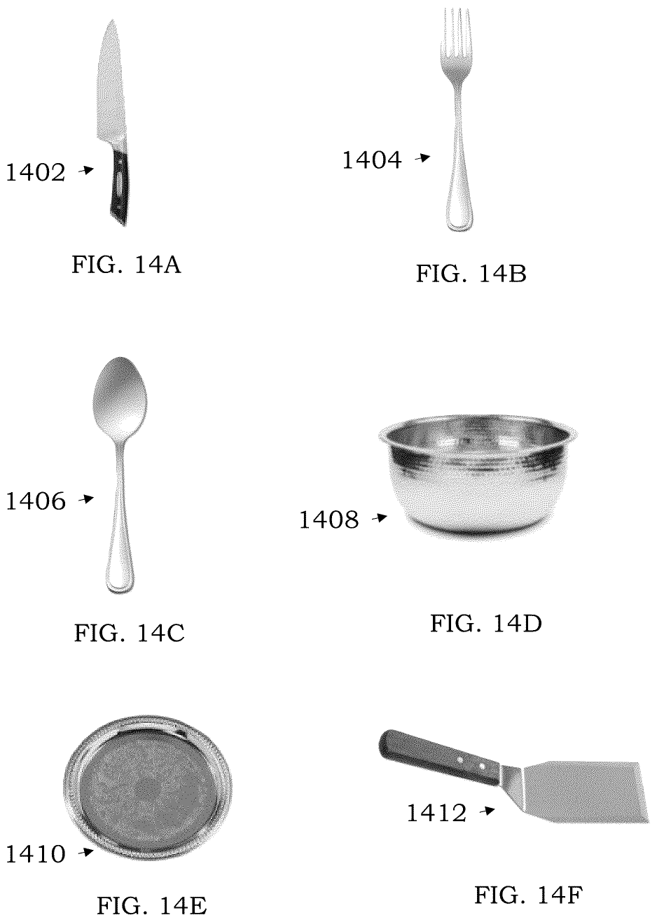

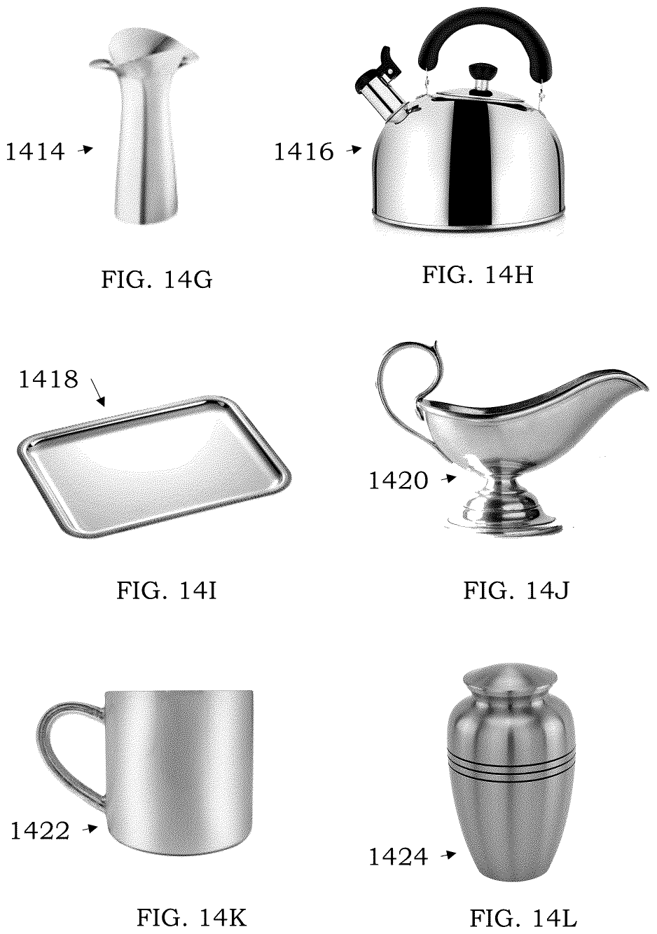

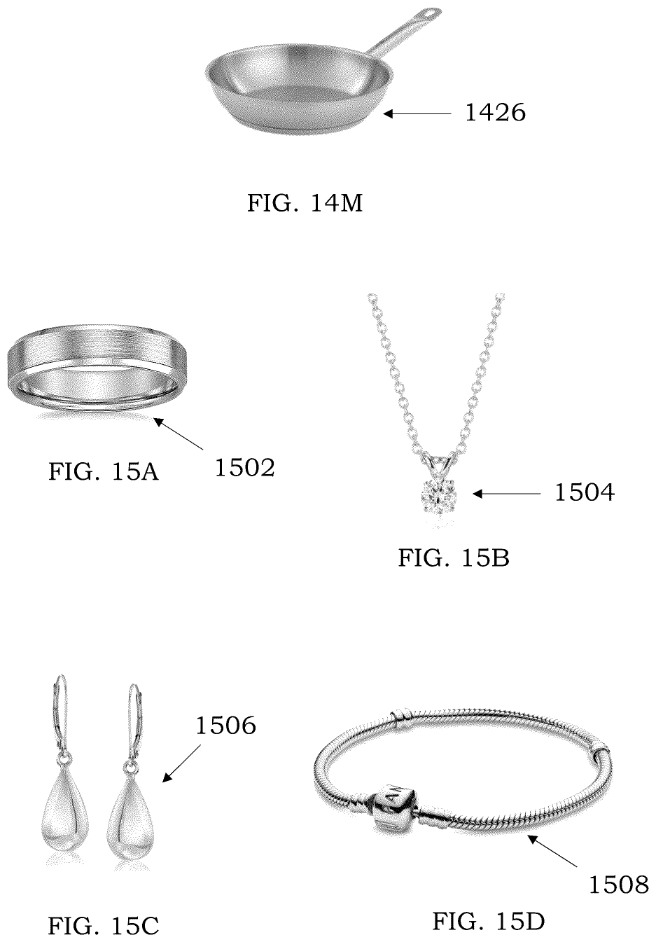

In other configurations, the articles described herein can be configured as an interior household article. For example, the interior household article can include a substrate and a coating on the substrate. The coating of the interior household article can include a first layer and a second layer, wherein the first layer comprises a molybdenum alloy, a nickel alloy or both. The second layer can comprise chromium. The exact form of the interior household article may vary and illustrative forms include those articles where it is desirable to have a shiny surface. For example, the interior household article may be a knife 1402 (FIG. 14A), a fork 1404 (FIG. 14B), a spoon 1406 (FIG. 14C), a bowl 1408 (FIG. 14D), a plate 1410 (FIG. 14E), a spatula 1412 (FIG. 14F), a vase 1414 (FIG. 14G), a tea kettle 1416 (FIG. 14H), a serving tray 1418 (FIG. 14I), a gravy bowl 14 (FIG. 14), a mug 1422 (FIG. 14K), an urn 1424 (FIG. 14L), a cooking pan 1426 (FIG. 14M) and other household items including, but not limited to, a bathroom fitting, cabinet hardware, a refrigerator, a stove, a dishwasher, a sink, a bathtub, a shower basin or a shower wall. In certain embodiments, the first layer can be formed on the substrate and the second layer can be on the first layer.

In certain examples, the interior household article can include any of those materials or layers described in connection with the articles of FIGS. 1-12. For example, the interior household article can include a substrate, at least a first layer and a second layer. The first layer comprises a molybdenum alloy, a nickel alloy or both and optionally other materials. The second layer can include chromium, chromium compounds and optionally other materials. In some examples, the first layer of the interior household article coating comprises a nickel molybdenum alloy. For example, the molybdenum can be present in the first layer at 20% by weight or less. Alternatively, nickel can be present in the first layer at 80% by weight or more.

In other configurations, the interior household article can include one or more layers between the first layer and the second layer, whereas in some configurations the coating can only include the first layer and the second layer. For example, an intermediate layer can be present between the first layer and the second layer so the interior household article includes three layers on a substrate as noted above. The exact material(s) present in the intermediate layers may vary. For example, the intermediate layer can include one or more transition metals, particles, nanoparticles, refractory metals, metal alloys, etc. In some embodiments, the intermediate layer may be a “bright” or “semi-bright” layer as noted herein.

In certain embodiments, the first layer and the second layer of the interior household article can be formed or otherwise deposited in numerous different manners as noted herein. In some instances, the first layer of the interior household article can include an electrodeposited molybdenum alloy coating, an electroplated molybdenum alloy coating, an electroless deposited molybdenum alloy coating, an electrodeposited nickel alloy coating, an electroplated nickel alloy coating or an electroless deposited nickel alloy coating.

In certain embodiments, the first layer and the second layer of the interior household article may together provide some corrosion resistance or other desired properties. For example, a coating including a first layer and a second layer (and optionally an intermediate layer) may exhibit less than 7% corrosion on its surface after 500 hours of the standard salt spray test per ASTM B117-19.

In some configurations, the coating of an interior household article or individual layers of the coating may be free or certain metals or metal alloys to enhance overall performance. For example, the first layer, the second layer or both of an interior household article may be free of iron. In other instances, the first layer, the second layer or both of an interior household article may be free of tungsten. If desired, the first layer and/or the second layer of the interior household article may be free of both iron and tungsten.

In certain embodiments where an interior household article includes a first layer and a second layer comprising chromium, one or more layers may be present between the first layer (e.g., a layer comprising a Mo alloy or a Ni alloy) and the substrate of the interior household article. For example, one or more of an adhesion promotion layer, a corrosion promotion layer, a grain refinements layer, etc. may be present between the substrate of the interior household article and the first layer. In certain configurations where a substrate of the interior household article includes a first layer (e.g., a layer comprising a Mo alloy or a Ni alloy) and a second layer, the substrate of the interior household article may be any of those materials listed herein for substrates. For example, the substrate can include one or more of copper, a copper alloy, nickel, a nickel alloy, cobalt, a cobalt alloy, a plastic, steel, carbon steel, stainless steel, tool steel, galvanized steel, alloy steel, a superalloy, a nickel-chromium superalloy, nickel-chromium-iron-molybdenum alloy, zinc, a zinc alloy, titanium, a titanium alloy, aluminum, an aluminum alloy or other materials and combinations noted herein.

In some embodiments, one or more surfaces of the substrate of the interior household article can be treated (e.g., physically or chemically) prior to placing the first layer on the substrate. For example, one or more substrate surfaces of the interior household article can be hardened, carburized, nitrated, anodized or may be treated to provide combinations thereof.

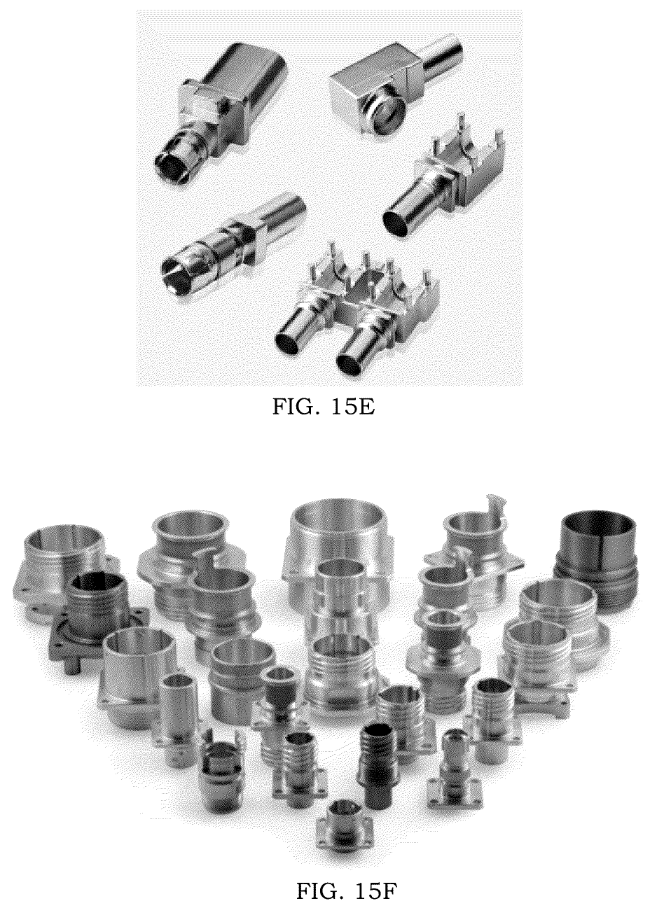

In certain embodiments, the coatings described herein can be used on jewelry. The jewelry may be produced using gold, silver, stainless steel or other metals, and a coating can be included on these metals to reduce corrosion and/or extend the lifetime of the jewelry article. Illustrative jewelry articles include, but are not limited to, a ring 1502 (FIG. 15A), a necklace 1504 (FIG. 15B), earrings 1506 (FIG. 15C), a bracelet 15 (FIG. 15D) or other jewelry articles. The jewelry can include any of those materials or layers described in connection with FIGS. 1-12. For example, the jewelry can include a substrate, at least a first layer and a second layer. The first layer comprises a molybdenum alloy, a nickel alloy or both and optionally other materials. The second layer can include chromium, chromium compounds and optionally other materials. In some examples, the first layer of the jewelry coating comprises a nickel molybdenum alloy. For example, the molybdenum can be present in the first layer at 20% by weight or less. Alternatively, nickel can be present in the first layer at 80% by weight or more.

In other configurations, the jewelry can include one or more layers between the first layer and the second layer, whereas in some configurations the coating can only include the first layer and the second layer. For example, an intermediate layer can be present between the first layer and the second layer so the jewelry article includes three layers on a substrate as noted above. The exact material(s) present in the intermediate layers may vary. For example, the intermediate layer can include one or more transition metals, particles, nanoparticles, refractory metals, metal alloys, etc. In some embodiments, the intermediate layer may be a “bright” or “semi-bright” layer as noted herein.

In certain embodiments, the first layer and the second layer of the jewelry can be formed or otherwise deposited in numerous different manners as noted herein. In some instances, the first layer of the jewelry article can include an electrodeposited molybdenum alloy coating, an electroplated molybdenum alloy coating, an electroless deposited molybdenum alloy coating, an electrodeposited nickel alloy coating, an electroplated nickel alloy coating or an electroless deposited nickel alloy coating.

In certain embodiments, the first layer and the second layer of the jewelry article may together provide some corrosion resistance or other desired properties. For example, a coating including a first layer and a second layer (and optionally an intermediate layer) may exhibit less than 7% corrosion on its surface after 500 hours of the standard salt spray test per ASTM B 117-19.

In some configurations, the coating of a jewelry article or individual layers of the coating may be free or certain metals or metal alloys to enhance overall performance. For example, the first layer, the second layer or both of a jewelry article may be free of iron. In other instances, the first layer, the second layer or both of a jewelry article may be free of tungsten. If desired, the first layer and/or the second layer of the jewelry article may be free of both iron and tungsten.

In certain embodiments where a jewelry article includes a first layer and a second layer comprising chromium, one or more layers may be present between the first layer (e.g., a layer comprising a Mo alloy or a Ni alloy) and the substrate of the jewelry article. For example, one or more of an adhesion promotion layer, a corrosion promotion layer, a grain refinements layer, etc. may be present between the substrate of the jewelry article and the first layer. In certain configurations where a substrate of the jewelry article includes a first layer (e.g., a layer comprising a Mo alloy or a Ni alloy) and a second layer, the substrate of the jewelry article may be any of those materials listed herein for substrates. For example, the substrate can include one or more of copper, a copper alloy, nickel, a nickel alloy, cobalt, a cobalt alloy, a plastic, steel, carbon steel, stainless steel, tool steel, galvanized steel, alloy steel, a superalloy, a nickel-chromium superalloy, nickel-chromium-iron-molybdenum alloy, zinc, a zinc alloy, titanium, a titanium alloy, aluminum, an aluminum alloy or other materials and combinations noted herein.

In some embodiments, one or more surfaces of the substrate of the jewelry article can be treated (e.g., physically or chemically) prior to placing the first layer on the substrate. For example, one or more substrate surfaces of the jewelry article can be hardened, carburized, nitrated, anodized or may be treated to provide combinations thereof.

In certain embodiments, the articles described herein can be configured as a connector shell. In certain embodiments, the coatings described herein can be used on a connector shell. The connector shell may be produced using steel, steel alloys, zinc alloys, aluminum, copper, brass, nickel, nickel alloys, or other metals, and a coating can be included on these metals to reduce corrosion and/or extend the lifetime of the connector shell. Connector shells can be circular shells, RF connector housings, or any other type. Illustrative connector shell articles include but are not limited to those shown in FIGS. 15E and 15F, or other connector shell articles. The connector shell can include any of those materials or layers described in connection with FIGS. 1-12. For example, the connector shell can include a substrate, at least a first layer and a second layer. The first layer comprises a molybdenum alloy, a nickel alloy or both and optionally other materials. The second layer can include chromium, chromium compounds and optionally other materials. In some examples, the first layer of the connector shell's coating comprises a nickel molybdenum alloy. For example, the molybdenum can be present in the first layer at 20% by weight or less. Alternatively, nickel can be present in the first layer at 80% by weight or more.

In some instances, the connector shell can include a substrate and a coating on the substrate. The coating of the connector shell can include a first layer and a second layer, wherein the first layer is comprising a molybdenum alloy, a nickel alloy or both. The second layer can comprise chromium. The exact form of the connector shell may vary. In certain embodiments, the first layer can be formed on the substrate and the second layer can be on the first layer.

In certain examples, the connector shell can include any of those materials described in connection with the articles described herein. For example, the connector shell can include a substrate, at least a first layer and a second layer. The first layer comprises a molybdenum alloy, a nickel alloy or both and optionally other materials. The second layer can include chromium, chromium compounds and optionally other materials. In some examples, the first layer of the connector shell coating comprises a nickel molybdenum alloy. For example, the molybdenum can be present in the first layer at 20% by weight or less. Alternatively, nickel can be present in the first layer at 80% by weight or more.

In other configurations, the connector shell can include one or more layers between the first layer and the second layer, whereas in some configurations the coating can only include the first layer and the second layer. For example, an intermediate layer can be present between the first layer and the second layer so the connector shell includes three layers on a substrate as noted above. The exact material(s) present in the intermediate layers may vary. For example, the intermediate layer can include one or more transition metals, particles, nanoparticles, refractory metals, metal alloys, etc. In some embodiments, the intermediate layer may be a “bright” or “semi-bright” layer as noted herein.

In certain embodiments, the first layer and the second layer of the connector shell can be formed or otherwise deposited in numerous different manners as noted herein. In some instances, the first layer of the connector shell can include an electrodeposited molybdenum alloy coating, an electroplated molybdenum alloy coating, an electroless deposited molybdenum alloy coating, an electrodeposited nickel alloy coating, an electroplated nickel alloy coating or an electroless deposited nickel alloy coating.

In certain embodiments, the first layer and the second layer of the connector shell may together provide some corrosion resistance or other desired properties. For example, a coating including a first layer and a second layer (and optionally an intermediate layer) may exhibit less than 7% corrosion on its surface after 500 hours of the standard salt spray test per ASTM B 117-19.

In some configurations, the coating of a connector shell or individual layers of the coating may be free or certain metals or metal alloys to enhance overall performance. For example, the first layer, the second layer or both of a connector shell may be free of iron. In other instances, the first layer, the second layer or both of a connector shell may be free of tungsten. If desired, the first layer and/or the second layer of the connector shell may be free of both iron and tungsten.

In certain embodiments where a connector shell includes a first layer and a second layer comprising chromium, one or more layers may be present between the first layer (e.g., a layer comprising a Mo alloy or a Ni alloy) and the substrate of the connector shell. For example, one or more of an adhesion promotion layer, a corrosion promotion layer, a grain refinements layer, etc. may be present between the substrate of the connector shell and the first layer. In certain configurations where a substrate of the connector shell includes a first layer (e.g., a layer comprising a Mo alloy or a Ni alloy) and a second layer, the substrate of the connector shell may be any of those materials listed herein for substrates. For example, the substrate can include one or more of copper, a copper alloy, nickel, a nickel alloy, cobalt, a cobalt alloy, a plastic, steel, carbon steel, stainless steel, tool steel, galvanized steel, alloy steel, a superalloy, a nickel-chromium superalloy, nickel-chromium-iron-molybdenum alloy, zinc, a zinc alloy, titanium, a titanium alloy, aluminum, an aluminum alloy or other materials and combinations noted herein.

In some embodiments, one or more surfaces of the substrate of the connector shell can be treated (e.g., physically or chemically) prior to placing the first layer on the substrate. For example, one or more substrate surfaces of the connector shell can be hardened, carburized, nitrated, anodized or may be treated to provide combinations thereof.

In certain embodiments, a decorative item comprises a decorative item substrate, wherein at least a portion of an outer surface of the decorative item substrate comprises a coated surface, wherein the coated surface comprises a surface coating, and wherein the surface coating comprises an alloy layer comprising (i) molybdenum and (ii) at least one element selected from the group consisting of nickel, tungsten, cobalt, chromium, tin, phosphorous, iron, magnesium and boron or at least one compound comprising one or more of nickel, tungsten, cobalt, chromium, tin, phosphorous, iron, magnesium or boron.

In certain embodiments, the decorative item substrate comprises stainless steel, hardened steel, carbon steel, alloy steel, a precious metal or other metal, and wherein the surface coating comprises a chromium layer on the alloy layer.

In some embodiments, the molybdenum is present in the surface coating at 35% or less by weight based on a weight of the surface coating, or at 25% or less by weight based on a weight of the surface coating, or at 15% or less by weight based on a weight of the surface coating, or at 35% or less by weight based on a weight of the alloy layer, or at 25% or less by weight based on a weight of the alloy layer, or at 15% or less by weight based on a weight of the alloy layer. In other embodiments, the molybdenum is present in the surface coating at 65% or more by weight based on a weight of the surface coating, or at 75% or more by weight based on a weight of the surface coating, or at 85% or more by weight based on a weight of the surface coating, or at 65% or less by weight based on a weight of the alloy layer, or at 75% or less by weight based on a weight of the alloy layer, or at 85% or less by weight based on a weight of the alloy layer.

In additional embodiments, the coated surface comprises a surface roughness Ra of less than 1 micron. In other embodiments, the alloy layer consists essentially of nickel and molybdenum or consists essentially of nickel, molybdenum and one of tin, phosphorous, iron, magnesium or boron.

In some examples, the coated surface comprises a surface roughness Ra of less than 1 micron, and the molybdenum is present in the alloy layer at 20% or less by weight based on a weight of the surface coating, and the surface coating excludes precious metals.

In other examples, the alloy layer is an electrodeposited alloy layer. In some embodiments, the alloy layer is an exposed outer layer of the surface coating. In other embodiments, the exposed outer layer consists essentially of molybdenum and only one of nickel, tungsten, cobalt, tin, phosphorous, iron, chromium, magnesium or boron. In some examples, the exposed outer layer consists essentially of molybdenum and only two of nickel, tungsten, cobalt, tin, phosphorous, iron, chromium, magnesium or boron. In other examples, the exposed outer layer consists essentially of both molybdenum and phosphorous and at least one of nickel, cobalt, tin, chromium, tungsten, iron, magnesium or boron.

In certain examples, the alloy layer is an electrodeposited alloy layer, and further comprising an intermediate layer between the surface and the alloy layer wherein the intermediate layer comprises one or more of nickel, nickel alloys, copper, copper alloys, nickel-tungsten alloys, cobalt alloys, nickel-phosphorous alloys, alloys of molybdenum or tungsten or both and at least one of nickel, cobalt, chromium, tin, phosphorous, iron or boron.

In other embodiments, an additional layer is formed on the alloy layer, wherein the additional layer comprises one or more of nickel, nickel alloys, nickel-tungsten alloys, cobalt alloys, cobalt-phosphorous alloys, nickel-phosphorous alloys, alloys of molybdenum and at least one of nickel, cobalt, chromium, tin, phosphorous, iron or boron, ceramics, ceramic comprises compounds of tungsten, chromium, aluminum, zirconium, titanium, nickel, cobalt, molybdenum, silicon, boron, metal nitride, a nitride, a metal carbide, a carbide, a boron, tungsten, tungsten carbide, chromium carbide, chromium oxide, aluminum oxide, zirconia, zirconium oxide, titania, nickel carbide, nickel oxide, nanocomposite, an oxide composite, or combinations thereof.

In some examples, the alloy layer further comprises one or more particles selected from the group consisting of solid nanoparticles, polymeric particles, hard particles, silicon dioxide particles, silicon carbide particles, titanium dioxide particles, polytetrafluoroethylene particles, hydrophobic particles, diamond particles, particles functionalized with hydrophobic groups, solid particles and combinations thereof.

In other examples, the alloy layer is present as an exposed outer layer of the surface coating, wherein the exposed outer layer is an electrodeposited alloy layer, and wherein the electrodeposited alloy layer excludes precious metals.

Several examples are discussed below to test certain coating formulations. These versions are referred to as H-max and O-Max for reference, and as Maxshield or Maxshield coatings collectively. The H-Max family includes a nickel molybdenum coating that is a proposed replacement for electroplated hard Chrome (EHC) coating. Its wear resistance is higher than chrome and can be used is aggressive wear environments. The O-Max family is a nickel molybdenum coating that is more chemically resistant than H-Max and provides extreme chemical resistance. The properties of the coatings can be altered, for example, by varying the ratio of nickel and molybdenum in the coatings.

### EXAMPLE 1

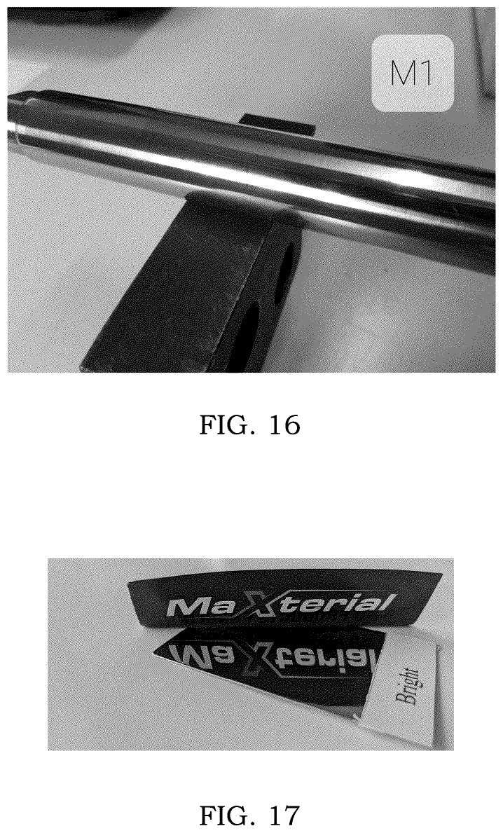

All versions of the coatings have a metallic appearance. FIG. 16 is a photograph showing the appearance of H-Max applied on a hydraulic rod after some minor polishing. All versions of the coatings can be machined, polished, or buffed to change their appearance and roughness. Bright coatings with mirror-like appearance right after the electroplating process can also be produced. The bright, reflective coating shown in FIG. 17 is a coating right after the plating process without any polishing or buffing. O-Max and H-Max can also be matt if needed.

### EXAMPLE 2

The most common thickness of the coatings is between 0.4 mil to 3 mil (10 micrometer to 75 micrometer). However, the coating thickness can be altered by deposition time and the number of coating layers. Thus, coatings with thicknesses less than 0.4 mil and more than 3 mil can be produced.

### EXAMPLE 3

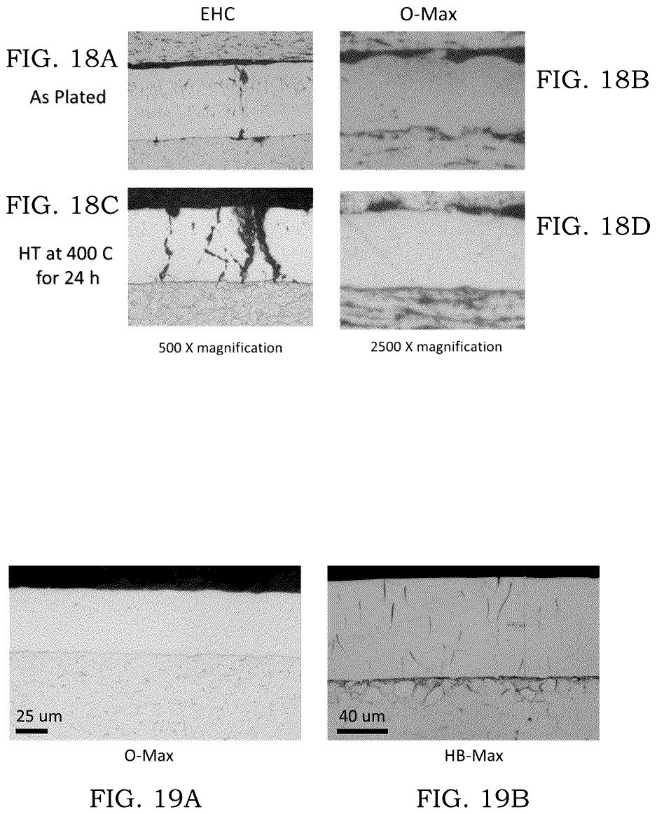

This test was done to study the cross-section of O-Max, measure the thickness and evaluate the effect of the heat treatment on coating structure. All the metallographic works were performed using in-house equipment. EHC samples with the thickness of around 100 μm were provided to us by a chrome plating shop. The cross-section of the as-plated and heat-treated EHC and O-Max samples are shown in FIGS. 18A-18D. As-plated EHC has micro-cracks all over the cross-section, while as-plated O-Max is almost crack-free. After heat-treating EHC, cracks were grown to large macro-cracks. As shown in FIGS. 18A-18D, some of the cracks grew all the way from the substrate to the surface. The presence of this kind of macro-cracks in the coating structure can significantly reduce the corrosion protection of the coating. In contrast, O-Max's cross-section remained the same after the heat exposure, and no sign of crack development was observed in O-Max. Reducing mechanical properties of EHC at high temperature may be related to this crack growth mechanism and degradation that occurs in EHC in the exposure of heat.

FIGS. 19A and 19B show a cross-section of O-Max (FIG. 19A) and H-Max (FIG. 19B) coatings. This figure also shows that O-Max is almost crack-free, while H-Max coating has some micro-cracks. As noted herein, the presence of micro-cracks can enhance lubricity in applications where the coating contacts an oil or lubricant.

### EXAMPLE 4

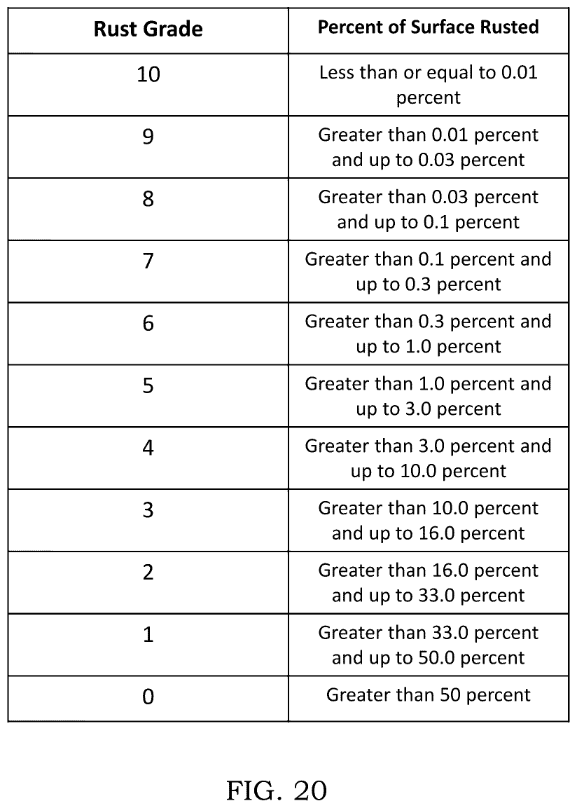

A salt spray corrosion test was performed by Assured Testing Services which is NADCAP-certified testing facility. The standard corrosion test is also known as a salt fog test. During this test, the coated sample is exposed to 5% sodium chloride mist which simulates marine environment corrosion. The test was done according to ASTM B117 by the testing lab. Assured Testing Services also determined the corrosion ratings of different samples according to the ASTM B537 Rust Grade. This standard implies a rating range between 0 to 10 with 10 corresponding to the best corrosion resistance and 0 corresponding to the worse condition. A table showing the corrosion rating scale is present in FIG. 20.

In one example, the corrosion performance of an EHC coating is compared to the O-Max coatings after up to 1000 hours of exposure to the salt fog. We have supplied them with the following samples. All O-max coatings included a metallic underlayer (the composition can vary depending on intended use) and had the following properties: O-Max-V1 has a thickness between 20 to 30 μm; O-Max-V2: It has a thickness between 70 to 90 μm. Manufacturing O-Max-V2 used a heat-treatment process to improve hardness and wear performance; O-Max-V3 is similar to O-Max-V2 but it is not heat-treated.

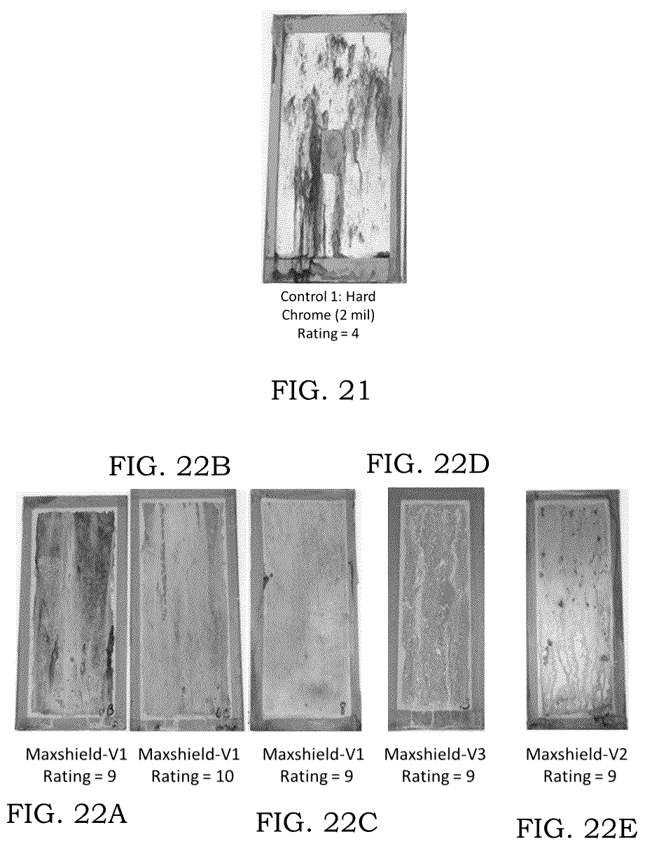

The corrosion rating of EHC with 20 to 30 micron thickness was 10 at 200 hours and went down to 4 at 400 hours report. FIG. 21 shows a photo of the EHC sample at 400 hours. According to the ASTM B537, a corrosion rate of 4 for EHC coating indicates that 3 to 10% of the surface area is corroded after 1000 hours. The images of all five O-Max coatings after 1000 hours exposure to the salt spray are shown in FIGS. 22A-22E. Four of these samples (FIGS. 22A, 22C, 22D and 22E) exhibit a corrosion rating of 9, while the corrosion rating for one of the O-Max-V1 samples (FIG. 22B) after 1000 hours is 10. A corrosion rate of 9 indicates rust formation in less than 0.03% of the surface area according to the ASTM B537 standard. O-Max-V1 sample with rating 10 did not rust at all in the first 1000 hours.

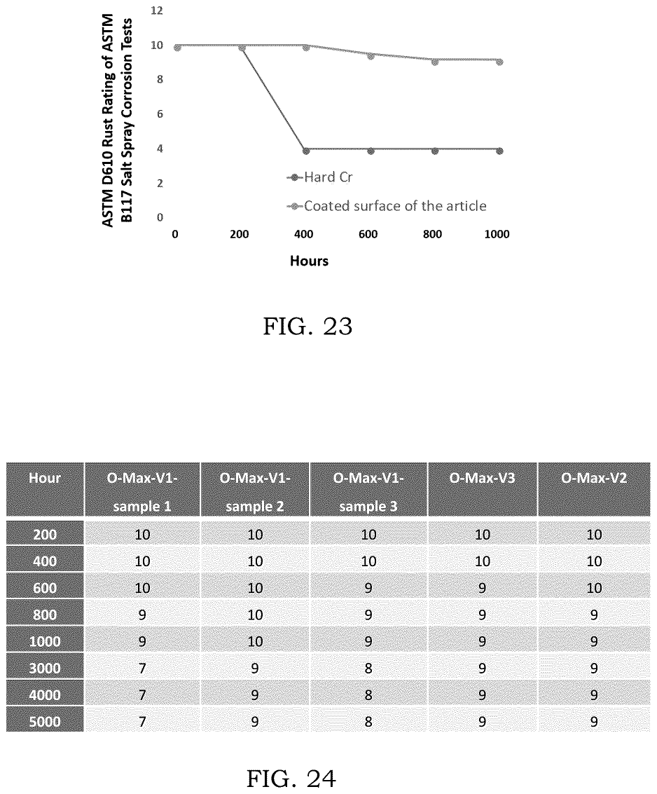

FIG. 23 compares the results of the salt spray test for our coatings with that of EHC coating. As this figure shows, corrosion rating of EHC coating reduces sharply to 4 after 400 hours exposure to the salt spray while the corrosion rate of the produced coatings remains above 9 up to 1000 hours exposure. For the scribed O-Max-V1 coating, a corrosion rate of 9 was obtained on the areas far from the scribed region. Creep measurement rating of 8 was obtained for the scribed region on this sample based on ASTM D1654. The preliminary tests on the scribed surface shows that the produced coatings are not expected to raise a significant risk of accelerated corrosion if they get scratched and the underneath steel surface gets exposed at the location of the scratch.

In another example, salt spray corrosion test was performed on O-Max samples up to 5000 hours. Rating of the samples at different times of the salt spray test up to 5000 hours are shown in the table in FIG. 24. As shown in this table, ratings of O-Max-V2 and O-Max-V3 remain at 9 up to 4000 hours of the salt spray. Three samples of O-Max-V1 exhibits corrosion rating of 7, 9, and 8. O-Max-V1 has lower thickness compared to O-Max-V2 and O-Max-V3. For thinner coatings, there is more chance for the corrosive media to get to the base steel substrate from the pinholes and defects on the coating and result in corrosion. This is the reason that O-Max-V2 and O-Max-V3 perform better than O-Max-V1 at this elongated exposure to the corrosive media.

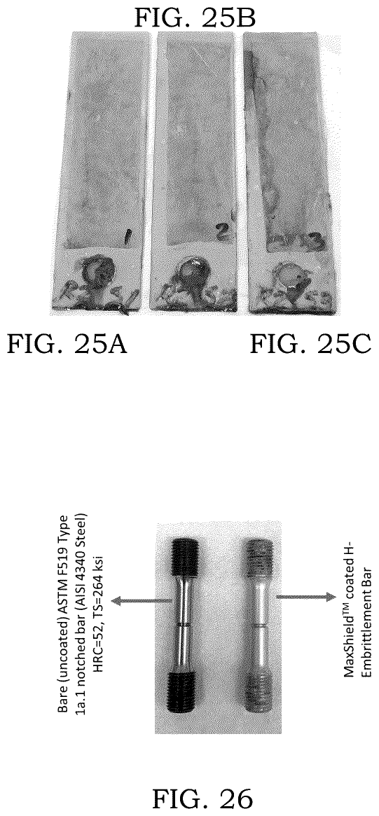

In another example, corrosion performance of H-Max family was tested. In this test, 25 um thick H-Max coating with a metallic underlayer was tested in the salt spray chamber according to ASTM B117 by the Assured testing lab. There samples were tested up to 1000 hours of salt spray. The rating of all three samples after 1000 hours was 10, meaning that no corrosion was observed in the testing area of the samples. FIGS. 25A-25C shows the images of the samples after 1000 hours of the salt spray. It is worth mentioning that the rust color at the edge of the third sample (FIG. 25C) is the bleeding from the backside of the sample.

In another example, H-Max and O-Max coated parts were tested according to the salt spray corrosion test of ASTM B117 with less than 5% corrosion on the surface after 1000 hours.

In another example, H-Max and O-Max coated parts were tested according to the salt spray corrosion test of ASTM B117 with less than 5% corrosion on the surface after 5000 hours.

In another example, carbon steel parts coated with H-Max and O-Max were tested according to the salt spray corrosion test of ASTM B117 with corrosion rating of more than 6 after 48 hours. In another example, sockets coated with H-Max with a nickel underlayer showed no corrosion after 48 hours.

### EXAMPLE 5

This test was performed by Assured Testing Services (Ridgway, PA), a NADCAP-certified testing facility. The test was performed on three sets of standard notched bars coated with O-Max, and another three sets coated in H-Max. Each set includes four notched bars covered with these coatings. The images of one of these notched bars before and after applying the coating are shown in FIG. 26. The bars were tested per ASTM F519 for 200 hours of sustained loads in the amount of 75% of their fracture strength by the testing lab. Based on the standard a plating process shall be considered non-embrittling if none of the plated sample fracture within 200 hours of loading. All the bars coated with O-Max and H-Max passed this test with no fracture. These results show that O-Max and H-Max coatings do not cause hydrogen-induced cracking (hydrogen embrittlement). None of the samples sent for this test had been heat-treated to relieve the hydrogen embrittlement. It is worth mentioning that EHC is susceptible to hydrogen embrittlement, and therefore, it requires a bake-relief process (Federal Specification, 1967). It is important to note that hydrogen embrittlement also depends on the pre-treatment process in addition to the plating process. Depending on the pre-treatment process, hydrogen embrittlement may occur in the coating regardless of the plating process. Therefore, bake relief is always recommended as a safety measure for all coatings.

### EXAMPLE 6

Shock absorbers are used in almost all land vehicles. Chrome-coated cylinders are a typical part of shock absorbers for wear protection. In this instance, we replaced the chrome used on the shock absorber cylinder with MaxShield.

A test apparatus that simulated back and forth movement of a shock-absorber as used to test wear. The test fails when fluid leakage from the shock absorber is observed due to the wear of the seal (made of Nitro-rubber) or the coating. In this test, the tested H-max-coated shock absorber outperformed EHC by performing flawlessly for 100,000 cycles.

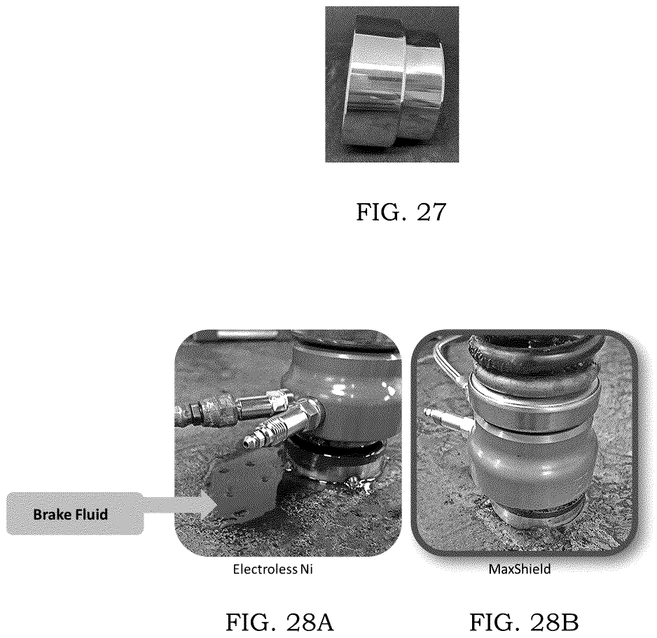

A second H-Max application is focused on the hydraulic parts used in the clutch systems of cars. During operation of the clutch systems, for example when the driver pushes the clutch pedal in a manual car, multiple parts experience constant wear, with some of those parts coated in electroless nickel. We replaced the electroless nickel coating with H-Max. Chrome and other wear-resistant coatings cannot be used on these specific brake parts due to their lack of ability to properly coat inside surfaces and restricted areas. FIG. 27 is a photograph of the part coated with H-Max. The part has both inside and outside surfaces. A test apparatus simulating back and forth movement was used to determine oil-leakage and failure of the part. Both H-Max and electroless nickel-coated parts were tested for 100,000 cycles. As shown in FIGS. 28A and 28B, after 100,000 cycles electroless nickel coating wears away, and the brake fluid drips out (FIG. 28A), dampening the entire table. On the contrary, H-Max remains intact, and no oil leakage was observed (FIG. 28B).

A third H-Max application is focused on the hydraulic parts for industrial applications including cranes. Two H-Max coated, and one EHC coated cylinders were tested co-currently. A test rig is prepared with a triple parallel connection to fill every single cylinder. The three cylinders are mounted in parallel, performing the same movement. The rods stroke out without load in stage 1 and with 50 kg load in the stage 2. Active strokes back and forward included: 1st stage: 7992; 2nd stage: 8362. The H-Max cylinders did not fail the test.

### EXAMPLE 7

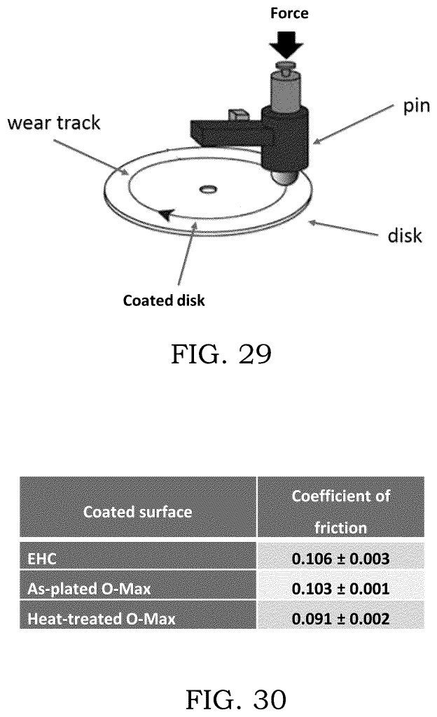

The Pin on the Disk test was performed by EP Laboratories. They have been listed in Qmed as an independent testing laboratory specialized in mechanical testing at the nano and micro levels. In this test, friction coefficient of as-plated and heat-treated O-Max coatings with 50 um thickness were measured per ASTM G99 specification by EP Laboratories. As shown in FIG. 29, the test involved applying a 20 N force through a hard ball made of 440C stainless steel onto the lubricated coating surface that rotates 200 revolution per minute. One of the main characteristics of EHC is its low friction coefficient or its slippery nature in lubricated environments. In this test, friction coefficient of EHC was measured and compared with O-Max coatings.

Friction coefficients measured for EHC coating, as-plated and heat-treated O-Max coatings are shown in the table of FIG. 30. As shown in this table, friction coefficients of both versions of O-Max are very similar to that of EHC coating.

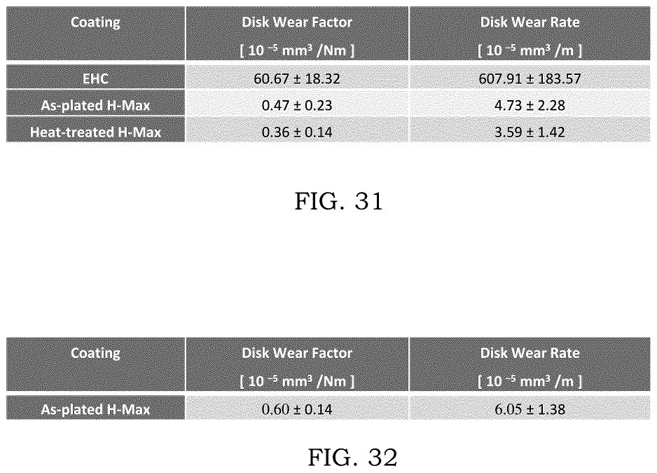

In another test, wear properties of H-Max were compared with the wear properties of EHC. Four carbon steel samples coated with 50 um thick EHC, as-plated H-Max, and heat-treated H-Max were sent to the EP laboratories to be tested according to the ASTM G-99 standard in not lubricated condition. Wear properties of these samples that were obtained from the test are listed in the table of FIG. 31. As this table show, the H-Max products exhibited more than two order of magnitudes better wear resistance than EHC. Thus, the wear rate of H-Max is significantly less than EHC.

Another example of the wear factor and wear rate of H-Max coating are shown in the table of FIG. 32.

### EXAMPLE 8

Numerous hardness tests have been performed on MaxShield coatings according to the ASTM E384-17 standards using an in-house hardness tester (Phase II, Upper Saddle River, NJ) and independent third parties. In one example, Vickers hardness between 520 to 550 were obtained for O-Max. In one example, Vickers hardness between 740 to 780 were measured for the H-Max coating. In another example, hardnesses of 680 was observed for the as-plated H-Max coating. Heat treatment can increase the hardness of all versions of the coating. In one example, the hardness can increased to around 650 HV for O-Max by a proper heat treatment process. In one example, heat treatment of H-Max resulted in the hardness of 850 to 940 HV. In another example, heat treatment resulted in the hardness of 800 for H-Max. In one example, the Vickers hardness of as-plated H-Max is better than as-plated electroless nickel coating (480-500 HV) and almost similar to the hardness of the heat-treated electroless nickel (700-800 HV). It is worth mentioning that electroless nickel is a wear-resistant coating that is known as one of the replacements for EHC coating. In another example, the hardness of as-plated H-Max is comparable with that of the as-plated EHC.

Hardness of EHC coating reduces at high temperatures. Heat treatment at 190° C. for 23 hours reduces the hardness of EHC to 700-750 HV. As illustrated before by the cross-sectional images, heat ruins the integrity of the EHC coating by creating large macro-cracks in its structure. Therefore, EHC loses its integrity at high temperatures.

### EXAMPLE 9

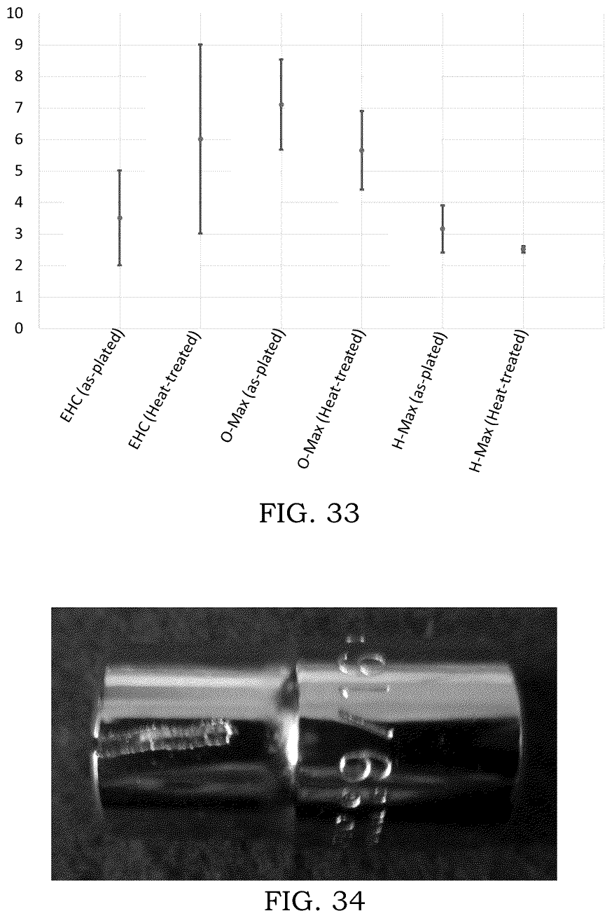

The Standard Taber abrasion test was performed according to the ASTM D4060 standard. In this test, an abrader machine (Tabor Industries, North Tonawanda, New York) was used to abrade the surface of the coating by applying 1 kg load on each abrasive wheel. Taber wear index (TWI) is the milligram weight loss per 1000 cycles. An example of the TWI values for MaxShield coatings and EHC at as-plated and heat-treated conditions are exhibited in FIG. 33. This test has been done on at least three different samples for each coating and the results for the EHC coatings match with those in the literature. These results exhibit the average TWI of 7.1 and 5.6 for as-plated and heat-treated O-Max, respectively. For H-Max the average TWI of 3.1 and 2.5 were obtained for the as-plated and heat-treated conditions, respectively. As-plated and heat-treated EHC resulted in the TWI of 3.5 and 6, respectively. These results confirm that unlike MaxShield that becomes more wear-resistant with heat-treatment, wear properties of EHC degrades at the heat exposure. Our H-Max family coatings exhibit better TWI compared to the EHC at both as-plated and heat-treated conditions. TWI of as-plated O-Max is comparable with that of the heat-treated EHC, while TWI of heat-treated O-Max is better than that of the heat-treated EHC.

### EXAMPLE 10

An adhesion bend test was conducted on heat-treated O-Max samples according to ASTM B571-18. If the coating does not provide a strong adhesion, it cannot provide wear and corrosion protection either. In this test, a strip of 1008 Carbon Steel (CS) with exposed area of 3 cm×5 cm was coated on one side with 10 um O-Max. The coated sample was then placed in a furnace for 1 hour at 700 degrees C in air. A piece of tape was attached to the coating surface. The air bubbles were removed from the area under the tape to ensure there was a strong adhesion between the coating and the tape. The taped sample then was bent to 180 degrees, and the tape was removed from the coating surface. The test fails if the coating delaminates from the surface and transfers to the tape. The tape was clear in this test, and delamination of the coating was not observed. Therefore, the coating passed the adhesion bend test.

In another example, three steel sockets coated in H-Max were adhesion tested according to the ASTM B571, Grind-Saw test. A crack is sawed into the socket as shown in FIG. 34. All three parts passed the adhesion test without any visible lifting or peeling of the plating at the cut site.

### EXAMPLE 11

In one example, MaxShield coating were ground from 0.006″ thickness to 0.003″-0.005″ thickness and were polished to a final surface finish of 4 to 8 microinches by a third party. No issues were experienced in machining processes. Our data indicates that MaxShield coatings can be machined without any adhesion failure. On the other side, machining EHC and thermal spray coating is known to be problematic because of chipping and flaking issue. It is difficult to polish thermal spray coating to a roughness of 0.2 um. This roughness is suggested for most seals of the hydraulic parts. Also, as-plated MaxShield coating is usually more uniform than the EHC coating, therefore, less grinding is expected for MaxShield compared to EHC. The difficulty of EHC grinding is one reason that third parties are seeking to replace EHC.

### EXAMPLE 12

This test has been done by TÜV SÜD, a global and well-reputed testing lab for environmental analysis. Two versions of MaxShield (O-Max and H-Max) were tested by this lab, and it was confirmed that these coatings do not contain substances of very high concern (SVHCs) according to the REACH and RoHS regulations. SVHCs is a list of 224 substances including Chromium, Cadmium, Cyanide, Lead, PFOS and PFAS. The tested samples did not include any levels above 0.01 as specified in REACH. The tested samples also did not contain any heavy metals (Pb, Cd, Hg, or Cr VI), polybrominated biphenyls, polybrominated diphenyl ethers or phthalates. This results are consistent with the Maxterial coatings providing more environmentally friendly coatings.

### EXAMPLE 13

O-Max offers multiple unit performance factors including the ability to perform in extremely acidic environments or when higher ductility is needed.

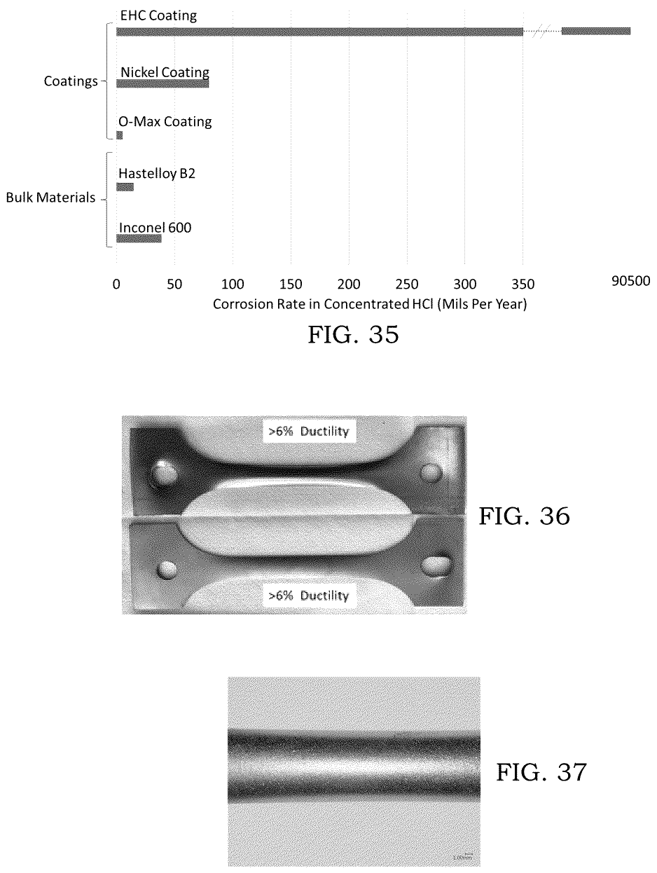

An internal test to measure acid resistance was performed. In this test, stand-alone coatings as films were immersed in an aqueous solution of concentrated hydrochloric acid (32 % stock solution of HCl) for 24 hours. The weight loss of the coatings after 24-hours exposure to the concentrated HCl solution was used to calculate the corrosion rate. It is worth mentioning that 32% HCl is a very strong acid with a negative pH. The results of one example that compares the corrosion rate of O-Max coating with an existing nickel coating and an EHC coating are shown in FIG. 35. This figure also provides the corrosion rate of Inconel and Hastelloy as corrosion-resistant bulk materials for reference. The rate reported for O-Max coating in this figure is the average of the corrosion test obtained for three samples. As this figure shows, the corrosion rate of O-Max coating (less than 13 milli-inch per year, sometimes as low as 1.5 milli-inch per year) is much lower than that of the existing nickel coating (80 milli-inch per year) (Nickel Development Institute) and not even comparable with the corrosion rate of EHC in concentrated HCl. EHC coating dissolves in concentrated HCl in less than 10 minutes and its corrosion rate is not on the scale of this figure. The figure also shows the corrosion rate of corrosion-resistant bulk materials, Hastelloy® B2 and Inconel®, against the concentrated HCl solution, based on the values published in the literature. Interestingly, in this example, O-Max coating shows lower corrosion rate compared to Hastelloy® (15 milli-inch per year) and Inconel® (39 milli-inch per year). Hastelloy® and Inconel® are superalloys known for their extreme corrosion resistance in HCl environment.

### EXAMPLE 14

In one example, ductility test was performed by Anamet, Inc., an A2LA certified testing lab on two versions of the O-Max coating with 25 um and 50 um thickness. In this test, coated T-bone specimens are tensile tested uniaxially according to ASTM E8/8M-22. The strain will continue until the coating flakes off and the underneath surface can be seen in 50× microscopic images. Both O-Max coatings could be elongated to above 6% without flaking or fracturing. The ductility value of greater than 6% is significantly higher than the ductility of EHC coatings, which is less than 0.1% according to National Bureau Standards. It is also higher than the ductility of electroless nickel coating, which is between 1% to 1.5%. Based on these results, it can be concluded that O-Max coating is much more formable compared to the EHC and electroless nickel coatings. FIG. 36 shows the images of the tested O-Max coatings after 6 percent elongation. The microscopic image of the 25 um coating is demonstrated in FIG. 37. As this figure exhibits at least 6% ductility without any fracture or blistering.

1. A decorative item comprising a decorative item substrate, wherein at least a portion of an outer surface of the decorative item substrate comprises a coated surface, wherein the coated surface comprises a surface coating, and wherein the surface coating comprises an alloy layer comprising (i) molybdenum or tungsten and (ii) at least one element selected from the group consisting of nickel, cobalt, chromium, tin, phosphorous, iron, magnesium and boron or at least one compound comprising one or more of nickel, cobalt, chromium, tin, phosphorous, iron, magnesium or boron.

2. The decorative item of claim 1, wherein the alloy layer is present on all surfaces of the decorative item substrate.

3. The decorative item of claim 1, wherein the alloy layer is present on inner surfaces of the decorative item substrate.

4. The decorative item of claim 3, wherein the molybdenum or tungsten is present in the surface coating at 40% or less by weight based on a weight of the surface coating, or at 20% or less by weight based on a weight of the surface coating, or at 10% or less by weight based on a weight of the surface coating, or at 40% or less by weight based on a weight of the alloy layer, or at 20% or less by weight based on a weight of the alloy layer, or at 10% or less by weight based on a weight of the alloy layer.

5. The decorative item of claim 3, wherein the surface coating comprises a surface roughness Ra of less than 1 micron.

6. The decorative item of claim 3, wherein the alloy layer consists essentially of nickel and molybdenum or consists essentially of nickel, molybdenum and phosphorous, or consists essentially of nickel and tungsten or consists essentially of nickel, tungsten and phosphorous.

7. The decorative item of claim 6, wherein the surface coating comprises a surface roughness Ra of less than 1 micron, and the molybdenum or tungsten is present in the alloy layer at 20% or less by weight based on a weight of the surface coating, and the surface coating excludes precious metals.

8. The decorative item of claim 7, wherein the alloy layer is an electrodeposited alloy layer.

9. The decorative item of claim 3, wherein the surface coating is free of any precious metals.

10. The decorative item of claim 1, wherein the alloy layer is an exposed outer layer of the surface coating.

11. The decorative item of claim 10, wherein the exposed outer layer (i) consists essentially of molybdenum or tungsten and only one element or compound comprising nickel, cobalt, tin, phosphorous, iron, chromium or boron, or (ii) consists essentially of molybdenum or tungsten and only two elements or compounds comprising of nickel, cobalt, tin, phosphorous, iron, chromium or boron, or (iii) consists essentially of molybdenum, nickel and only element or compound comprising tungsten, cobalt, tin, phosphorous, iron, chromium or boron or (iv) consists essentially of tungsten, nickel and only element or compound comprising molybdenum, cobalt, tin, phosphorous, iron, chromium, magnesium or boron.

12. The decorative item of claim 1, further comprising an intermediate layer between the alloy layer and the surface of the substrate.

13. The decorative item of claim 12, wherein the alloy layer is present as an exposed outer layer of the surface coating, wherein the exposed outer layer is an electrodeposited alloy layer, and wherein the electrodeposited alloy layer excludes precious metals.

14. The decorative item of claim 1, or further comprising an additional layer formed on the alloy layer.

15. The decorative item of claim 1, wherein the alloy layer is present as an electrodeposited alloy layer, and wherein the electrodeposited alloy layer excludes precious metals.

16. The decorative item of claim 1, wherein the decorative item substrate comprises a textured surface.

17. The decorative item of claim 1, wherein the coated surface comprises a textured surface.

18. The decorative item of claim 17, wherein the textured surface comprises a surface roughness Ra of more than 1 micron and less than 30 microns.

19. The decorative item of claim 17, wherein the textured surface comprises a surface roughness Ra of more than 0.5 microns and less than 15 microns.

20. The decorative item of claim 17, wherein the coated surface is free of precious metals.

21-24. (canceled)
